(19) United States
(12) Patent Application Publication
(10) Pub. No.: US 2026/0173373 A1
(43) Pub. Date: Jun. 18, 2026

(54) THREE-DIMENSIONAL MEMORY DEVICE INCLUDING SYMMETRIC ARRAY CONNECTION STRIPS AND METHODS FOR FORMING THE SAME

(71) Applicant: Sandisk Technologies, Inc., Milpitas, CA (US)

(72) Inventors: Kota FUNAYAMA, Yokkaichi (JP); Koichi MATSUNO, Fremont, CA (US)

(21) Appl. No.: 18/984,190

(22) Filed: Dec. 17, 2024

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A device structure includes an alternating stack of insulating layers and electrically conductive layers, a first lateral isolation trench fill structure laterally extending along a first horizontal direction, and a second lateral isolation trench fill structure laterally extending along the first horizontal direction and spaced from the first lateral isolation trench fill structure by the alternating stack. The alternating stack includes a first alternating stack portion located in a first memory array region, a second alternating stack portion located in a second memory array region that is laterally spaced from the first memory array region along the first horizontal direction, a connection strip portion connecting the first alternating stack portion and the second alternating stack portion, a first staircase portion adjoined to a first side of the connection strip portion, and a second staircase portion adjoined to a second side of the connection strip portion.

### FIELD

The present disclosure relates generally to the field of semiconductor devices, and particularly to a three-dimensional memory device including symmetric array connection strips and methods for forming the same.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure comprises an alternating stack of insulating layers and electrically conductive layers that alternate along a vertical direction; a first lateral isolation trench fill structure laterally extending along the first horizontal direction; and a second lateral isolation trench fill structure laterally extending along the first horizontal direction and spaced from the first lateral isolation trench fill structure along the second horizontal direction by the alternating stack. The alternating stack comprises: a first alternating stack portion located in a first memory array region; a second alternating stack portion located in a second memory array region that is laterally spaced from the first memory array region along a first horizontal direction; a connection strip portion located in a connection strip region and connecting the first alternating stack portion and the second alternating stack portion; a first staircase portion adjoined to a first side of the connection strip portion along a second horizontal direction that is perpendicular to the first horizontal direction; and a second staircase portion adjoined to a second side of the connection strip portion along the second horizontal direction.

According to another aspect of the present disclosure, a method of forming a device structure comprises forming a vertically alternating sequence of continuous insulating layers and continuous sacrificial material layers; forming stepped cavities having a respective stepped bottom surface in the vertically alternating sequence; forming in-process retro-stepped dielectric material portions in the stepped cavities; forming memory stack structures through the vertically alternating sequence, wherein each of the memory stack structures comprises a respective vertical stack of memory elements and a vertical semiconductor channel; forming lateral isolation trenches through the vertically alternating sequence; and replacing the sacrificial material layers with electrically conductive layers. The lateral isolation trenches cut the vertically alternating sequence into multiple alternating stacks of respective insulating layers and respective sacrificial material layers; each of the lateral isolation trenches laterally extends along a first horizontal direction and divides a respective one of the in-process retro-stepped dielectric material portions into a respective pair of retro-stepped dielectric material portions; and a contiguous combination of an alternating stack, a first retro-stepped dielectric material portion, and a second retro-stepped dielectric material portion is formed between each neighboring pair of the lateral isolation trenches.

According to another aspect of the present disclosure, a method of forming a device structure comprises forming a vertically alternating sequence of continuous insulating layers and continuous sacrificial material layers; forming first and second stepped cavities having a respective stepped bottom surface in the vertically alternating sequence such that a connection strip region is located between the first and the second stepped cavities; forming respective first and second in-process retro-stepped dielectric material portions in the respective first and second stepped cavities; forming access openings through the connection strip region; forming memory stack structures through the vertically alternating sequence, wherein each of the memory stack structures comprises a respective vertical stack of memory elements and a vertical semiconductor channel; forming lateral isolation trenches through the vertically alternating sequence; and replacing the sacrificial material layers with electrically conductive layers through the lateral isolation trenches and through the access openings.

### BRIEF DESCRIPTION OF THE DRAWINGS

FIG. 1 is a schematic vertical cross-sectional view of a first exemplary structure for forming a semiconductor die after formation of a vertically alternating sequence of first-tier continuous insulating layers and first-tier continuous sacrificial material layers according to a first embodiment of the present disclosure.

FIG. 2A is a schematic vertical cross-sectional view of the first exemplary structure after formation of first-tier stepped cavities according to the first embodiment of the present disclosure. FIG. 2B is a schematic top-down view of the first exemplary structure of FIG. 2A. The vertical plane A-A′ in FIG. 2B is the cut plane of the vertical cross-sectional view of FIG. 2A. FIG. 2C is a schematic vertical cross-sectional view of a region of the first exemplary structure along the vertical plane C-C′ in FIG. 2B. FIG. 2D is a schematic vertical cross-sectional view of a region of the first exemplary structure along the vertical plane D-D′ in FIG. 2B.

FIGS. 3A-3E are sequential vertical cross-sectional views of a region underneath a first-tier stepped cavity during local thickening of the first-tier continuous sacrificial material layers according to the first embodiment of the present disclosure.

FIG. 4A is a schematic vertical cross-sectional view of the first exemplary structure after formation of first-tier retro-stepped dielectric material portions according to the first embodiment of the present disclosure. FIG. 4B is a schematic top-down view of the first exemplary structure of FIG. 4A. The vertical plane A-A′ in FIG. 4B is the cut plane of the vertical cross-sectional view of FIG. 4A. FIG. 4C is a schematic vertical cross-sectional view of a region of the first exemplary structure along the vertical plane C-C′ in FIG. 4B. FIG. 4D is a schematic vertical cross-sectional view of a region of the first exemplary structure along the vertical plane D-D′ in FIG. 4B.

FIG. 5A is a schematic vertical cross-sectional view of the first exemplary structure after formation of first-tier openings and first-tier sacrificial opening fill structures according to the first embodiment of the present disclosure. FIG. 5B is a schematic top-down view of the first exemplary structure of FIG. 5A. The vertical plane A-A′ in FIG. 5B is the cut plane of the vertical cross-sectional view of FIG. 5A. FIG. 5C is a schematic vertical cross-sectional view of a region of the first exemplary structure along the vertical plane C-C′ in FIG. 5B. FIG. 5D is a schematic vertical cross-sectional view of a region of the first exemplary structure along the vertical plane D-D′ in FIG. 5B.

FIG. 6A is a schematic vertical cross-sectional view of the first exemplary structure after formation of a vertically alternating sequence of second-tier continuous insulating layers and second-tier continuous sacrificial material layers, second-tier retro-stepped dielectric material portions, and a contact-level dielectric layer according to the first embodiment of the present disclosure. FIG. 6B is a schematic top-down view of the first exemplary structure of FIG. 6A. The vertical plane A-A′ in FIG. 6B is the cut plane of the vertical cross-sectional view of FIG. 6A. FIG. 6C is a schematic vertical cross-sectional view of a region of the first exemplary structure along the vertical plane C-C′ in FIG. 6B. FIG. 6D is a schematic vertical cross-sectional view of a region of the first exemplary structure along the vertical plane D-D′ in FIG. 6B.

FIG. 7A is a schematic vertical cross-sectional view of the first exemplary structure after formation of second-tier openings according to the first embodiment of the present disclosure. FIG. 7B is a schematic top-down view of the first exemplary structure of FIG. 7A. The vertical plane A-A′ in FIG. 7B is the cut plane of the vertical cross-sectional view of FIG. 7A. FIG. 7C is a schematic vertical cross-sectional view of a region of the first exemplary structure along the vertical plane C-C′ in FIG. 7B. FIG. 7D is a schematic vertical cross-sectional view of a region of the first exemplary structure along the vertical plane D-D′ in FIG. 7B.

FIG. 8A is a schematic vertical cross-sectional view of the first exemplary structure after formation of second-tier sacrificial opening fill structures according to the first embodiment of the present disclosure. FIG. 8B is a schematic top-down view of the first exemplary structure of FIG. 8A. The vertical plane A-A′ in FIG. 8B is the cut plane of the vertical cross-sectional view of FIG. 8A. FIG. 8C is a schematic vertical cross-sectional view of a region of the first exemplary structure along the vertical plane C-C′ in FIG. 8B. FIG. 8D is a schematic vertical cross-sectional view of a region of the first exemplary structure along the vertical plane D-D′ in FIG. 8B.

FIG. 9A is a schematic vertical cross-sectional view of the first exemplary structure after removal of sacrificial support opening fill structures according to the first embodiment of the present disclosure. FIG. 9B is a schematic top-down view of the first exemplary structure of FIG. 9A.

FIG. 10A is a schematic vertical cross-sectional view of the first exemplary structure after formation of support pillar structures according to the first embodiment of the present disclosure. FIG. 10B is a schematic top-down view of the first exemplary structure of FIG. 10A.

FIG. 11A is a schematic vertical cross-sectional view of the first exemplary structure after removal of sacrificial contact opening fill structures according to the first embodiment of the present disclosure. FIG. 11B is a schematic top-down view of the first exemplary structure of FIG. 11A. FIG. 11C is a schematic vertical cross-sectional view of a region of the first exemplary structure along the vertical plane C-C′ in FIG. 11B. FIG. 11D is a schematic vertical cross-sectional view of a region of the first exemplary structure along the vertical plane D-D′ in FIG. 11B.

FIG. 12 is a vertical cross-sectional view of the first exemplary structure after formation of fin cavities around the contact via openings according to the first embodiment of the present disclosure.

FIG. 13 is a vertical cross-sectional view of the first exemplary structure after formation of annular dielectric spacers around the contact via openings according to the first embodiment of the present disclosure.

FIG. 14A is a schematic vertical cross-sectional view of the first exemplary structure after formation of finned sacrificial contact via opening fill structures according to the first embodiment of the present disclosure. FIG. 14B is a schematic top-down view of the first exemplary structure of FIG. 14A. FIG. 14C is a schematic vertical cross-sectional view of a region of the first exemplary structure along the vertical plane C-C′ in FIG. 14B. FIG. 14D is a schematic vertical cross-sectional view of a region of the first exemplary structure along the vertical plane D-D′ in FIG. 14B.

FIG. 15A is a schematic vertical cross-sectional view of the first exemplary structure after removal of sacrificial memory opening fill structures according to the first embodiment of the present disclosure. FIG. 15B is a schematic top-down view of the first exemplary structure of FIG. 15A. FIG. 15C is a schematic vertical cross-sectional view of a region of the first exemplary structure along the vertical plane C-C′ in FIG. 15B. FIG. 15D is a schematic vertical cross-sectional view of a region of the first exemplary structure along the vertical plane D-D′ in FIG. 15B.

FIGS. 16A-16F illustrate sequential vertical cross-sectional views of a memory opening during formation of a memory opening fill structure according to an embodiment of the present disclosure.

FIG. 17A is a schematic vertical cross-sectional view of the first exemplary structure after formation of memory opening fill structures according to the first embodiment of the present disclosure. FIG. 17B is a schematic top-down view of the first exemplary structure of FIG. 17A. FIG. 17C is a schematic vertical cross-sectional view of a region of the first exemplary structure along the vertical plane C-C′ in FIG. 17B. FIG. 17D is a schematic vertical cross-sectional view of a region of the first exemplary structure along the vertical plane D-D′ in FIG. 17B.

FIG. 18A is a schematic vertical cross-sectional view of the first exemplary structure after formation of lateral isolation trenches according to the first embodiment of the present disclosure. FIG. 18B is a schematic top-down view of the first exemplary structure of FIG. 18A.

FIG. 19A is a schematic vertical cross-sectional view of the first exemplary structure after formation of sacrificial lateral isolation trench fill structures according to the first embodiment of the present disclosure. FIG. 19B is a schematic top-down view of the first exemplary structure of FIG. 19A.

FIG. 20A is a schematic vertical cross-sectional view of the first exemplary structure after formation of bridge recesses according to the first embodiment of the present disclosure. FIG. 20B is a schematic top-down view of the first exemplary structure of FIG. 20A.

FIG. 21A is a schematic vertical cross-sectional view of the first exemplary structure after formation of bridge structures according to the first embodiment of the present disclosure. FIG. 21B is a schematic top-down view of the first exemplary structure of FIG. 21A.

FIG. 22A is a schematic vertical cross-sectional view of the first exemplary structure after formation of voids in the access openings, the contact openings, and the lateral isolation trenches according to the first embodiment of the present disclosure. FIG. 22B is a schematic top-down view of the first exemplary structure of FIG. 22A.

FIG. 23 is a schematic vertical cross-sectional view of the first exemplary structure after formation of laterally-extending cavities according to the first embodiment of the present disclosure.

FIG. 24 is a schematic vertical cross-sectional view of the first exemplary structure after conformal deposition of an electrically conductive material layer according to the first embodiment of the present disclosure.

FIG. 25 is a schematic vertical cross-sectional view of the first exemplary structure after conformal deposition of a dielectric liner layer according to the first embodiment of the present disclosure.

FIG. 26A is a schematic vertical cross-sectional view of the first exemplary structure after patterning the dielectric liner layer and the electrically conductive material layer according to the first embodiment of the present disclosure. FIG. 26B is a schematic top-down view of the first exemplary structure of FIG. 26A.

FIG. 27 is a schematic vertical cross-sectional view of the first exemplary structure after formation of a connection-level dielectric layer according to the first embodiment of the present disclosure.

FIG. 28A is a schematic vertical cross-sectional view of the first exemplary structure after formation of connection via structures according to the first embodiment of the present disclosure. FIG. 28B is a schematic top-down view of the first exemplary structure of FIG. 28A. FIG. 28C is a schematic vertical cross-sectional view of a region of the first exemplary structure along the vertical plane C-C′ in FIG. 28B. FIG. 28D is a schematic vertical cross-sectional view of a region of the first exemplary structure along the vertical plane D-D′ in FIG. 28B.

FIG. 29A is a schematic vertical cross-sectional view of a second exemplary structure after formation of second-tier sacrificial opening fill structures according to the second embodiment of the present disclosure. FIG. 29B is a schematic top-down view of the second exemplary structure of FIG. 29A. The vertical plane A-A′ in FIG. 29B is the cut plane of the vertical cross-sectional view of FIG. 29A. FIG. 29C is a schematic vertical cross-sectional view of a region of the second exemplary structure along the vertical plane C-C′ in FIG. 29B. FIG. 29D is a schematic vertical cross-sectional view of a region of the second exemplary structure along the vertical plane D-D′ in FIG. 29B.

FIG. 30A is a schematic vertical cross-sectional view of the second exemplary structure after removal of sacrificial support opening fill structures according to the second embodiment of the present disclosure. FIG. 30B is a schematic top-down view of the second exemplary structure of FIG. 30A.

FIG. 31A is a schematic vertical cross-sectional view of the second exemplary structure after formation of support pillar structures according to the second embodiment of the present disclosure. FIG. 31B is a schematic top-down view of the second exemplary structure of FIG. 31A.

FIG. 32A is a schematic vertical cross-sectional view of the second exemplary structure after removal of sacrificial memory opening fill structures according to the second embodiment of the present disclosure. FIG. 32B is a schematic top-down view of the second exemplary structure of FIG. 32A. FIG. 32C is a schematic vertical cross-sectional view of a region of the second exemplary structure along the vertical plane C-C′ in FIG. 32B. FIG. 32D is a schematic vertical cross-sectional view of a region of the second exemplary structure along the vertical plane D-D′ in FIG. 32B.

FIG. 33A is a schematic vertical cross-sectional view of the second exemplary structure after formation of memory opening fill structures according to the second embodiment of the present disclosure. FIG. 33B is a schematic top-down view of the second exemplary structure of FIG. 33A. FIG. 33C is a schematic vertical cross-sectional view of a region of the second exemplary structure along the vertical plane C-C′ in FIG. 33B. FIG. 33D is a schematic vertical cross-sectional view of a region of the second exemplary structure along the vertical plane D-D′ in FIG. 33B.

FIG. 34A is a schematic vertical cross-sectional view of the second exemplary structure after formation of lateral isolation trenches according to the second embodiment of the present disclosure. FIG. 34B is a schematic top-down view of the second exemplary structure of FIG. 34A.

FIG. 35A is a schematic vertical cross-sectional view of the second exemplary structure after formation of sacrificial lateral isolation trench fill structures according to the second embodiment of the present disclosure. FIG. 35B is a schematic top-down view of the second exemplary structure of FIG. 35A.

FIG. 36A is a schematic vertical cross-sectional view of the second exemplary structure after formation of bridge recesses according to the second embodiment of the present disclosure. FIG. 36B is a schematic top-down view of the second exemplary structure of FIG. 36A.

FIG. 37A is a schematic vertical cross-sectional view of the second exemplary structure after formation of bridge structures according to the second embodiment of the present disclosure. FIG. 37B is a schematic top-down view of the second exemplary structure of FIG. 37A.

FIG. 38A is a schematic vertical cross-sectional view of the second exemplary structure after formation of voids in the access openings and the lateral isolation trenches according to the second embodiment of the present disclosure. FIG. 38B is a schematic top-down view of the second exemplary structure of FIG. 38A.

FIG. 39 is a schematic vertical cross-sectional view of the second exemplary structure after formation of laterally-extending cavities according to the second embodiment of the present disclosure.

FIG. 40A is a schematic vertical cross-sectional view of the second exemplary structure after formation of electrically conductive layers according to the second embodiment of the present disclosure. FIG. 40B is a schematic top-down view of the second exemplary structure of FIG. 40A.

FIG. 41A is a schematic vertical cross-sectional view of the second exemplary structure after formation of access opening fill structures and lateral isolation trench fill structures according to the second embodiment of the present disclosure. FIG. 41B is a schematic top-down view of the second exemplary structure of FIG. 41A.

FIG. 42A is a schematic vertical cross-sectional view of the second exemplary structure after formation of contact openings according to the second embodiment of the present disclosure. FIG. 42B is a schematic top-down view of the second exemplary structure of FIG. 42A. FIG. 42C is a schematic vertical cross-sectional view of a region of the second exemplary structure along the vertical plane C-C′ in FIG. 42B. FIG. 42D is a schematic vertical cross-sectional view of a region of the second exemplary structure along the vertical plane D - D′ in FIG. 42B.

FIG. 43A is a schematic vertical cross-sectional view of the second exemplary structure after formation of contact via structures, a connection-level dielectric layer, and connection via structures according to the second embodiment of the present disclosure. FIG. 43B is a schematic top-down view of the second exemplary structure of FIG. 43A. FIG. 43C is a schematic vertical cross-sectional view of a region of the second exemplary structure along the vertical plane C-C′ in FIG. 43B. FIG. 43D is a schematic vertical cross-sectional view of a region of the second exemplary structure along the vertical plane D-D′ in FIG. 43B.

### DETAILED DESCRIPTION

As discussed above, embodiments of the present disclosure are directed to a three-dimensional memory device including symmetric array connection strips and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

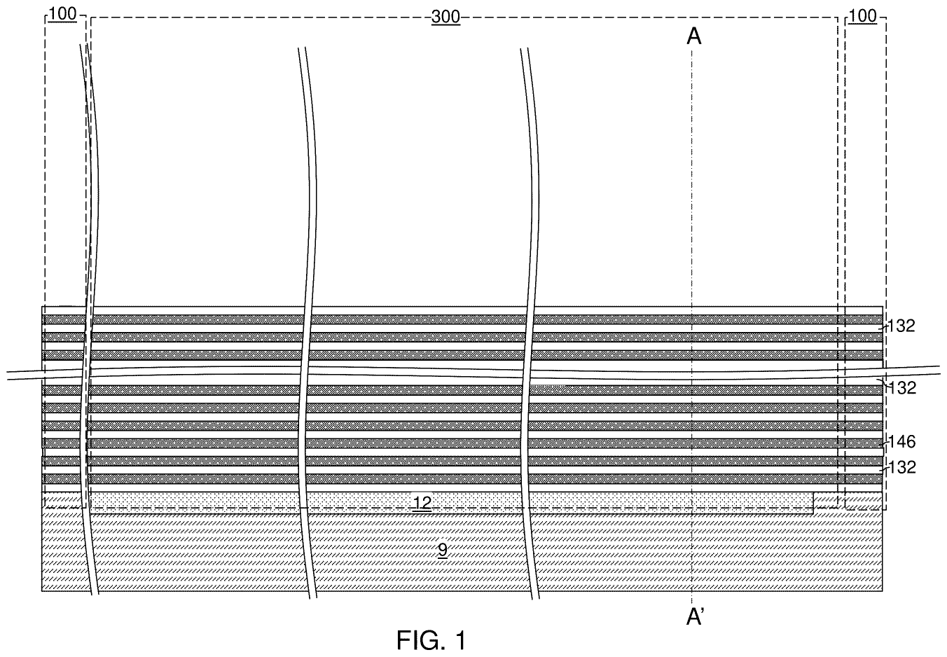

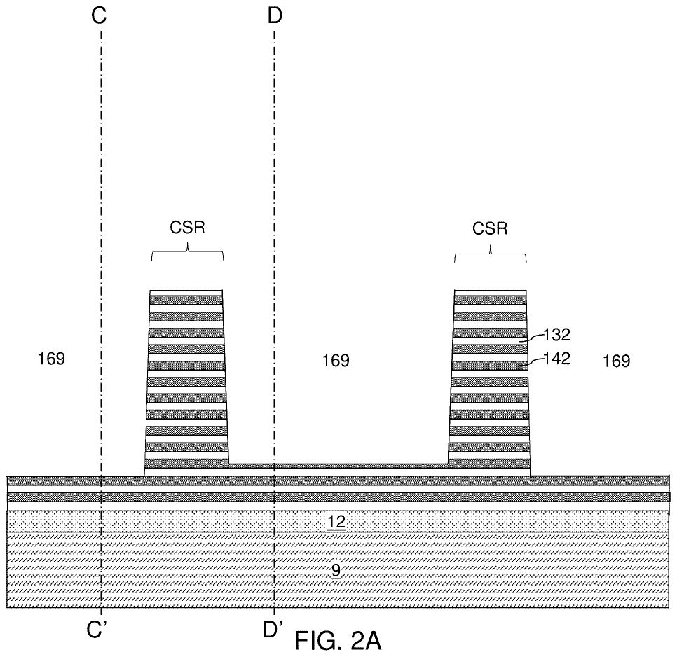

Referring to FIG. 1, a first exemplary structure for forming a semiconductor die is illustrated. The first exemplary structure comprises a substrate 9, an optional etch-stop dielectric layer 12 that is formed on a top surface of the substrate 9, and a vertically alternating sequence of first-tier continuous insulating layers 132 and first-tier continuous sacrificial material layers 142 that is formed over the etch-stop dielectric layer 12. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. The first-tier continuous insulating layers 132 may also be referred to as first-tier continuous insulating layers 132. The first-tier continuous sacrificial material layers 142 may also be referred to as first-tier continuous sacrificial material layers 142.

The first-tier continuous insulating layers 132 can be composed of the first material, and the first-tier continuous sacrificial material layers 142 can be composed of the second material, which is different from the first material. Each of the first-tier continuous insulating layers 132 is a continuous insulating layer that continuously extends over the entire area of the substrate 9, and may have a uniform thickness throughout. Each of the first-tier continuous sacrificial material layers 142 includes a sacrificial material (which may comprise a dielectric material), and continuously extends over the entire area of the substrate 9, and may have a uniform thickness throughout. Insulating materials that may be used for the first-tier continuous insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier continuous insulating layers 132 may be silicon oxide.

The second material of the first-tier continuous sacrificial material layers 142 is a sacrificial material that may be removed selectively to the first material of the first-tier continuous insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material. In one embodiment, the first-tier continuous sacrificial material layers 142 may comprise silicon nitride. The second material of the first-tier continuous sacrificial material layers 142 may be subsequently replaced with electrically conductive electrodes which may function, for example, as control gate electrodes of a vertical NAND device.

The thickness of each first-tier continuous insulating layer 132 may be in a range from 12 nm to 50 nm, such as from 15 nm to 30 nm, although lesser and greater thicknesses may also be employed. The thickness of each first-tier continuous sacrificial material layer 142 may be in a range from 15 nm to 50 nm, such as from 20 nm to 30 nm, although lesser and greater thicknesses may also be employed. In summary, a vertically alternating sequence of unit layer stacks over a substrate. Each of the unit layer stacks comprises a first continuous insulating layer (such as a first-tier continuous insulating layer 132) and a first spacer material layer (such as a first-tier continuous sacrificial material layer 142). Generally, the first spacer material layers are formed as, or are subsequently replaced with, first-tier electrically conductive layers. While an embodiment is described in which the first spacer material layers are formed as first-tier continuous sacrificial material layers 142 that are subsequently replaced with first-tier electrically conductive layers, alternative embodiments are expressly contemplated herein in which the first spacer material layers are formed as first-tier electrically conductive layers. In such embodiments, steps for replacing the material of the first spacer material layers with an electrically conductive material can be omitted. The first exemplary structure may comprise a first memory array region 100, a second memory array region 100 that is laterally spaced from the first memory array region 100, and an inter-array region 300 located between the first memory array region 100 and the second memory array region 100.

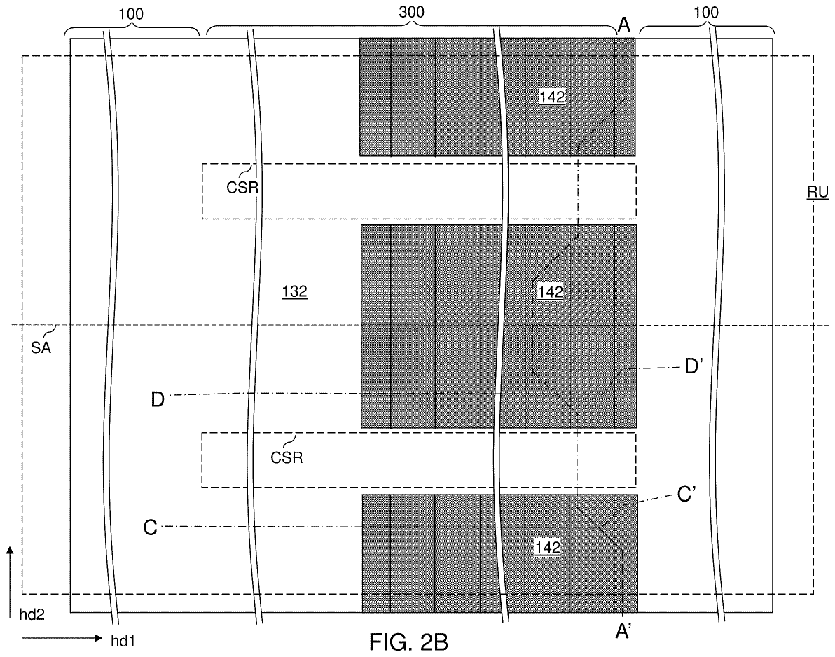

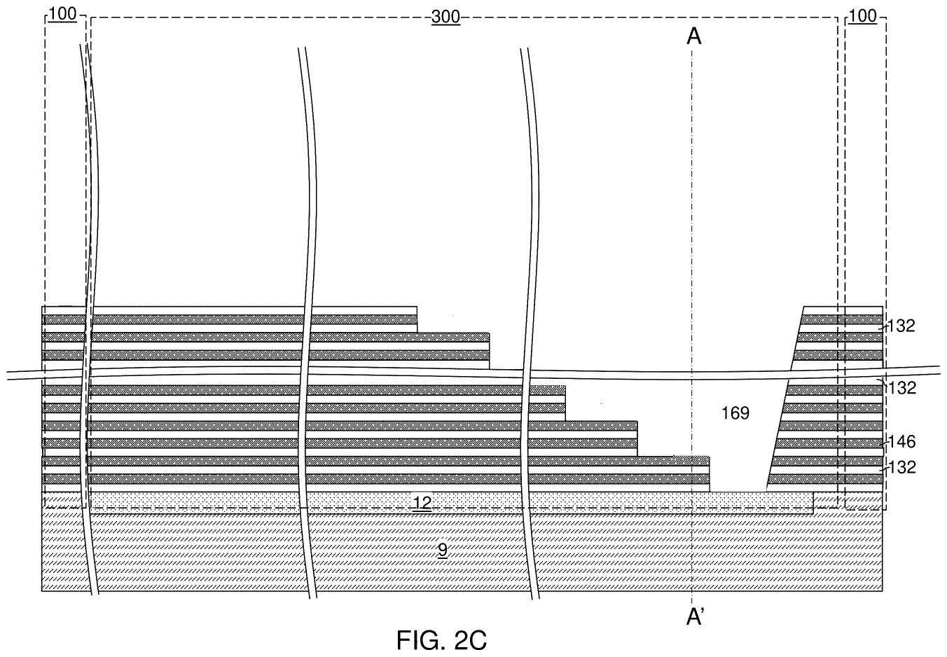

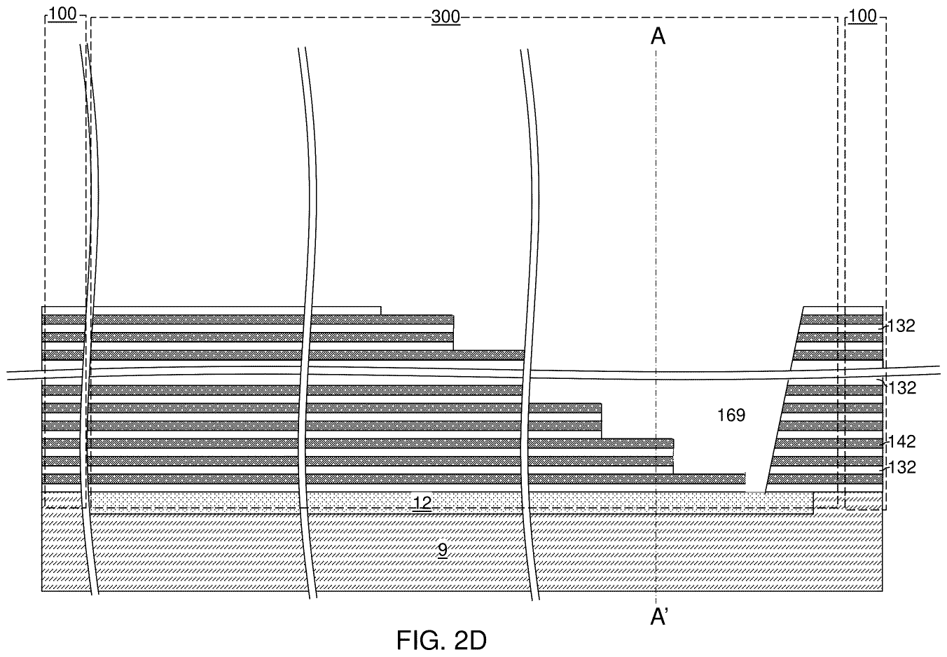

Referring to FIGS. 2A-2D, first-tier stepped cavities 169 can be formed over each contiguous set of stepped surfaces of the first-tier vertically alternating sequence (132, 142). The second memory array region 100 may be laterally spaced from the first memory array region 100 along a first horizontal direction (e.g., word line direction) hd1. The inter-array region 300 is located between the first memory array region 100 and the second memory array region 100. A plurality of first-tier stepped cavities 169 can be formed in the inter-array region 300 such that the first-tier stepped cavities 169 are laterally spaced apart from each other along a second horizontal direction (e.g., bit line direction) hd2 that is perpendicular to the first horizontal direction hd1. Within each first-tier stepped cavity 169, the lateral extents of the first-tier continuous sacrificial material layers 142 along the first horizontal direction hd1 vary (e.g., decrease) with a vertical distance from the substrate 9.

The first-tier vertically alternating sequence comprises a plurality of connection strip regions CSR (e.g., word line bridge regions) that are laterally interlaced with the first-tier stepped cavities 169 along the second horizontal direction hd2. The CSR may include all or at least 80% of the continuous sacrificial material layers 142 in the first-tier vertically alternating sequence (132, 142). Each CSR continuously extends from the first memory array region 100 to the second memory array region 100 through the inter-array region 300. In other words, each of the continuous sacrificial material layers 142 in the CSR extends continuously from the first memory array region 100 to the second memory array region 100 through the inter-array region 300.

In one embodiment, the levels of the horizontally-extending surfaces of the stepped surfaces of the first-tier stepped cavities 169 may be vertically offset for neighboring pairs of first-tier stepped cavities 169. For example, upon sequentially numbering the first-tier stepped cavities 169 along the second horizontal hd2 with positive integers beginning with 1, and upon numbering the first-tier continuous sacrificial material layers 142 from bottom to top with positive integers beginning with 1, odd-numbered first-tier stepped cavities 169 may comprise horizontal surfaces of odd-numbered first-tier continuous sacrificial material layers 142, and even-numbered first-tier stepped cavities 169 may comprise horizontal surfaces of even-numbered continuous sacrificial material layers 142. FIG. 2B illustrates a repeating unit “RU” of two memory block areas. The separate area of each memory block in the repeating unit RU is separated from the adjacent memory block area along the second horizontal direction (e.g., bit line direction) hd2 by border line “SA”.

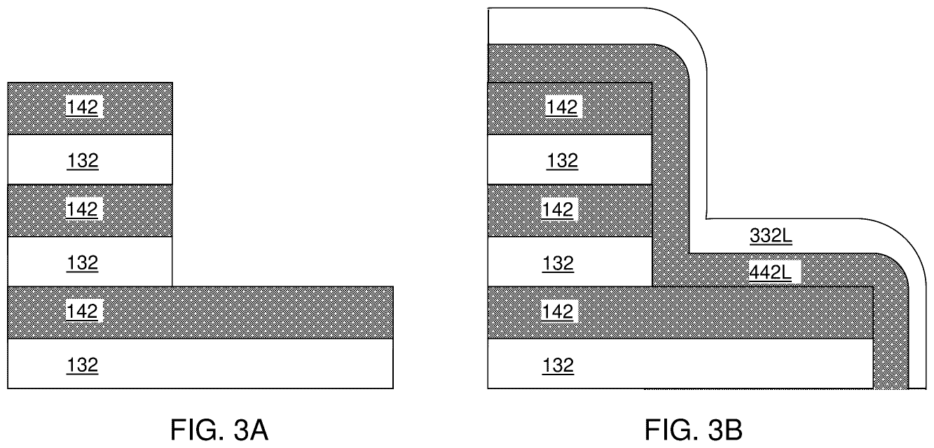

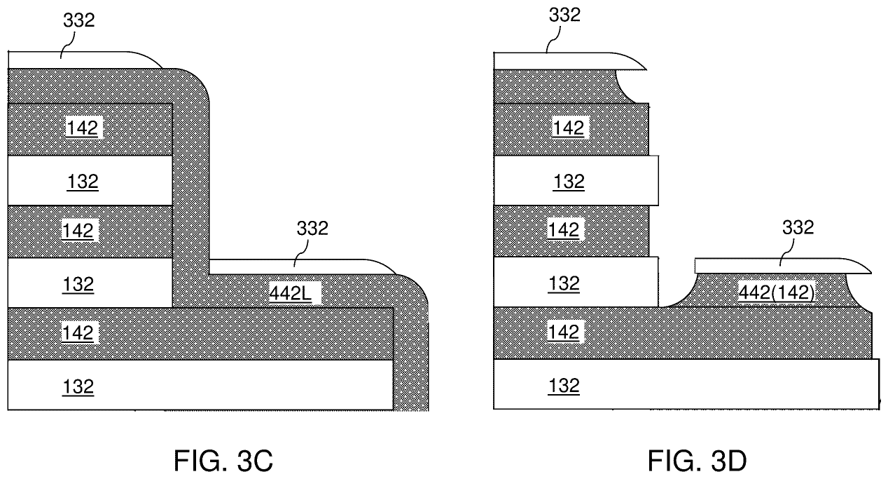

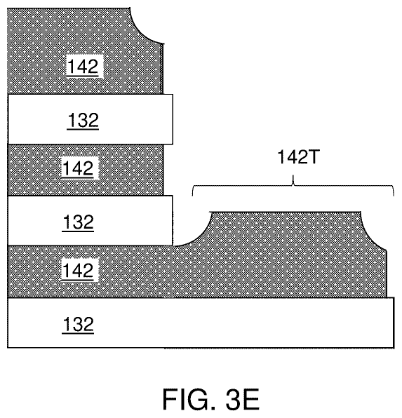

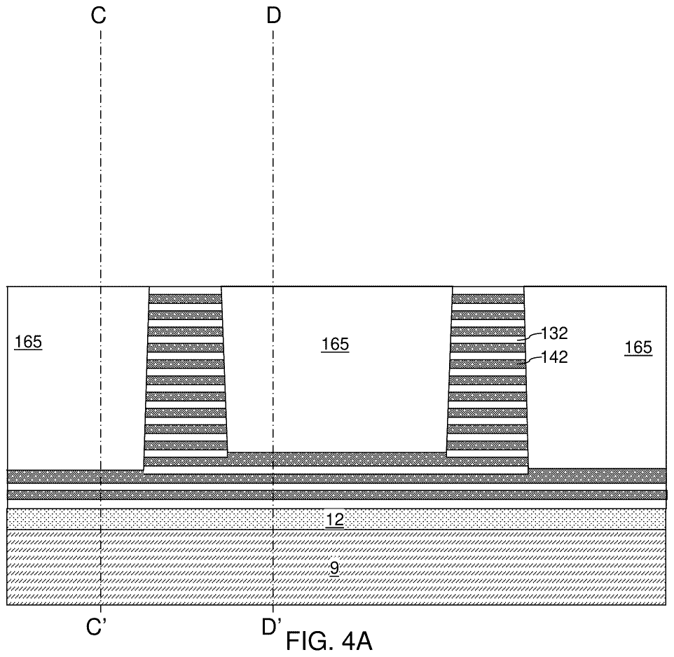

FIGS. 3A-3E are sequential vertical cross-sectional views of a region underneath a first-tier stepped cavity 169 during local thickening of the first-tier continuous sacrificial material layers 142 according to the first embodiment of the present disclosure.

Referring to FIG. 3A, a region of the first-tier stepped surfaces after the processing steps of FIGS. 2A-2D is illustrated.

Referring to FIG. 3B, an additional continuous sacrificial material layer 442L can be conformally deposited by a conformal deposition process such as a low pressure chemical vapor deposition process. The thickness of the additional continuous sacrificial material layer 442L may be in a range from 40% to 300%, such as from 60% to 150%, of the thickness of each first-tier continuous sacrificial material layer 142. The additional continuous sacrificial material layer 442L may comprise the same material as the first-tier continuous sacrificial material layers 142. For example, if the first-tier continuous sacrificial material layers 142 comprise silicon nitride, the additional continuous sacrificial material layer 442L may also comprise silicon nitride.

Subsequently, a non-conformal cover material layer 332L may be anisotropically deposited. The non-conformal cover material layer 332L may be anisotropically deposited, for example, by plasma enhanced chemical vapor deposition. The non-conformal cover material layer 332L comprises a material that can function as an etch mask material for subsequently etching unmasked portions of the additional continuous sacrificial material layer 442L. For example, the non-conformal cover material layer 332L may comprise silicon oxide. The vertical thickness of the horizontally-extending portions of the non-conformal cover material layer 332L is greater than the lateral thickness of the vertically-extending portions of the non-conformal cover material layer 332L. The difference between the vertical thickness of the horizontally-extending portions of the non-conformal cover material layer 332L and the lateral thickness of the vertically-extending portions of the non-conformal cover material layer 332L may be in a range from 1.3 to 3, such as from 1.5 to 2.

Referring to FIG. 3C, an isotropic etch process can be performed to isotropically etch the material of the non-conformal cover material layer 332L. The duration of the isotropic etch process is selected such that the etch distance of the isotropic etch process for the material of the non-conformal cover material layer 332L is greater than the lateral thickness of vertically-extending portions of the non-conformal cover material layer 332L, and is less than the vertical thickness of the horizontally-extending portions of the non-conformal cover material layer 332L. Thus, remaining horizontal portions of the non-conformal cover material layer 332L after the isotropic etch process comprise cover material plates 332 that are remaining portions of the non-conformal cover material layer 332L that overlie horizontally-extending portions of the additional continuous sacrificial material layer 442L. The cover material plates 332 have a vertical thickness that is not greater than the difference between the vertical thickness of the horizontally-extending portions of the non-conformal cover material layer 332L and the lateral thickness of vertically-extending portions of the non-conformal cover material layer 332L, and may be in a range from 10 nm to 50 nm, although lesser and greater thicknesses may also be employed.

Referring to FIG. 3D, a selective isotropic etch process can be performed to isotropically etch unmasked portions of the additional continuous sacrificial material layer 442L using the cover material plates 332 as a mask. Thus, the selective isotropic etch process does not significantly etch the materials of cover material plates 332 and the first-tier continuous insulating layers 132. The duration of the selective isotropic etch process may be selected such that the etch distance of the selective isotropic etch process for the material of the additional continuous sacrificial material layer 442L is not less than the uniform thickness of the additional continuous sacrificial material layer 442L. Thus, the exposed vertically-extending portions of the additional continuous sacrificial material layer 442L are removed by the selective isotropic etch process, while remaining horizontally-extending portions of the additional continuous sacrificial material layer 442L that are covered by a respective one of the cover material plates 332 are not significantly etched. The remaining horizontally-extending portions of the additional continuous sacrificial material layer 442L comprise sacrificial material plates 442, which are incorporated into a respective one of the first-tier continuous sacrificial material layers 142.

Referring to FIG. 3E, a selective etch process may be optionally performed to remove the cover material plates 332 without removing the materials of the sacrificial material plates 442 or the first-tier continuous sacrificial material layers 142. The material of sacrificial material plates 442 may be the same as the material of the first-tier continuous sacrificial material layers 142. Thus, the first-tier continuous sacrificial material layers 142 incorporate the sacrificial material plates 442, and are locally thickened in the regions of the first stepped surfaces. According to an aspect of the present disclosure, each first-tier continuous sacrificial material layer 142 comprises a respective locally thickened portion 142T underneath each first-tier stepped cavity 169.

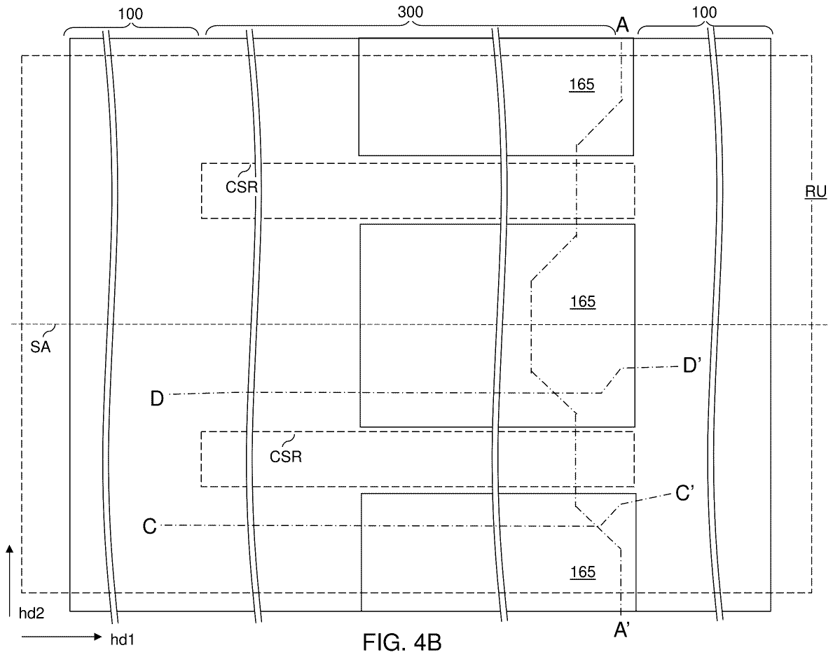

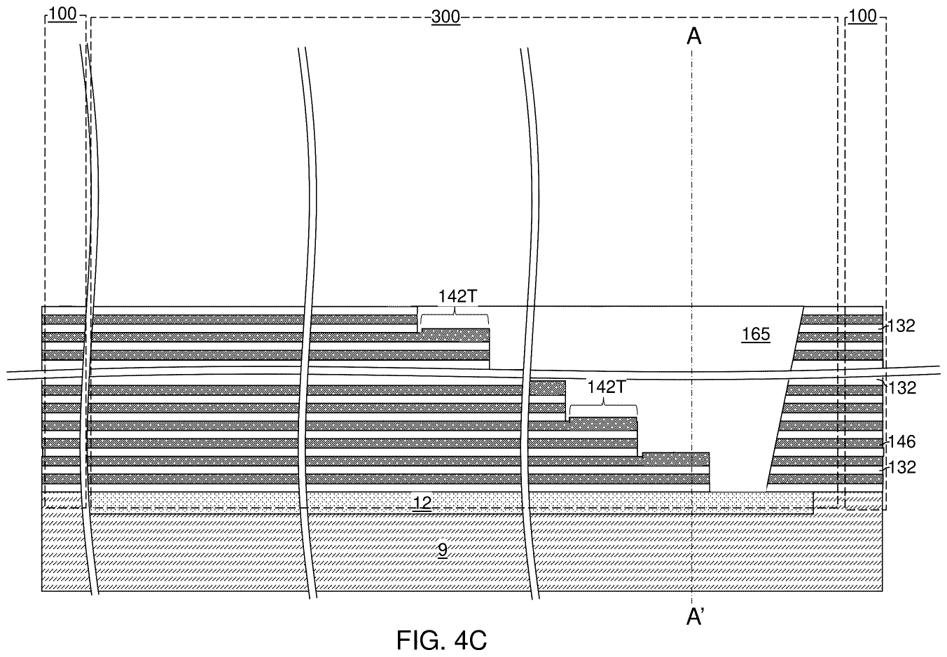

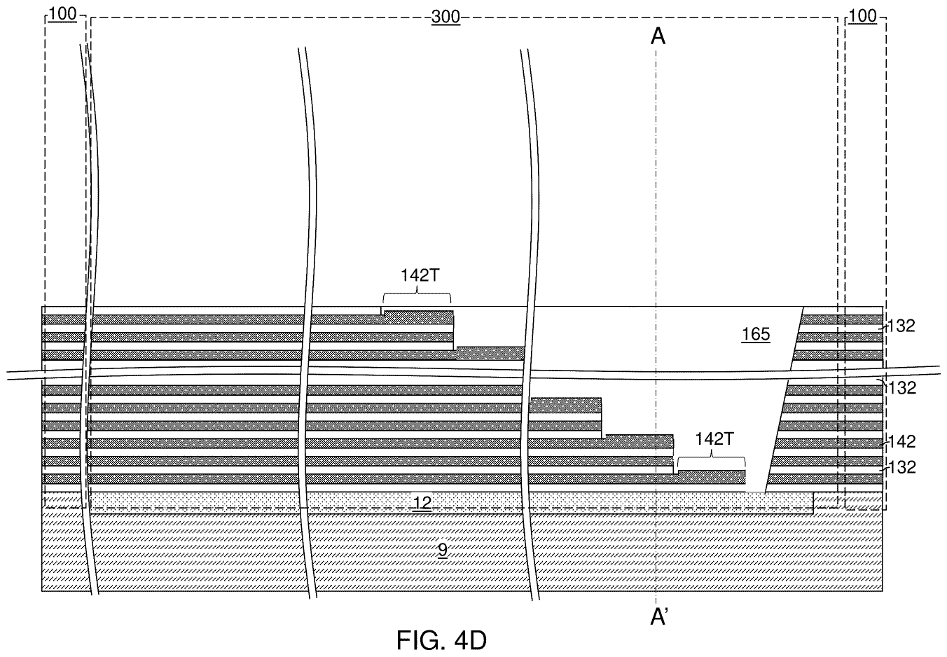

Referring to FIGS. 4A-4D, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first-tier vertically alternating sequence (132, 142). Each remaining portion of the first dielectric fill material that fills a respective first-tier stepped cavity 169 constitutes a first-tier retro-stepped dielectric material portion 165. Thus, the first-tier retro-stepped dielectric material portions 165 can be formed in the inter-array region 300. The first-tier retro-stepped dielectric material portions 165 are subsequently modified, and as such, may also be referred to as in-process first-tier retro-stepped dielectric material portions 165.

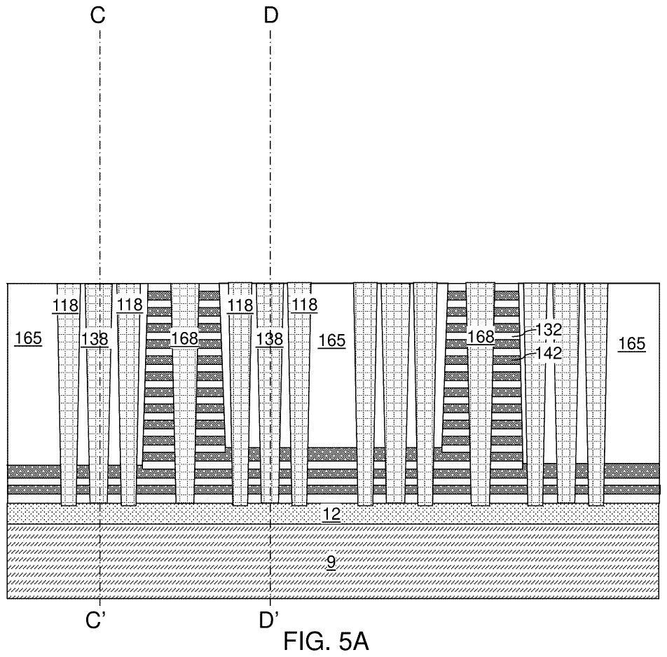

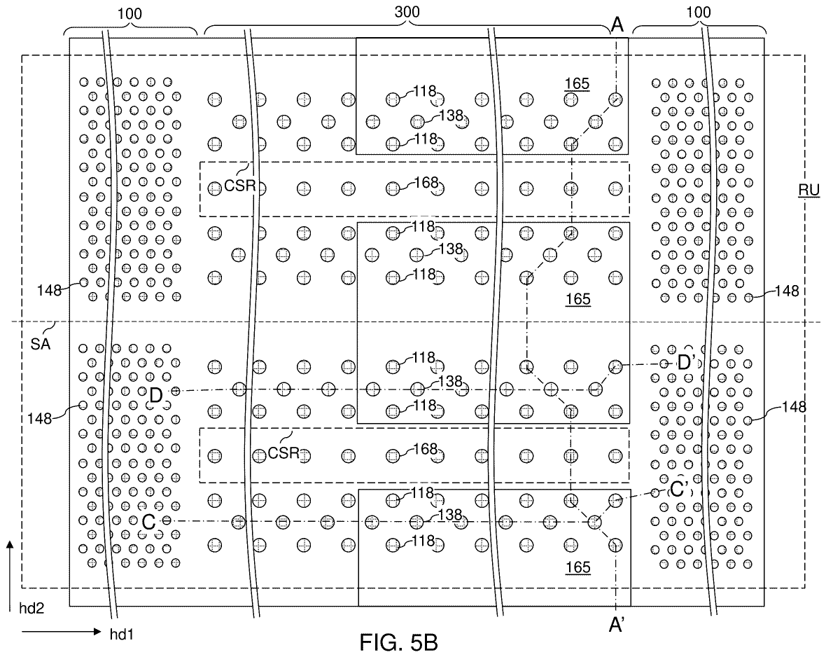

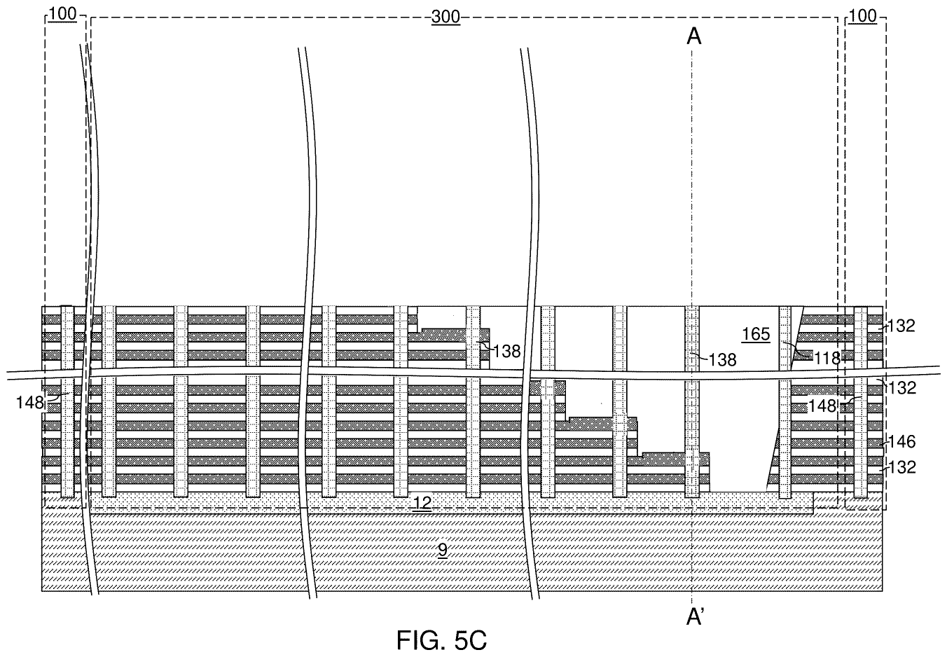

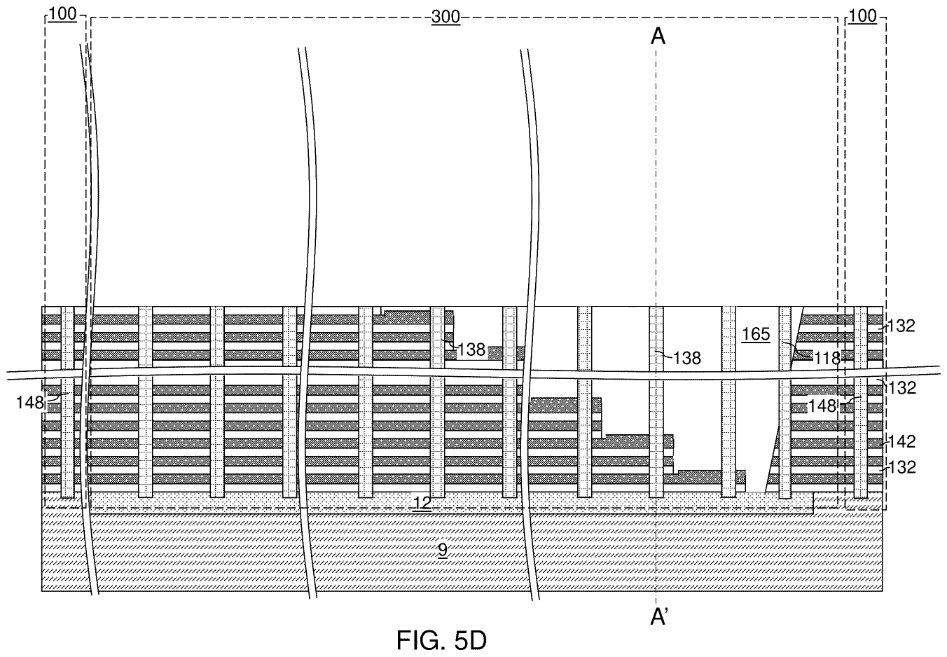

Referring to FIGS. 5A-5D, various first-tier openings may be formed through the first-tier vertically alternating sequence (132, 142) and into the substrate 9. A photoresist layer (not shown) may be applied over the first-tier vertically alternating sequence (132, 142), and may be lithographically patterned to form various openings therethrough. The pattern of openings in the photoresist layer may be transferred through the first-tier vertically alternating sequence (132, 142) and into the substrate 9 by a first anisotropic etch process to form the various first-tier openings concurrently. The various first-tier openings may include first-tier memory openings formed in the memory array regions 100, first-tier support openings and first-tier contact openings that vertically extend through the in-process first-tier retro-stepped dielectric material portions 165 and underlying portions of the first-tier vertically alternating sequence (132, 142), and first-tier access openings formed in the connection strip regions CSR. Each cluster of first-tier memory openings may be formed as a two-dimensional array of first-tier memory openings. The first-tier support openings are openings that are formed in the inter-array region 300 through a respective one of the in-process first-tier retro-stepped dielectric material portions 165, and are subsequently employed to form support pillar structures. Each first-tier contact opening is formed in a respective area in which a respective layer contact via structure is to be subsequently formed. A subset of the first-tier contact openings can be formed through a locally thickened portion 142T of a respective first-tier continuous sacrificial material layer 142 located under the first-tier retro-stepped dielectric material portion 165. Each first-tier access opening is formed in a respective connection strip region CSR.

Sacrificial first-tier opening fill structures (148, 118, 138, 168) may be formed in the various first-tier openings. For example, a sacrificial first-tier fill material is concurrently deposited in each of the first-tier openings. The sacrificial first-tier fill material includes a material that may be subsequently removed selectively to the materials of the first-tier continuous insulating layers 132 and the first-tier continuous sacrificial material layers 142. In one embodiment, the sacrificial first-tier fill material may include a semiconductor material, such as silicon (e.g., amorphous silicon or polysilicon), silicon-germanium, germanium, a III-V compound semiconductor material, or a combination thereof. Optionally, a thin etch stop liner (such as a silicon oxide layer having a thickness in a range from 1 nm to 3 nm) may be used prior to depositing the sacrificial first-tier fill material. The sacrificial first-tier fill material may be formed by a non-conformal deposition or a conformal deposition method.

Portions of the deposited sacrificial first-tier fill material may be removed from above the topmost layer of the first-tier vertically alternating sequence (132, 142). Remaining portions of the sacrificial first-tier fill material comprise sacrificial first-tier opening fill structures (148, 118, 138, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure 118. Each remaining portion of the sacrificial first-tier fill material in a first-tier contact opening constitutes a sacrificial first-tier contact opening fill structure 138. Each remaining portion of the sacrificial first-tier fill material in a first-tier access opening constitutes a sacrificial first-tier access opening fill structure 168. The various sacrificial first-tier opening fill structures (148, 118, 138, 168) are concurrently formed, i.e., during a same set of processes including the deposition process that deposits the sacrificial first-tier fill material and the planarization process that removes the deposited material from above the first-tier vertically alternating sequence (132, 142). The top surfaces of the sacrificial first-tier opening fill structures (148, 118, 138, 168) may be coplanar with the topmost surface of the first-tier vertically alternating sequence (132, 142). Each of the sacrificial first-tier opening fill structures (148, 118, 138, 168) may optionally include cavities therein. The set of all structures located between the bottommost surface of the first-tier vertically alternating sequence (132, 142) and the topmost surface of the first-tier vertically alternating sequence (132, 142) or embedded within the first-tier vertically alternating sequence (132, 142) constitutes a first-tier structure.

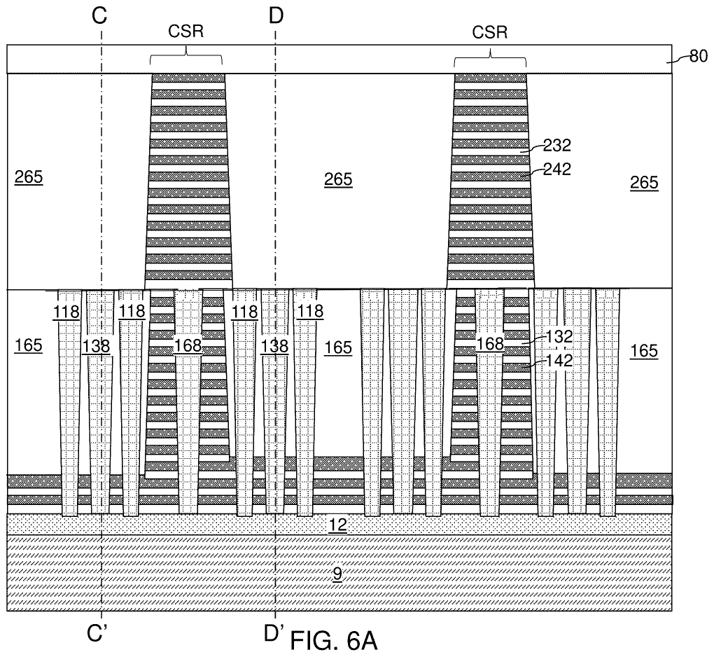

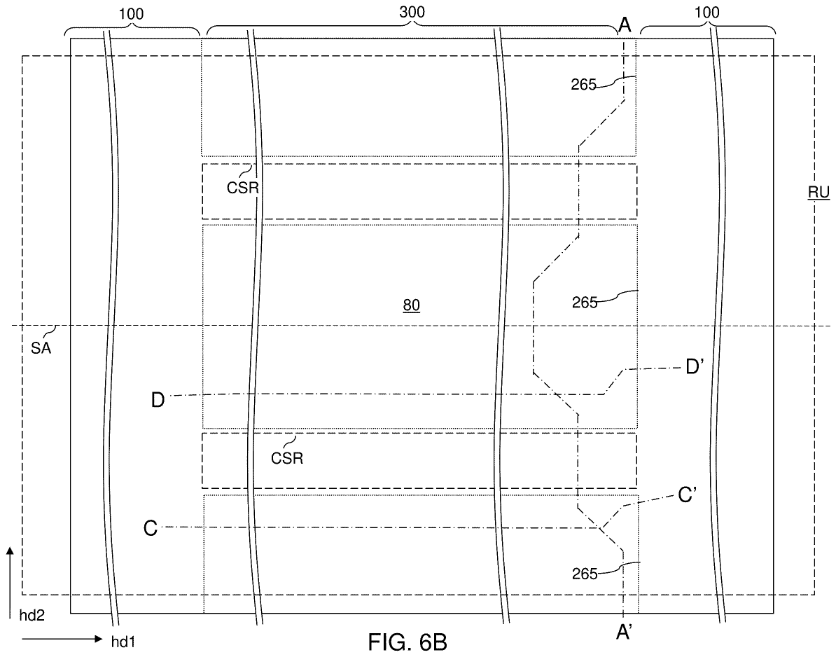

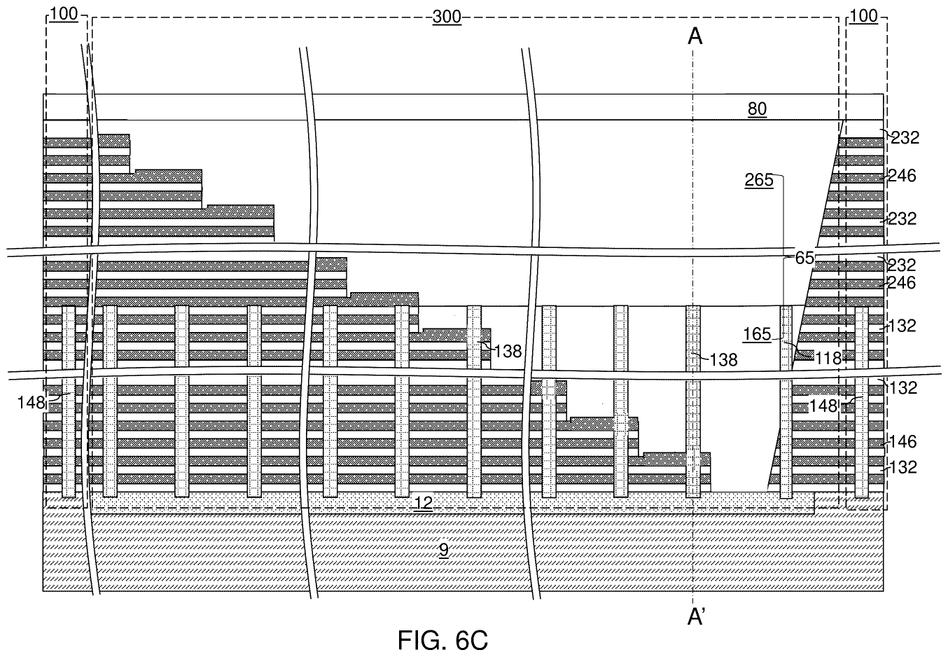

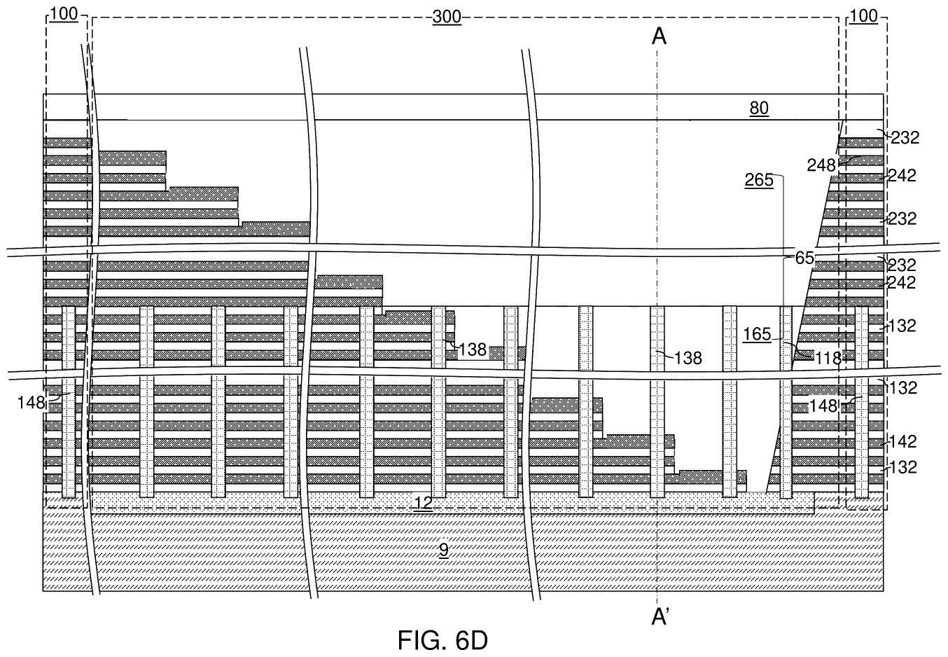

Referring to FIGS. 6A-6D, the processing steps described with reference to FIGS. 1-4D may be performed with any needed changes to form a second-tier vertically alternating sequence of second-tier continuous insulating layers 232 and second-tier continuous sacrificial material layers 242, second-tier stepped cavities, and second-tier retro-stepped dielectric material portions 265. Each second-tier stepped cavity may comprise a respective set of second-tier stepped surfaces that is laterally offset from the set of first-tier stepped surfaces of a respective underlying first-tier stepped cavity (which is filled with a respective in-process first-tier retro-stepped dielectric material portion 165). A dielectric fill material can be deposited in each of the second-tier stepped cavities to form second-tier retro-stepped dielectric material portions 265. The second-tier retro-stepped dielectric material portions 265 are modified in subsequent processing steps. As such, the second-tier retro-stepped dielectric material portions 265 are herein referred to as in-process second-tier retro-stepped dielectric material portions 265. A contact-level dielectric layer 80 can be formed over the second-tier vertically alternating sequence (232, 242) and the in-process second-tier retro-stepped dielectric material portions 265.

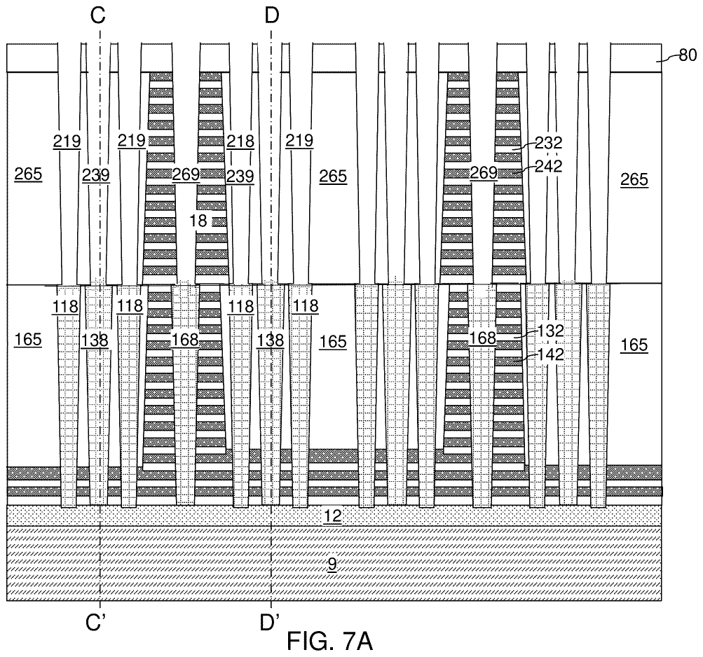

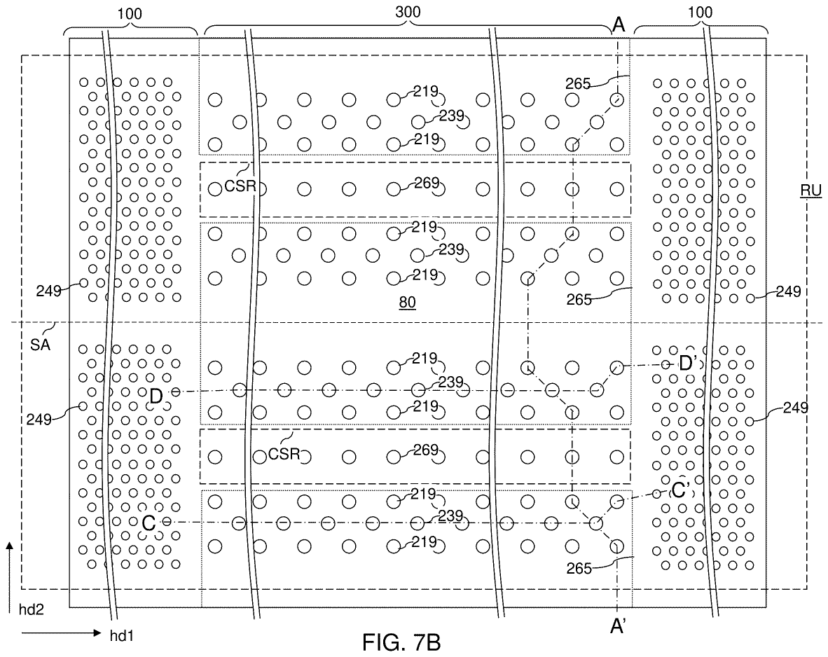

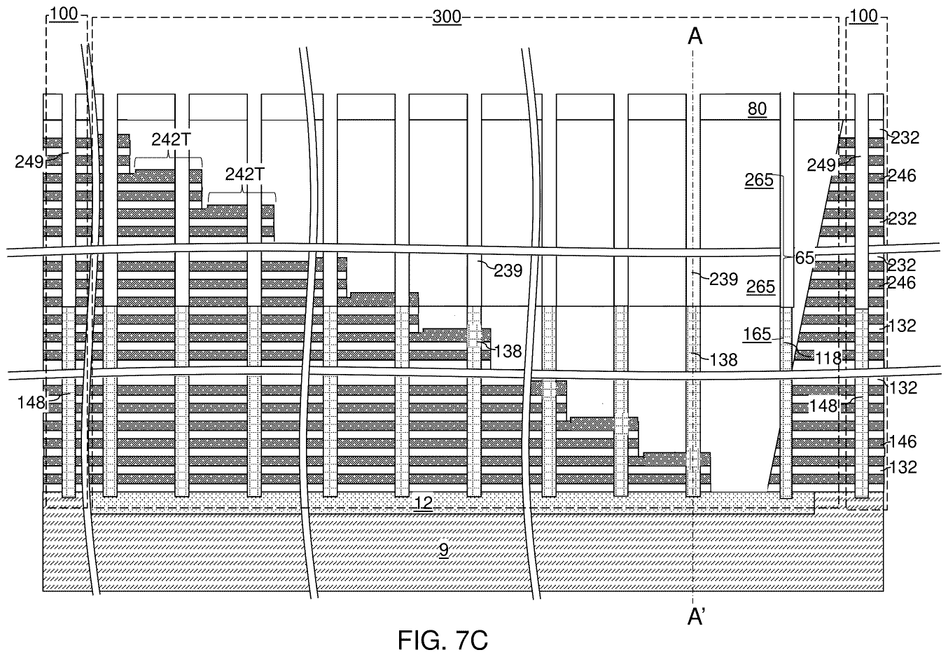

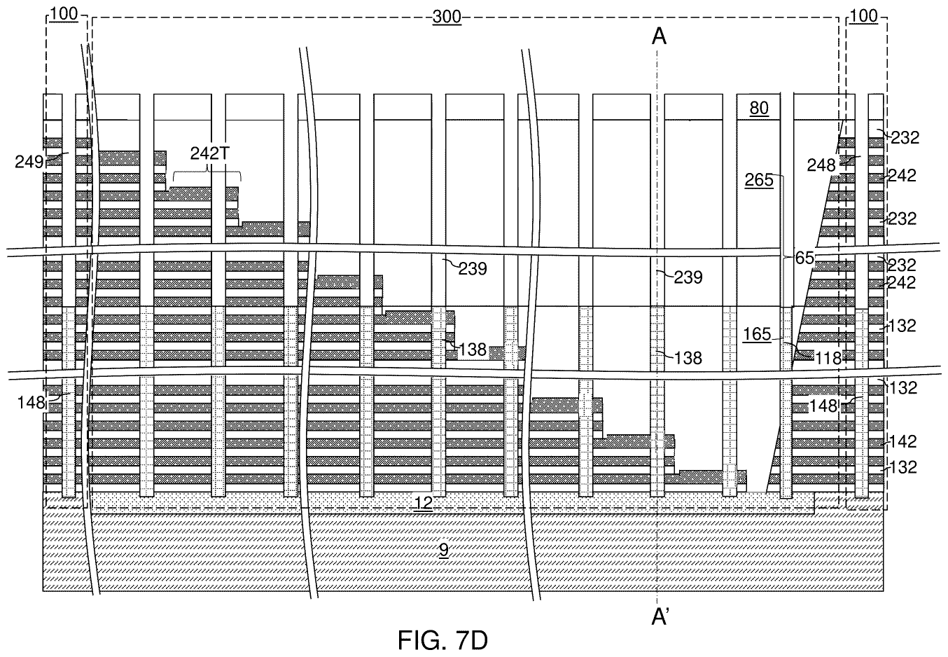

Referring to FIGS. 7A-7D, various second-tier openings may be formed through the contact-level dielectric layer 80, the second-tier vertically alternating sequence (232, 242), and the in-process second-tier retro-stepped dielectric material portions 265. A photoresist layer (not shown) may be applied over the contact-level dielectric layer 80, and may be lithographically patterned to form various openings therethrough. The pattern of openings in the photoresist layer may be the same as the pattern of the sacrificial first-tier opening fill structures (148, 118, 138, 168). The pattern of the openings in the photoresist layer can be transferred through the contact-level dielectric layer 80, the second-tier vertically alternating sequence (232, 242), and the in-process second-tier retro-stepped dielectric material portions 265 by a second anisotropic etch process to form the various second-tier openings concurrently. The various second-tier openings may include second-tier memory openings 249 formed in the memory array regions 100, second-tier support openings 219 and second-tier contact openings 239 that vertically extend through the in-process second-tier retro-stepped dielectric material portions 265 and underlying portions of the second-tier vertically alternating sequence (232, 242), and second-tier access openings 269 formed in the connection strip regions CSR. Each cluster of second-tier memory openings 249 may be formed as a two-dimensional array of second-tier memory openings. The second-tier support openings 219 are openings that are formed in the inter-array region 300 through a respective one of the in-process second-tier retro-stepped dielectric material portions 265, and are subsequently employed to form support pillar structures. Each second-tier contact opening 239 is formed in a respective area in which a respective layer contact via structure is to be subsequently formed. Each second-tier access opening 269 is formed in a respective connection strip region CSR.

According to an aspect of the present disclosure, each second-tier continuous sacrificial material layer 242 comprises a respective locally thickened portion 242T underneath each second-tier retro-stepped dielectric material portion 265. A subset of the second-tier contact openings 239 can be formed through a locally thickened portion 242T of a respective second-tier continuous sacrificial material layer 242.

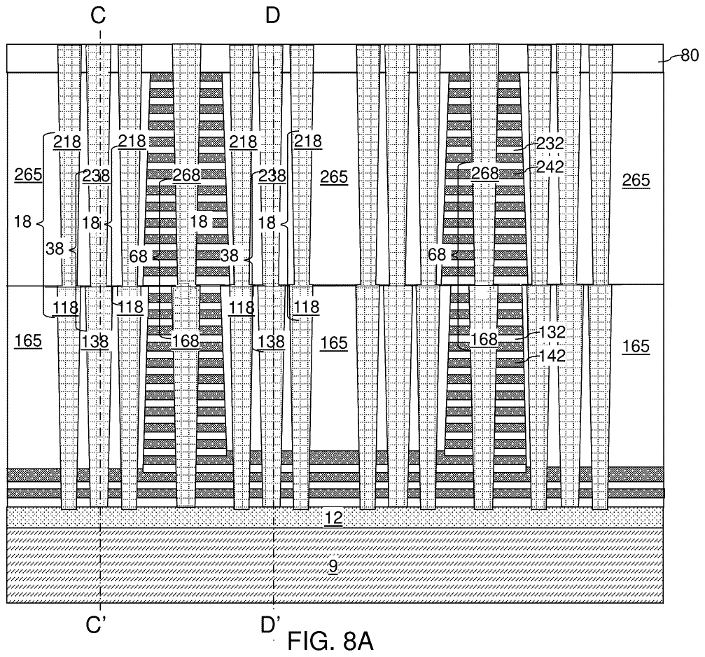

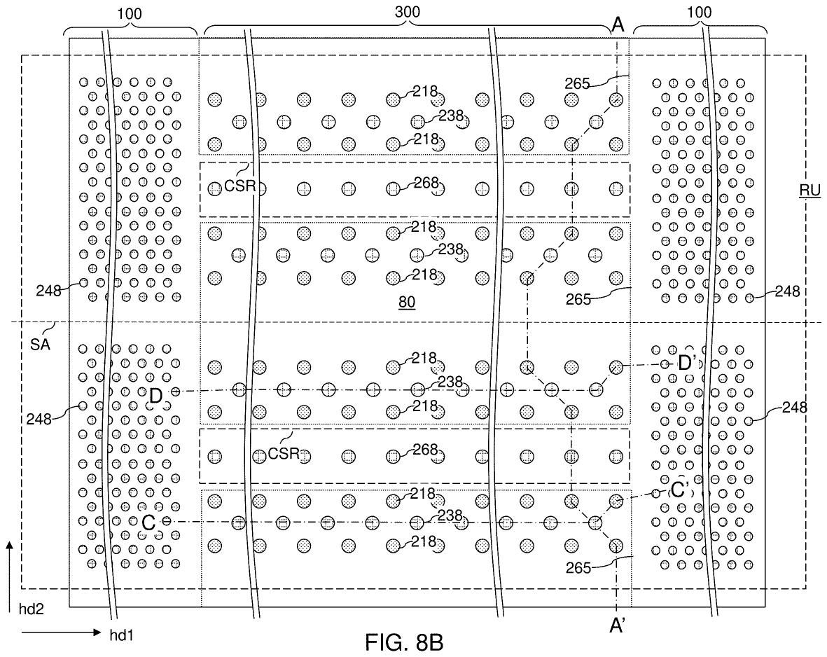

Referring to FIGS. 8A-8D, sacrificial second-tier opening fill structures (248, 218, 238, 268) may be formed in the various respective second-tier openings (249, 219, 239, 269). For example, a sacrificial second-tier fill material is concurrently deposited in each of the second-tier openings (249, 219, 239, 269). The sacrificial second-tier fill material includes a material that may be subsequently removed selectively to the materials of the second-tier continuous insulating layers 232 and the second-tier continuous sacrificial material layers 242. In one embodiment, the sacrificial second-tier fill material may be the same as the sacrificial first-tier fill material described above. The sacrificial second-tier fill material may be formed by a non-conformal deposition or a conformal deposition method.

Portions of the deposited sacrificial second-tier fill material may be removed from above the contact-level dielectric layer 80. Remaining portions of the sacrificial second-tier fill material comprise sacrificial second-tier opening fill structures (248, 218, 238, 268). Specifically, each remaining portion of the sacrificial second-tier fill material in a second-tier memory opening 249 constitutes a sacrificial second-tier memory opening fill structure 248. Each remaining portion of the sacrificial second-tier fill material in a second-tier support opening 219 constitutes a sacrificial second-tier support opening fill structure 218. Each remaining portion of the sacrificial second-tier fill material in a second-tier contact opening 239 constitutes a sacrificial second-tier contact opening fill structure 238. Each remaining portion of the sacrificial second-tier fill material in a second-tier access opening 269 constitutes a sacrificial second-tier access opening fill structure 268.

The various sacrificial second-tier opening fill structures (248, 218, 238, 268) are concurrently formed, i.e., during a same set of processes including the deposition process that deposits the sacrificial second-tier fill material and the planarization process that removes the second-tier deposition process from above the second-tier vertically alternating sequence (232, 242). The top surfaces of the sacrificial second-tier opening fill structures (248, 218, 238, 268) may be coplanar with the topmost surface of the contact-level dielectric layer 80. Each of the sacrificial second-tier opening fill structures (248, 218, 238, 268) may optionally include cavities therein. The set of all structures located between the bottommost surface of the second-tier vertically alternating sequence (232, 242) and the topmost surface of the second-tier vertically alternating sequence (232, 242) or embedded within the second-tier vertically alternating sequence (232, 242) constitutes a second-tier structure.

The sacrificial first-tier memory opening fill structures 148 and the sacrificial second-tier memory opening fill structures 248 are collectively referred to as sacrificial memory opening fill structures (148, 248). The sacrificial first-tier support opening fill structures 118 and the sacrificial second-tier support opening fill structures 218 are collectively referred to as sacrificial support opening fill structures 18. The sacrificial first-tier contact opening fill structures 138 and the sacrificial second-tier contact opening fill structures 238 are collectively referred to as sacrificial contact opening fill structures 38. The sacrificial first-tier access opening fill structures 168 and the sacrificial second-tier access opening fill structures 268 are collectively referred to as sacrificial access opening fill structures 68.

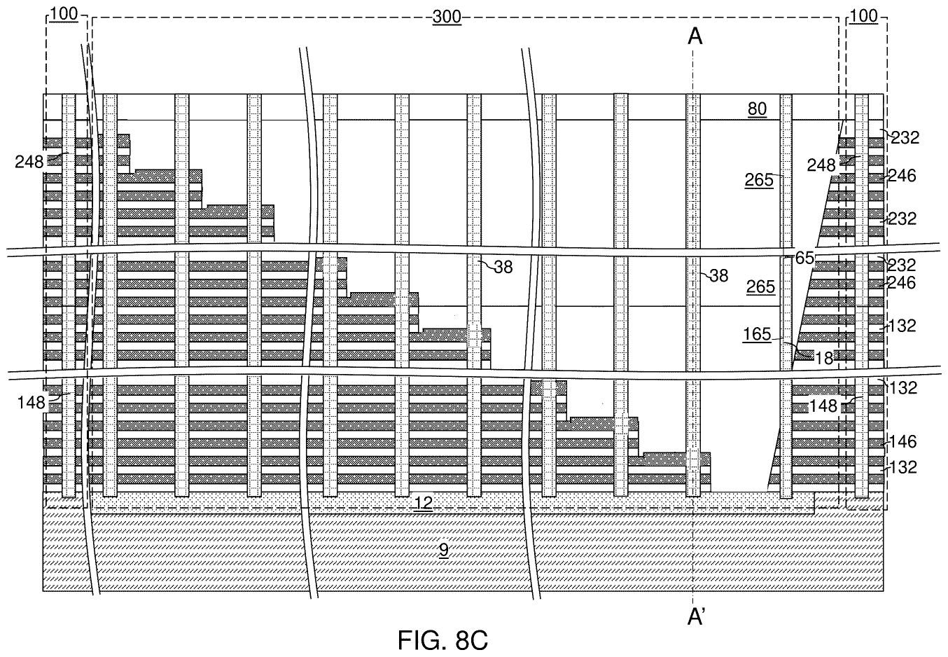

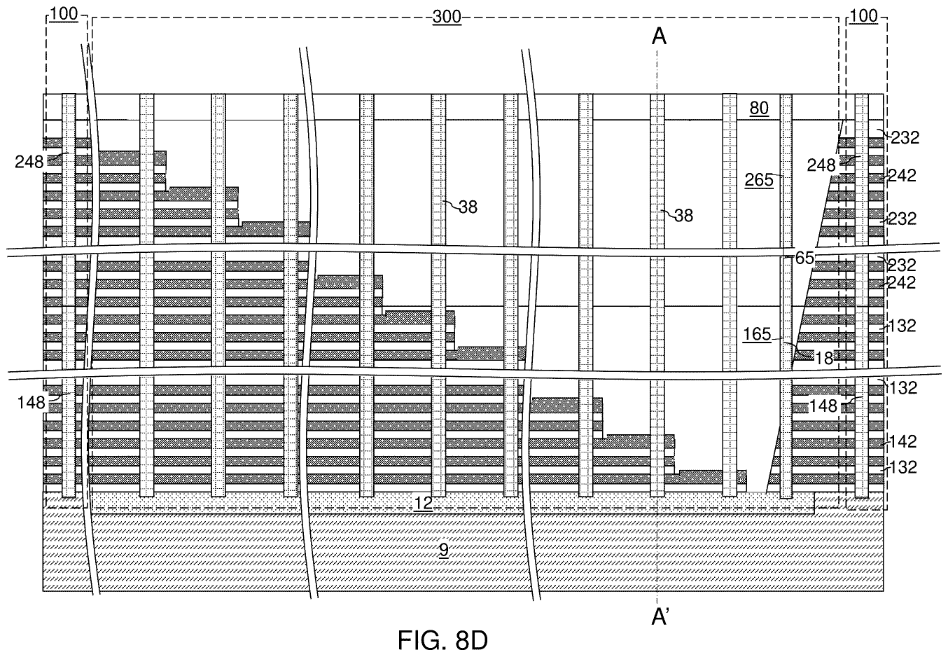

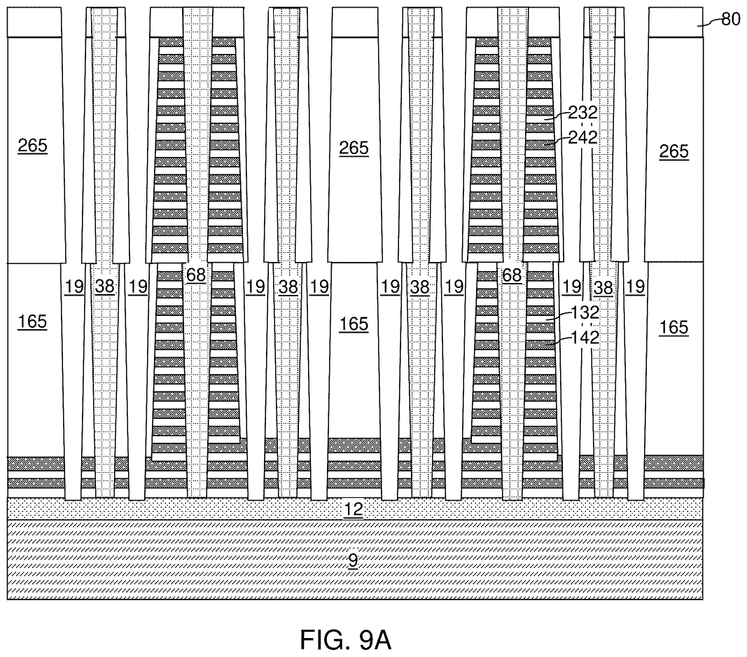

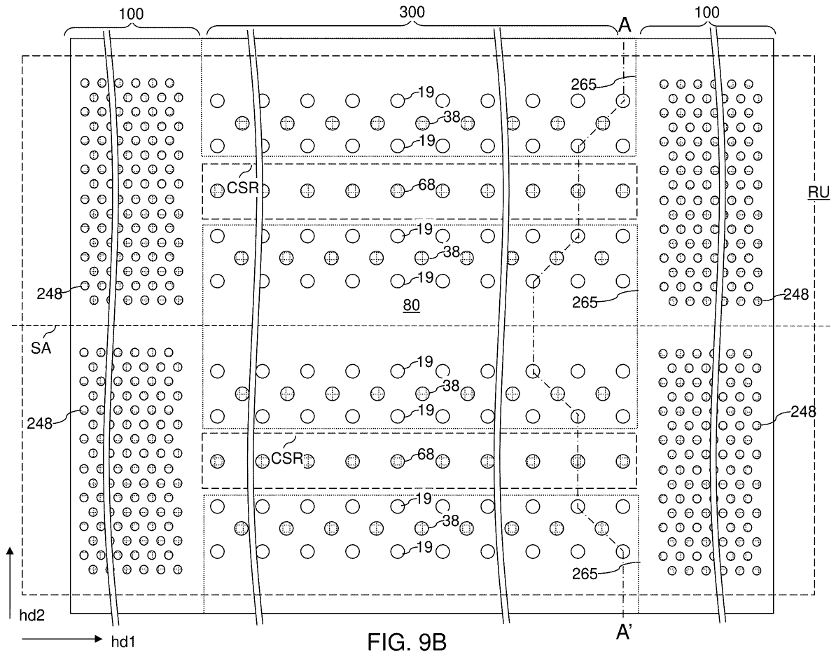

Referring to FIGS. 9A and 9B, an etch mask layer (not shown), such as a patterned photoresist layer, can be formed over the contact-level dielectric layer 80. The etch mask layer may comprise openings that overlie the sacrificial support opening fill structures 18. A selective etch process can be performed to etch the sacrificial fill materials of the sacrificial support opening fill structures 18 without etching the materials of the vertically alternating sequences {(132, 142), (232, 242)}, the in-process retro-stepped dielectric material portions (165, 265), or the etch-stop dielectric layer 12. For example, if the sacrificial support opening fill structures 18 comprise amorphous silicon, a wet etch process using hot trimethyl-2 hydroxyethyl ammonium hydroxide (“hot TMY”) or tetramethyl ammonium hydroxide (TMAH) may be performed to remove the sacrificial support opening fill structures 18. Support openings 19 are formed in the volumes from which the materials of the sacrificial support opening fill structures 18 are removed. The etch mask layer can be subsequently removed.

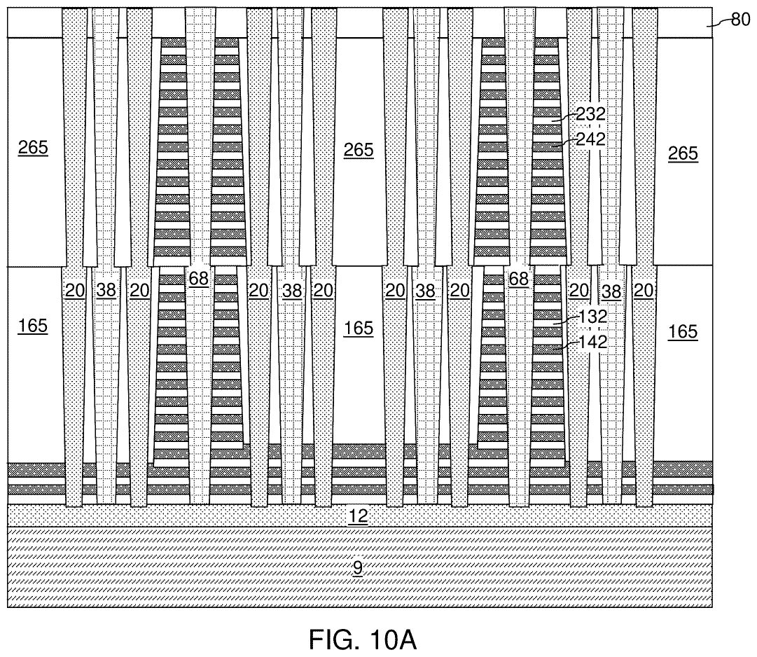

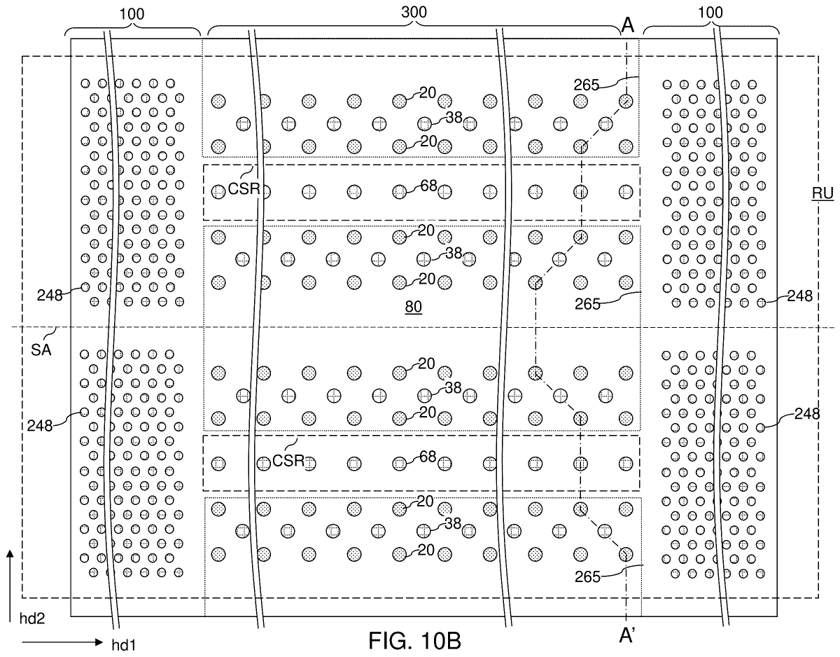

Referring to FIGS. 10A and 10B, a dielectric fill material, such as undoped silicate glass (i.e., silicon oxide) or a doped silicate glass can be deposited in the support openings 19. Excess portions of the dielectric fill material can be removed from above the horizontal plane including the top surface of the contact-level dielectric layer 80. Remaining portions of the dielectric fill material that fill the support openings 19 constitute support pillar structures 20, which are dielectric pillar structures.

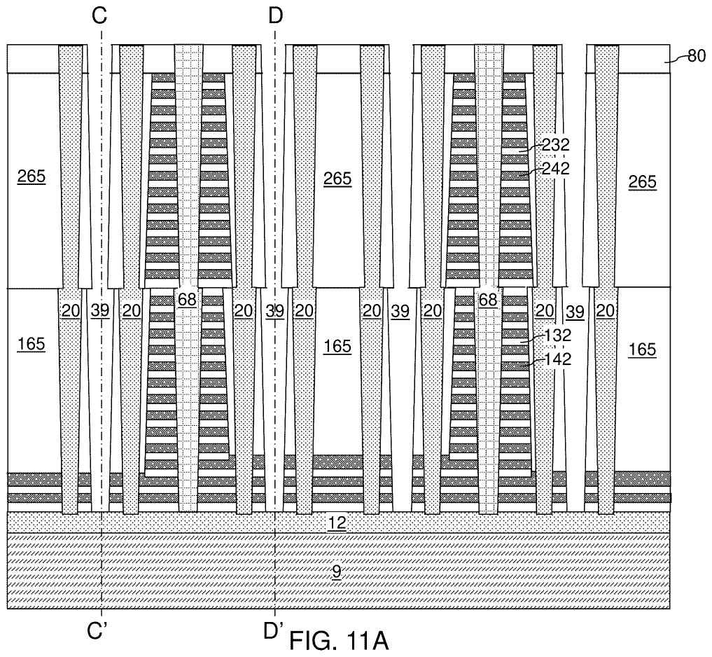

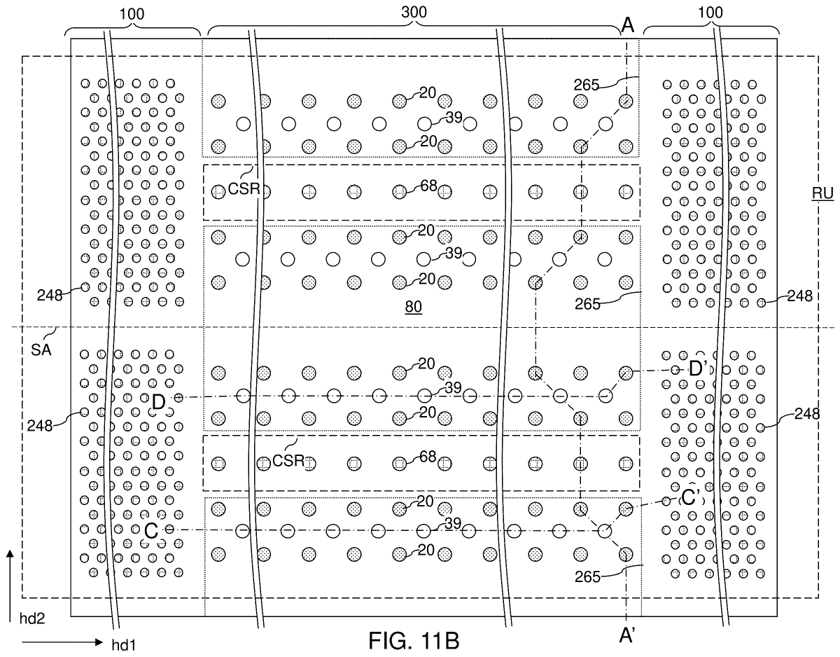

Referring to FIGS. 11A-11D, an etch mask layer (not shown) such as a patterned photoresist layer can be formed over the contact-level dielectric layer 80. The etch mask layer may comprise openings that overlie the sacrificial contact opening fill structures 38. A selective etch process can be performed to etch the sacrificial fill materials of the sacrificial contact opening fill structures 38 without etching the materials of the vertically alternating sequences {(132, 142), (232, 242)}, the in-process retro-stepped dielectric material portions (165, 265), or the etch-stop dielectric layer 12. For example, if the sacrificial contact opening fill structures 38 comprise amorphous silicon, a wet etch process using hot trimethyl-2 hydroxyethyl ammonium hydroxide (“hot TMY”) or tetramethyl ammonium hydroxide (TMAH) may be performed to remove the sacrificial contact opening fill structures 38. Contact openings 39 are formed in the volumes from which the materials of the sacrificial support opening fill structures 18 are removed. The etch mask layer can be subsequently removed.

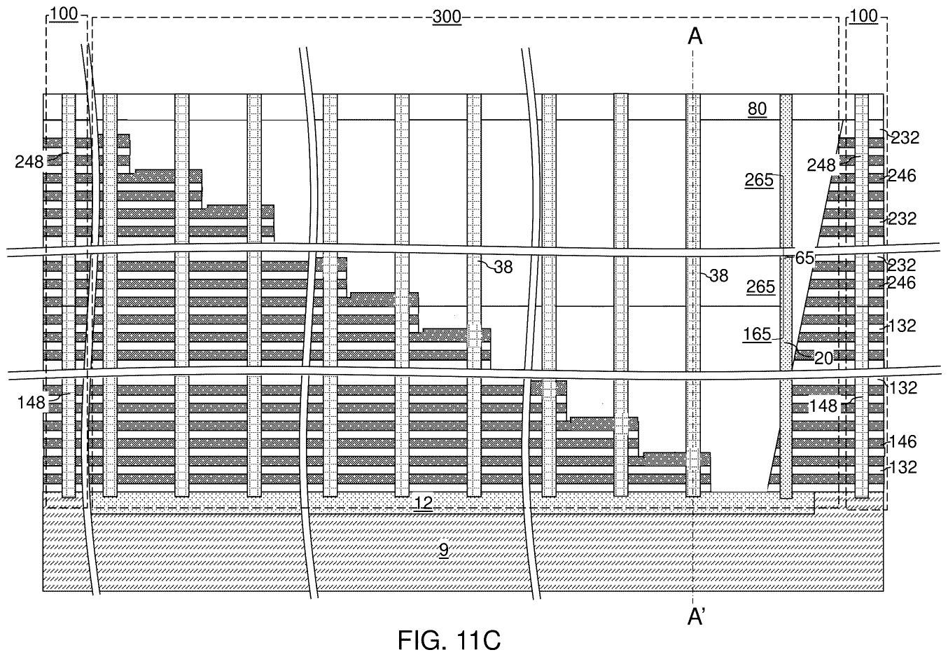

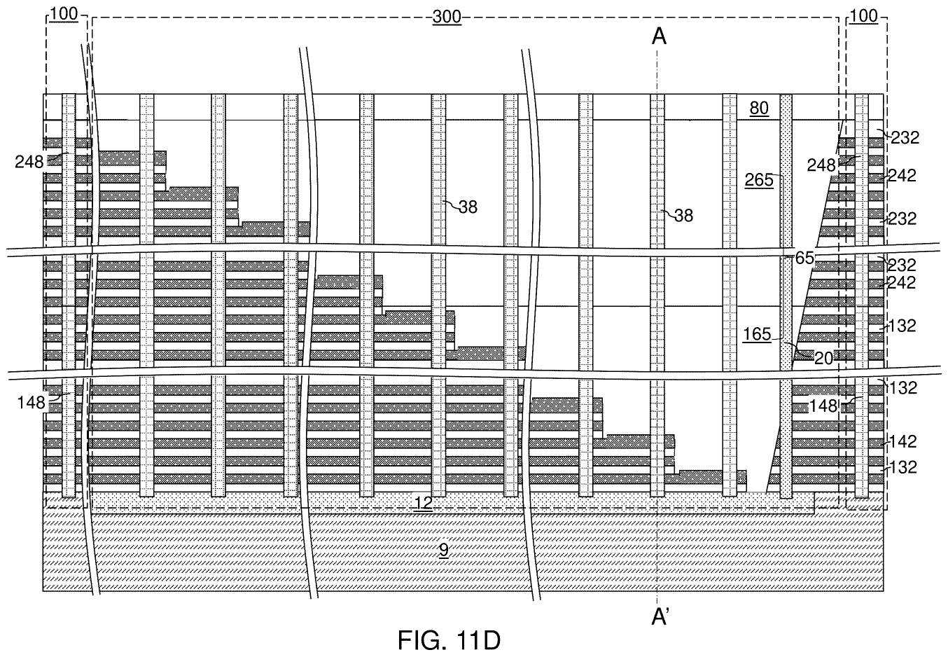

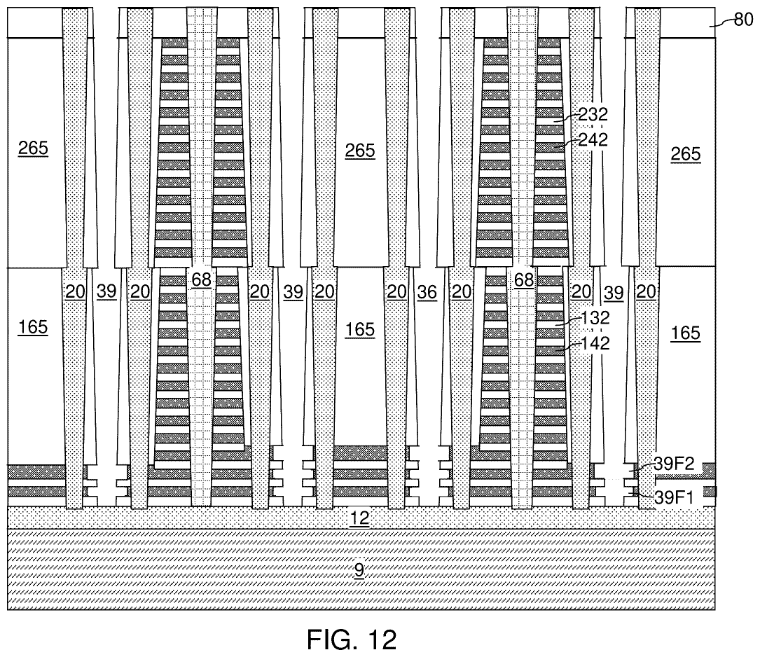

Referring to FIG. 12, a selective isotropic etch process can be performed to etch proximal portions of the continuous sacrificial material layers (142, 242) around each contact opening 39 without etching the materials of the continuous insulating layers (132, 232), the in-process retro-stepped dielectric material portions (165, 265), the contact-level dielectric layer 80, and the etch-stop dielectric layer 12. For example, if the continuous sacrificial material layers (142, 242) comprise silicon nitride, the selective isotropic etch process may comprise a wet etch process employing hot phosphoric acid. Fin cavities (39F1, 39F2) are formed in volumes from which the material of the continuous sacrificial material layers (142, 242) is removed. The duration of the selective isotropic etch process can be selected such that the etch distance of the selective isotropic etch process for the material of the continuous sacrificial material layers (142, 242) is greater than the thickness of the unthickened portions of the continuous sacrificial material layers (142, 242). In an illustrative example, the ratio of the etch distance of the selective isotropic etch process for the material of the continuous sacrificial material layers (142, 242) to the thickness of the unthickened portions of the continuous sacrificial material layers (142, 242) may be in a range from 1.1 to 4.

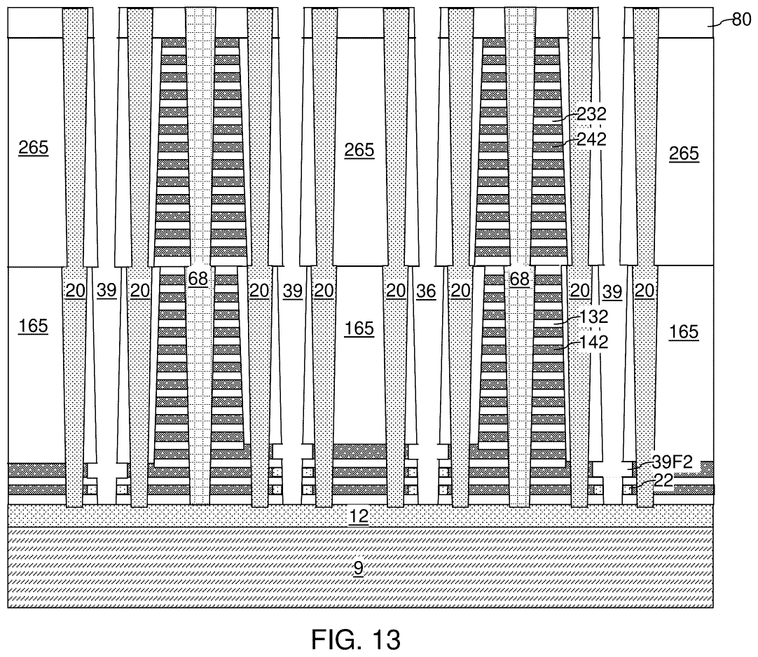

Referring to FIG. 13, a conformal dielectric material layer comprising a material different from the material of the continuous sacrificial material layers (142, 242) can be deposited in peripheral regions of the contact openings 39. For example, the conformal dielectric material layer may comprise silicon oxide or silicon carbonitride. The thickness of the conformal dielectric material layer can be greater than one half of the thickness of the unthickened portions of the continuous sacrificial material layers (142, 242), and can be less than one half of the thickness of the thickened portions (142T, 242T) of the continuous sacrificial material layers (142, 242). First-type fin cavities 39F1 located adjacent to unthickened portions of the continuous sacrificial material layers (142, 242) can be completely filled with the conformal dielectric material layer, while second-type fin cavities 39F2 located adjacent to thickened portions (142T, 242T) of the continuous sacrificial material layers (142, 242) can be partially filled with the conformal dielectric material layer.

Subsequently, an etch process can be performed to etch back the material of the conformal dielectric material layer. For example, if the conformal dielectric material layer comprises silicon oxide, the etch process may comprise a wet etch process employing dilute hydrofluoric acid. The duration of the isotropic etch process can be selected such that the etch distance of the isotropic etch process for the material of the conformal dielectric material layer is in a range from 100% of the lateral thickness of the vertically-extending portion of the conformal dielectric material layer to 140% of the lateral thickness of the vertically-extending portion of the conformal dielectric material layer. Vertically-extending portions of the conformal dielectric material layer can be removed from the peripheral region of each of the contact openings 39. Portions of the conformal dielectric material layer filling the second-type fin cavities are removed. Each remaining portion of the conformal dielectric material layer that fills a respective first-type fin cavity 39F1 constitutes an annular dielectric spacer 22. Each contact opening 39 that vertically extends through an unthickened portion of a continuous sacrificial material layer (142, 242) is laterally surrounded by an annular dielectric spacer 22.

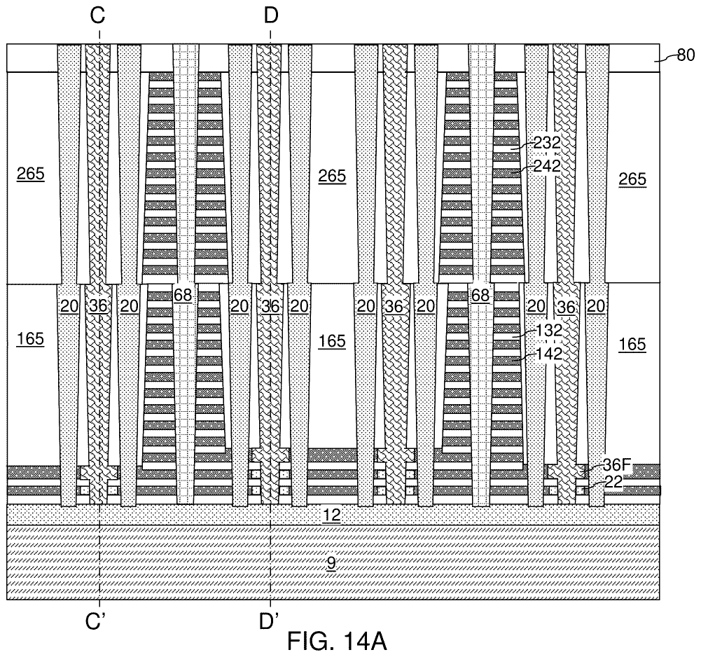

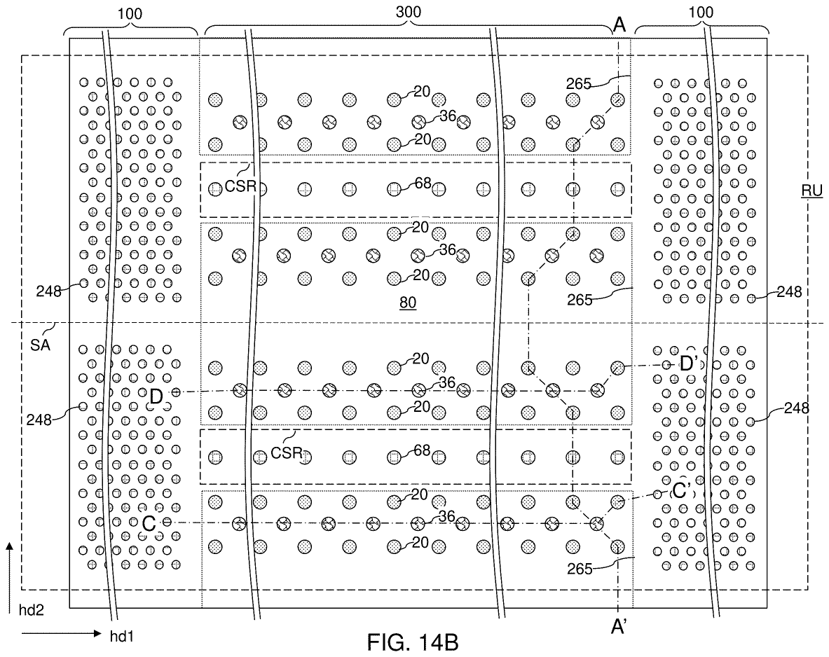

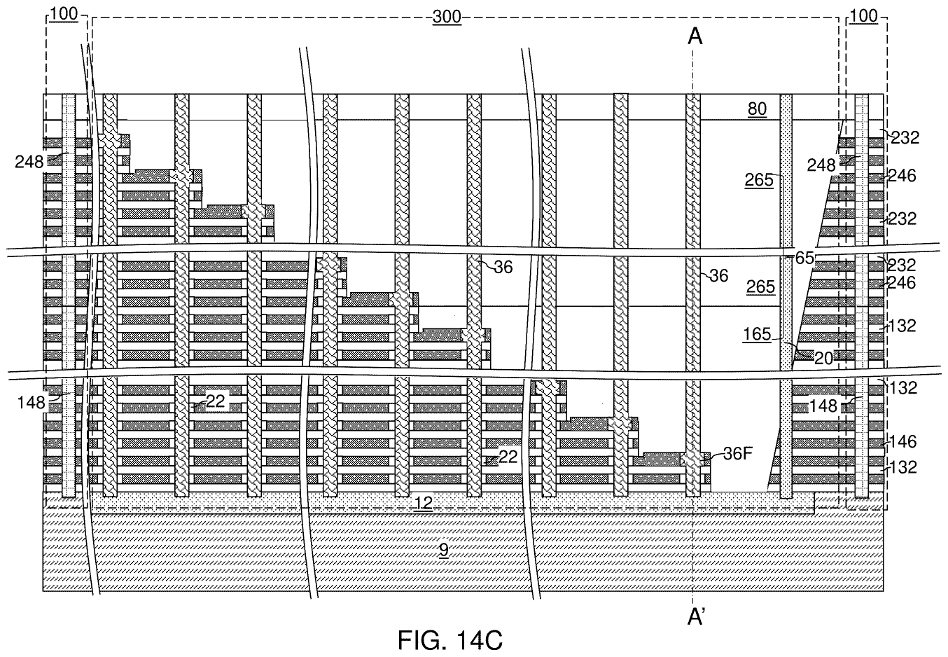

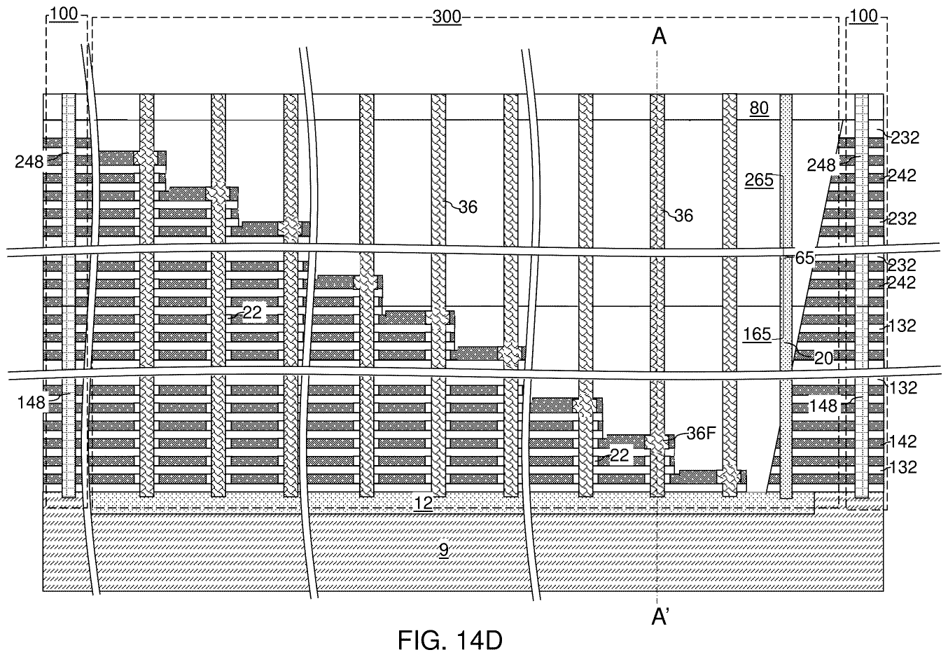

Referring to FIGS. 14A-14D, a sacrificial via fill material can be deposited in the contact openings 39. The sacrificial via fill material may comprise a semiconductor material, such as amorphous silicon, or a carbon-based material, such as amorphous carbon. Excess portions of the sacrificial via fill material can be removed from above the horizontal plane including the top surface of the contact-level dielectric layer 80. Each remaining portion of the sacrificial via fill material that fills a respective contact opening 39 comprises a finned sacrificial contact via opening fill structure 36. Each finned sacrificial contact via opening fill structure 36 comprises a respective fin portion 36F that laterally protrudes at a level of a thickened portions (142T, 242T) of a respective continuous sacrificial material layer (142, 242). Each fin portion 36F may contact the thickened portion (142T, 242T) of a respective one of the continuous sacrificial material layers (142, 242).

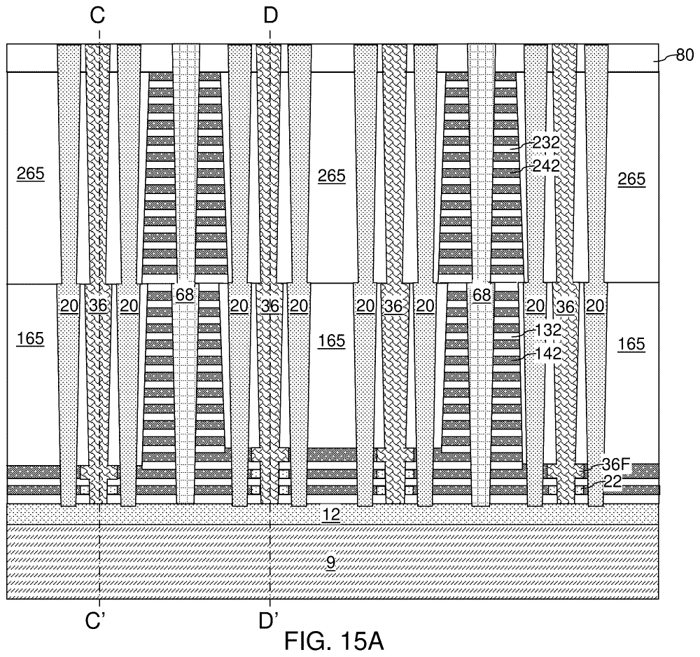

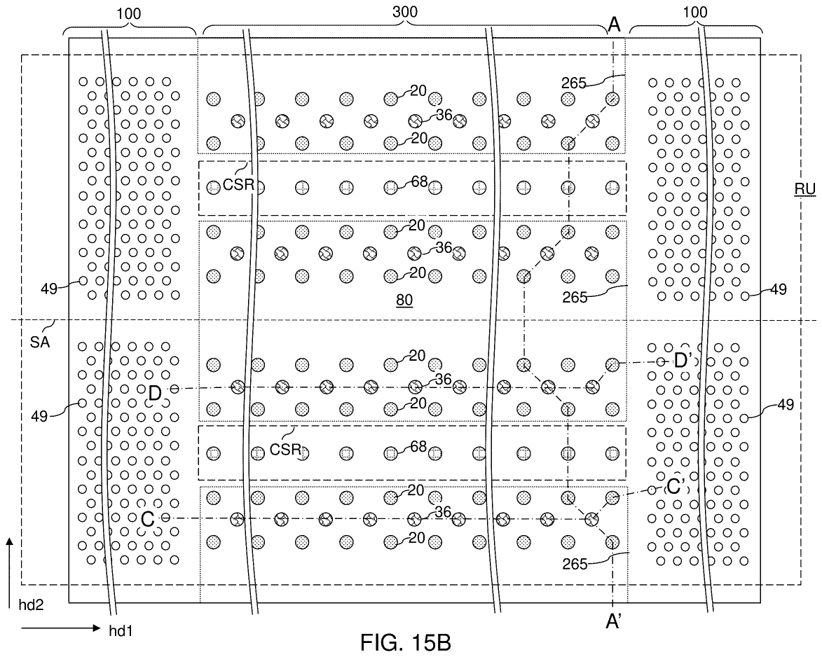

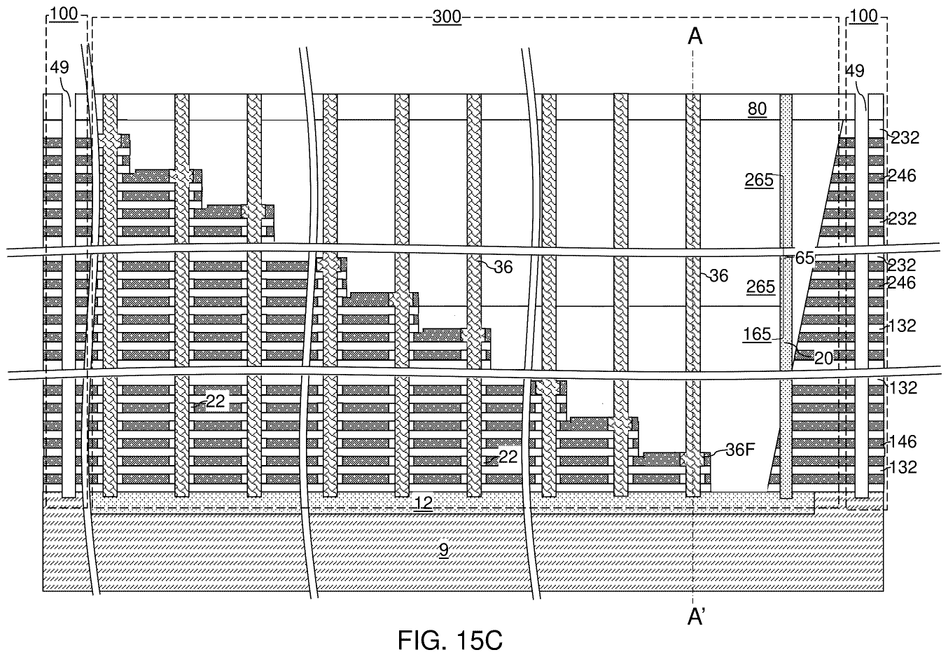

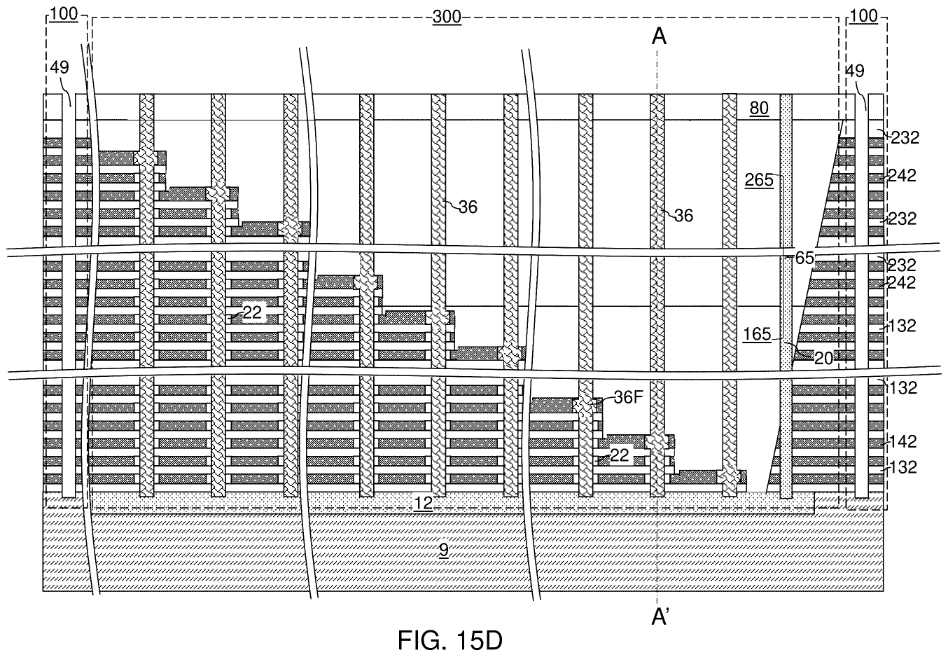

Referring to FIGS. 15A-15D, an etch mask layer (not shown) such as a patterned photoresist layer can be formed over the contact-level dielectric layer 80. The etch mask layer may comprise openings that overlie the sacrificial memory opening fill structures (148, 248). A selective etch process can be performed to etch the sacrificial fill materials of the sacrificial memory opening fill structures (148, 248) without etching the materials of the vertically alternating sequences {(132, 142), (232, 242)}, the in-process retro-stepped dielectric material portions (165, 265), or the etch-stop dielectric layer 12. For example, if the sacrificial memory opening fill structures (148, 248) comprise amorphous silicon, a wet etch process using hot trimethyl-2 hydroxyethyl ammonium hydroxide (“hot TMY”) or tetramethyl ammonium hydroxide (TMAH) may be performed to remove the sacrificial memory opening fill structures (148, 248). Memory openings 49 are formed in the volumes from which the materials of the sacrificial memory opening fill structures (148, 248) are removed. The etch mask layer can be subsequently removed.

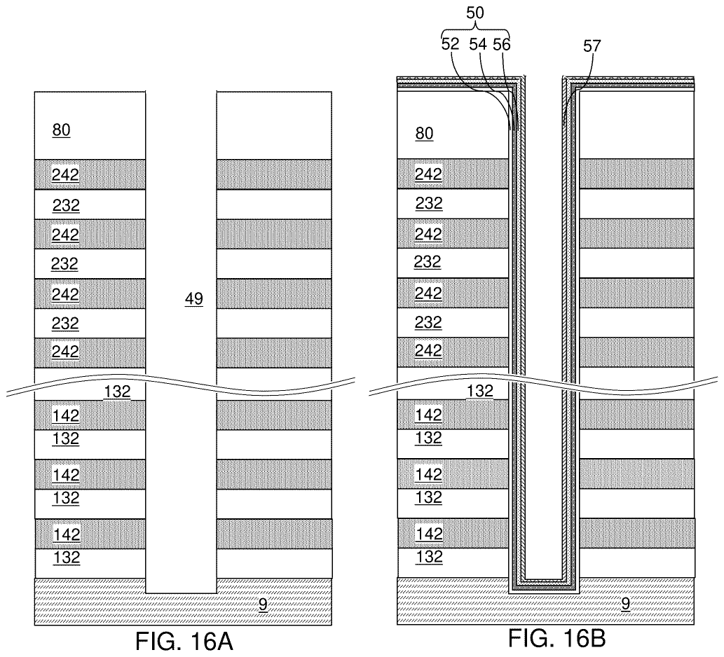

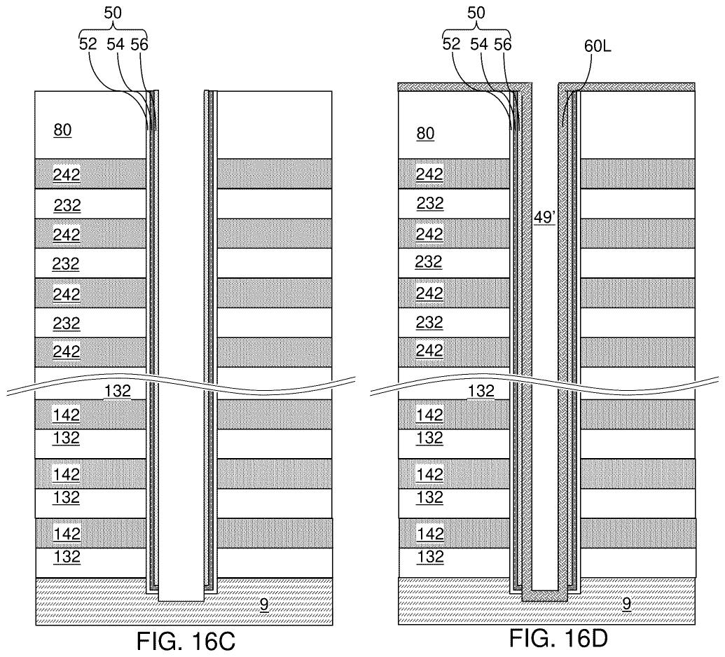

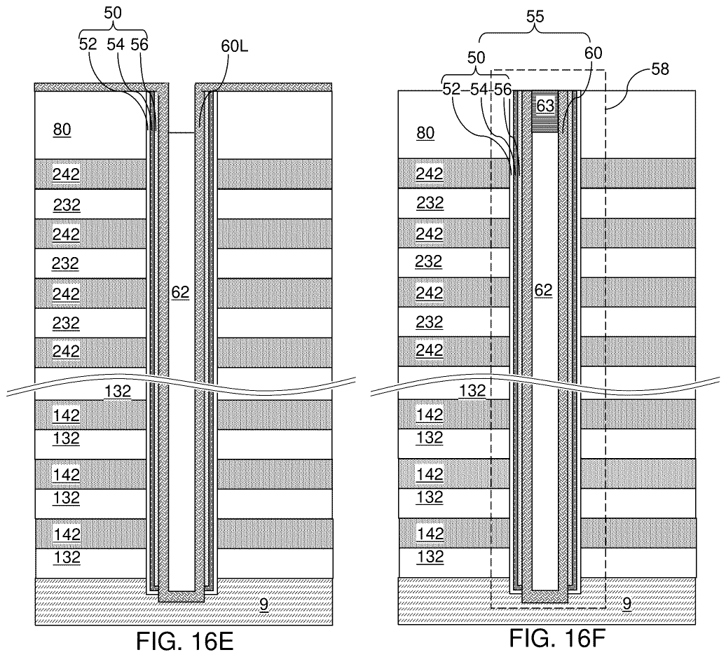

FIGS. 16A-16F illustrate sequential vertical cross-sectional views of a memory opening during formation of a memory opening fill structure according to an embodiment of the present disclosure.

Referring to FIG. 16A, a memory opening 49 in the first exemplary structure of FIG. 12 is illustrated.

Referring to FIG. 16B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within laterally-extending cavities into continuous sacrificial material layers 42. In one embodiment, the memory material layer 54 includes a silicon nitride layer. In one embodiment, the continuous sacrificial material layers 42 and the continuous insulating layers 32 may have vertically coincident sidewalls, and the memory material layer 54 may be formed as a single continuous layer. Alternatively, the continuous sacrificial material layers 42 may be laterally recessed with respect to the sidewalls of the continuous insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selectively to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 16C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selectively to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then the sacrificial cover layer 57 may be retained.

Referring to FIG. 16D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art.

In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon.

In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process.

The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 16E, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 16F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of laterally-extending cavities. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions 100 of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50, a respective vertical semiconductor channel 60, and a respective drain region 63.

In one embodiment, each of the memory stack structures 55 comprises vertical NAND string including the respective vertical stack of memory elements (comprising portions of a memory material layer 54 located at levels of the continuous sacrificial material layers 42) and a vertical semiconductor channel 60 that vertically extend through the continuous sacrificial material layers 42 adjacent to the respective vertical stack of memory elements.

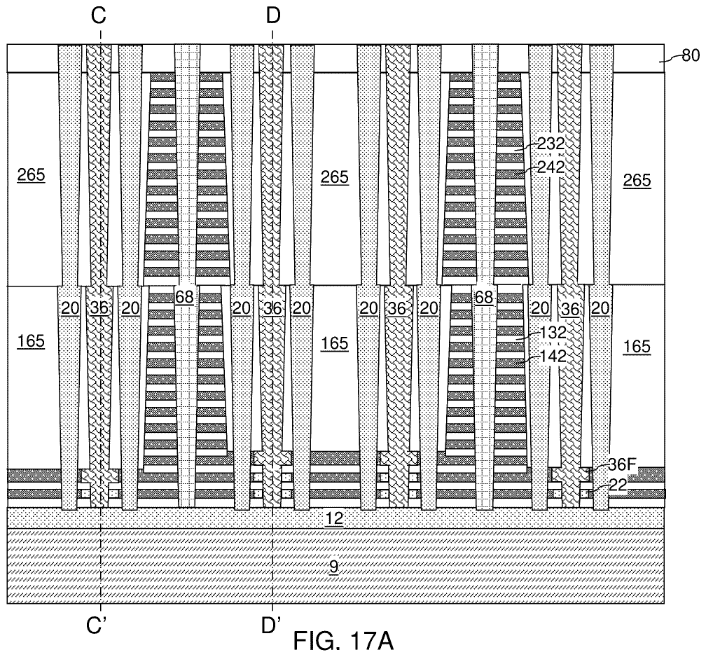

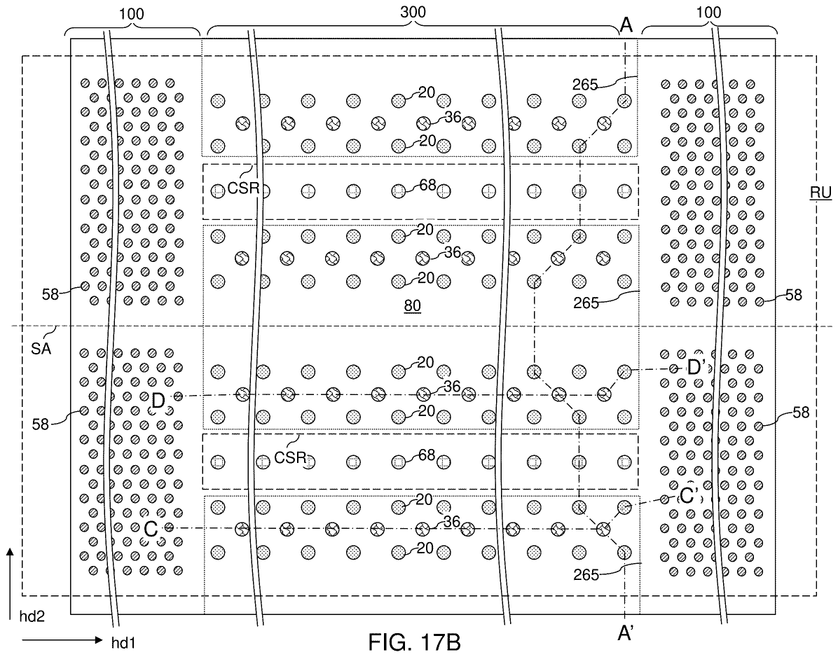

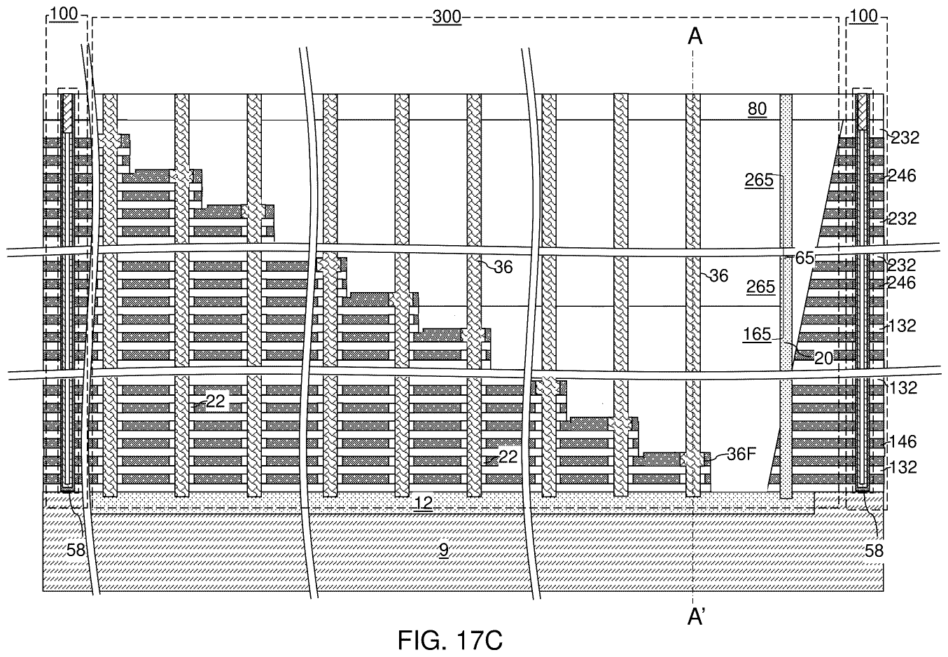

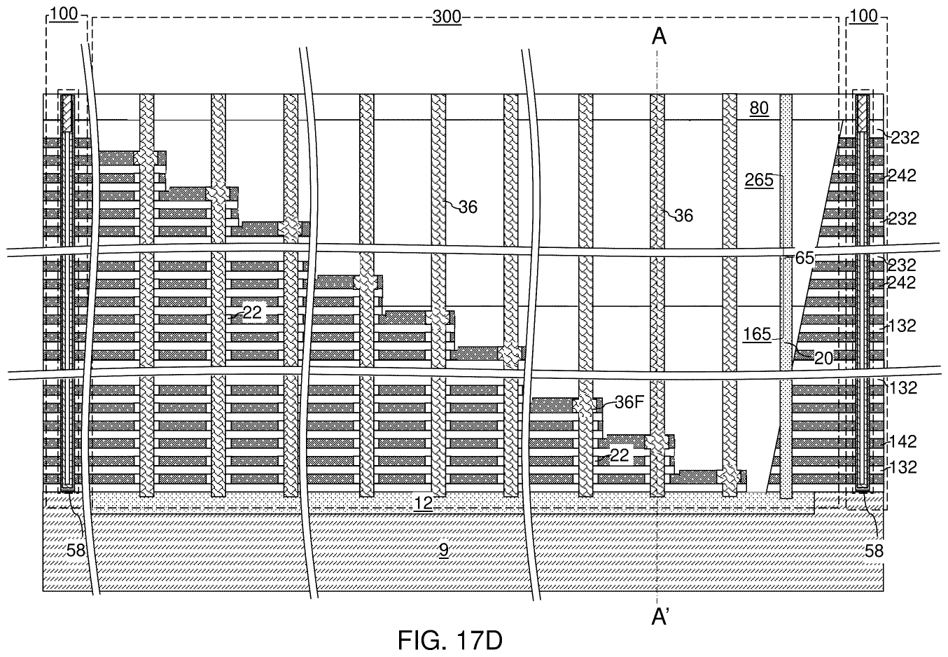

Referring to FIGS. 17A-17D, the first exemplary structure is illustrated after the processing steps of FIG. 16F, i.e., after formation of the memory opening fill structures 58 in the memory openings 49.

In summary, referring collectively to FIGS. 1-17D, at least one vertically alternating sequence of continuous insulating layers (132, 232) and continuous sacrificial material layers (142, 242) can be formed over a substrate 9. Stepped cavities having a respective stepped bottom surface can be formed in the at least one vertically alternating sequence. In-process retro-stepped dielectric material portions (165 and/or 265) can be formed in the stepped cavities. Memory opening fill structures 58 can be formed through the at least one vertically alternating sequence. Each of the memory opening fill structures 58 comprises a respective vertical stack of memory elements located at levels of the continuous sacrificial material layers (142, 242) within the plurality of tier structures, and further comprises a respective vertical semiconductor channel 60 that vertically extends through the plurality of tier structures.

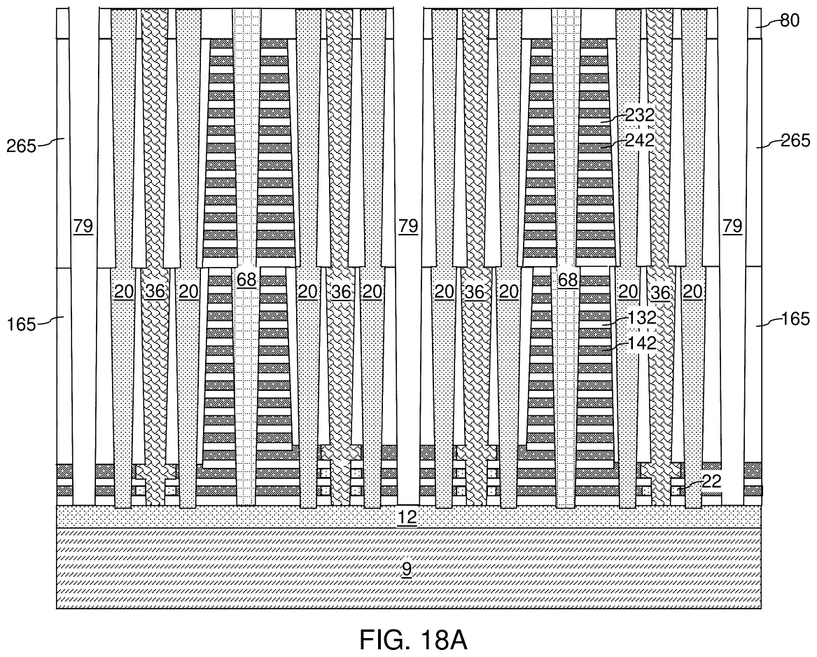

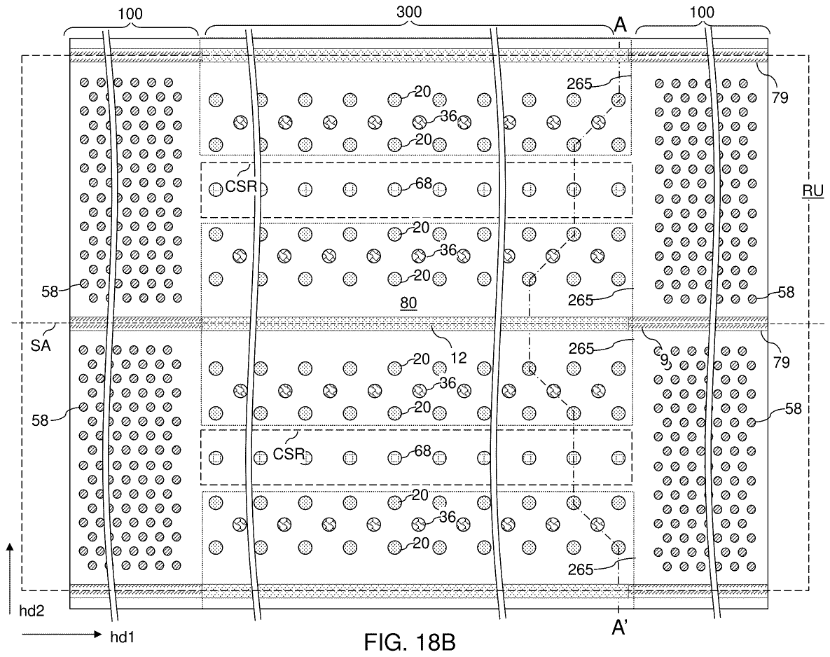

Referring to FIGS. 18A and 18B, a patterning film (not shown) can be anisotropically deposited over the contact-level dielectric layer 80. The patterning film comprises a material that may be subsequently employed as an etch mask material. The patterning film may be subsequently patterned, for example, by applying and lithographically patterning a photoresist layer over the patterning film, and by transferring the pattern of openings in the photoresist layer through the patterning film by performing an anisotropic etch process. Elongated openings laterally extending along the first horizontal direction hd1 can be formed in the patterning film. The photoresist layer may be removed after patterning the patterning film, or may be collaterally removed during a subsequent anisotropic etch process that transfers the pattern in the patterning film through the second-tier structure and the first-tier structure.

An anisotropic etch process can be performed to transfer the pattern of the elongated openings in the patterning film through the contact-level dielectric layer 80, the second-tier structure, and the first-tier structure. Lateral isolation trenches 79 can be formed in the volumes from which the materials of the contact-level dielectric layer 80, the second-tier structure, and the first-tier structure are removed. The patterning film can be subsequently removed, for example, by ashing or selective etching.

The lateral isolation trenches 79 can be formed through each vertically alternating sequence {(132, 142), (232, 242)}. The lateral isolation trenches 79 cut the at least one vertically alternating sequence into multiple alternating stacks {(132, 142), (232, 242)} of respective insulating layers (132, 232) and respective sacrificial material layers (142, 242). Each sacrificial material layer (142, 242) is a patterned portion of a respective continuous sacrificial material layer (142, 242). Each of the lateral isolation trenches 79 laterally extends along the first horizontal direction hd1, and divides a respective stack of the in-process retro-stepped dielectric material portions (165, 265) into a respective pair of stacks of retro-stepped dielectric material portions (16, 265). A contiguous combination of an alternating stack {(132, 142), (232, 242)} of insulating layers (132, 232) and sacrificial material layers (142, 242), a first retro-stepped dielectric material portion 165, and a second retro-stepped dielectric material portion 265 can be formed in a respective memory block area between each neighboring pair of lateral isolation trenches 79 of the lateral isolation trenches 79. Each of the multiple alternating stacks {(132, 142), (232, 242)} comprises a first alternating stack portion located in a first memory array region 100, a second alternating stack portion located in a second memory array region 100 that is laterally spaced from the first memory array region 100 along the first horizontal direction hd1, and a connection strip portion located in a connection strip region CSR and connecting the first alternating stack portion and the second alternating stack portion through region 300.

The respective first retro-stepped dielectric material portion 165 is a patterned portion of one of the in-process retro-stepped dielectric material portions 165 as formed at the processing steps of FIGS. 4A-4D . The respective second retro-stepped dielectric material portion 265 is a patterned portion of another of the in-process retro-stepped dielectric material portions 265 as formed at the processing steps of FIGS. 6A-6D.

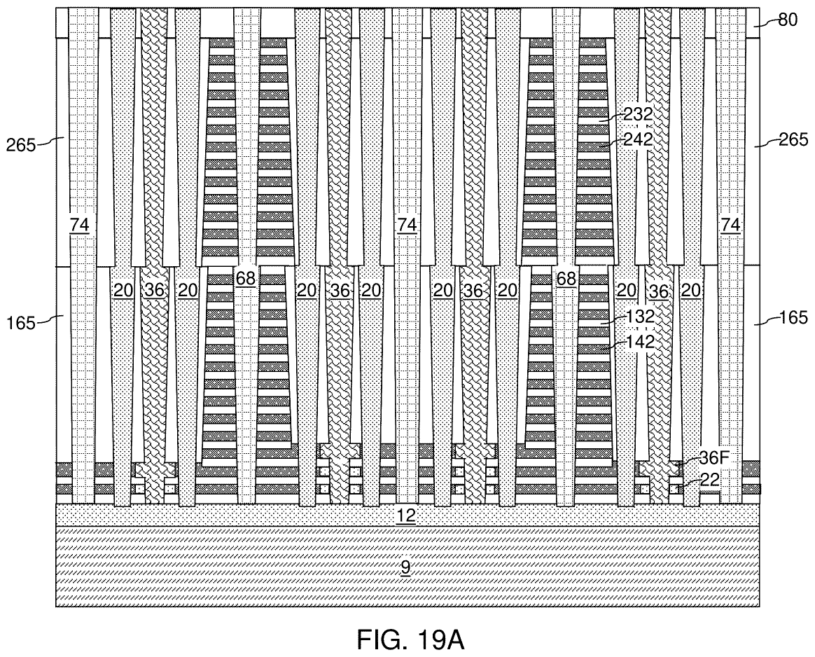

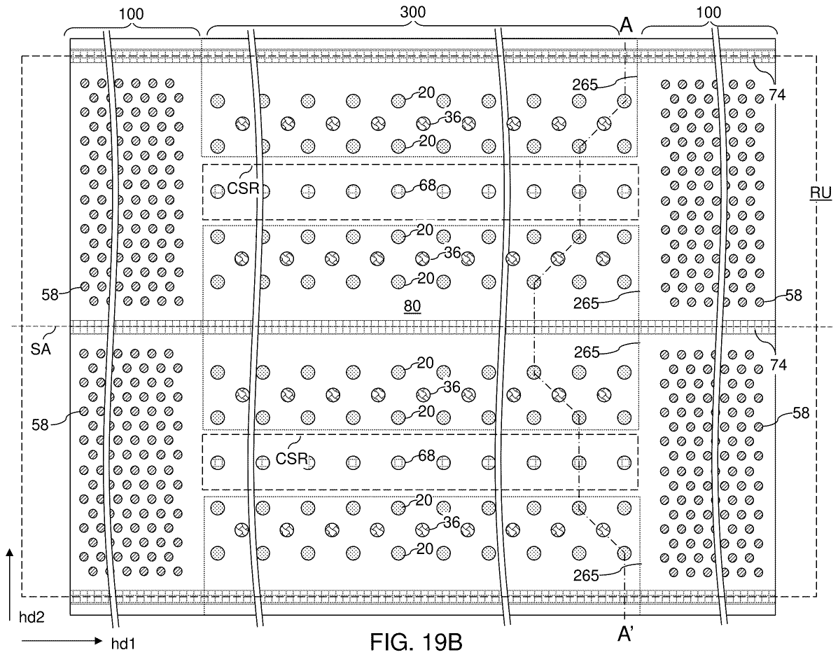

Referring to FIGS. 19A and 19B, a sacrificial trench fill material can be deposited in the lateral isolation trenches 79. The sacrificial trench fill material may comprise a semiconductor material, such as amorphous silicon, or a carbon-based material, such as amorphous carbon or diamond-like carbon. Excess portions of the sacrificial trench fill material can be removed from above the horizontal plane including the top surface of the contact-level dielectric layer 80. Each remaining portion of the sacrificial trench fill material filling a respective lateral isolation trench 79 constitutes a sacrificial lateral isolation trench fill structure 74.

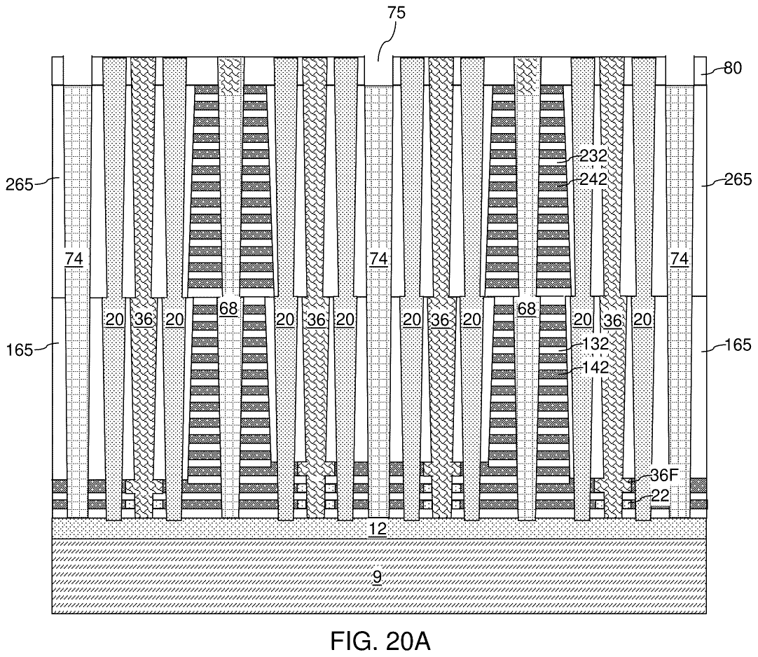

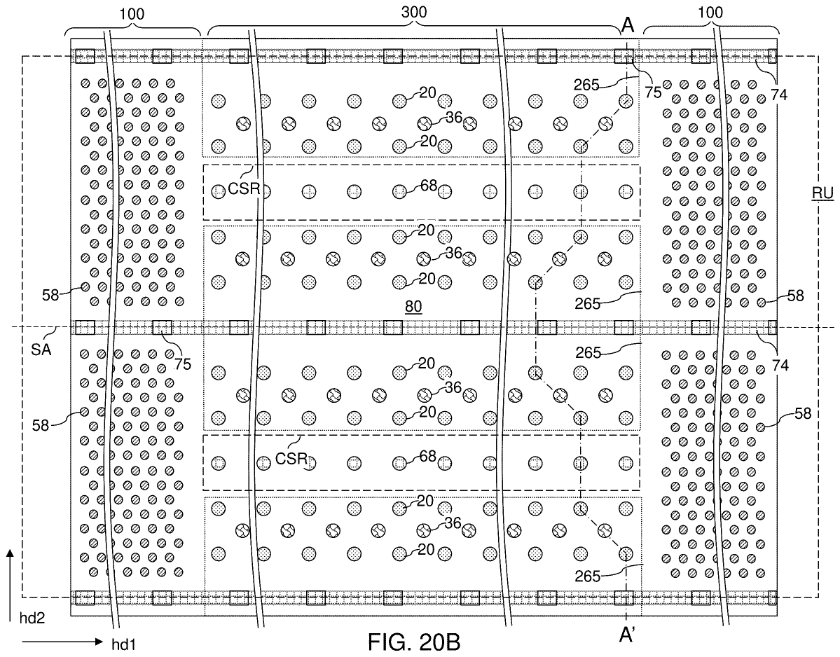

Referring to FIGS. 20A and 20B, a photoresist layer (not shown) can be applied over the first exemplary structure, and can be lithographically patterned to form rows of discrete openings overlying the sacrificial lateral isolation trench fill structures 74. A selective etch process can be performed to etch unmasked portions of the sacrificial lateral isolation trench fill structures 74 selectively to the materials of the contact-level dielectric layer 80 to form recess cavities, which are herein referred to as bridge recesses 75. For example, if the sacrificial lateral isolation trench fill structures 74 comprise amorphous silicon, the selective etch process may comprise a wet etch process using hot trimethyl-2 hydroxyethyl ammonium hydroxide (“hot TMY”) or tetramethyl ammonium hydroxide (TMAH). The duration of the selective etch process can be selected such that the bottom surfaces of the bridge recesses 75 are formed about the height of the bottom surfaces of the contact-level dielectric layer 80. The photoresist layer can be subsequently removed, for example, by ashing.

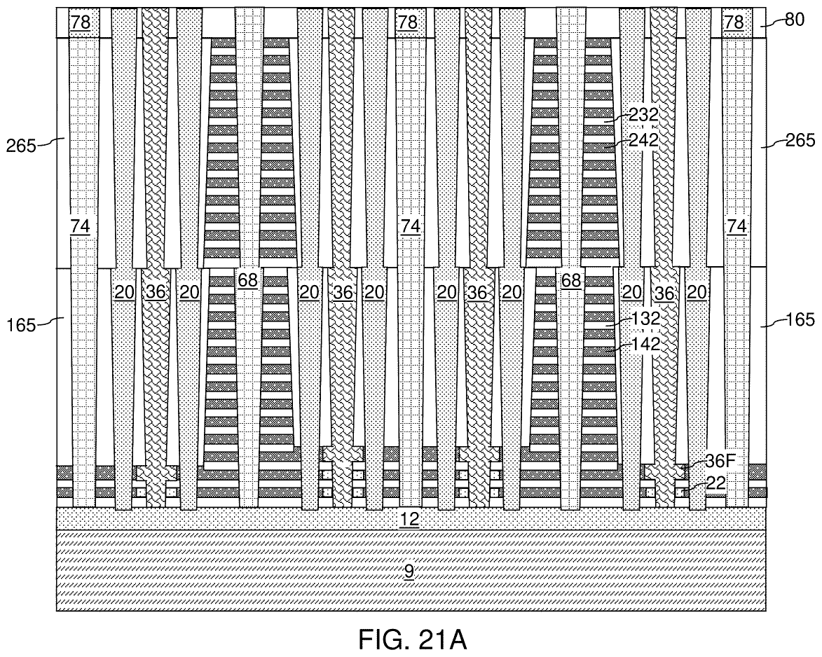

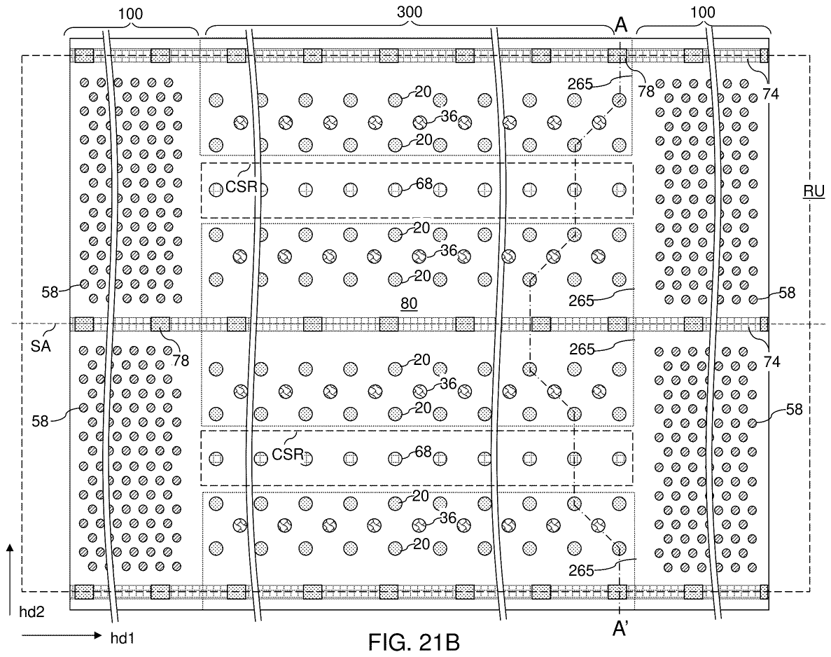

Referring to FIGS. 21A and 21B, a dielectric fill material, such as silicon oxide, can be deposited in the bridge recesses 75. Excess portions of the dielectric fill material can be removed from above the horizontal plane including the top surface of the contact-level dielectric layer 80. Each remaining portion of the dielectric fill material filling a respective one of the bridge recesses 75 constitutes a bridge structure 78, which is a dielectric material portion providing lateral support between neighboring portions of the contact-level dielectric layer 80 during subsequent processing steps in which voids are present in the lateral isolation trenches 79.

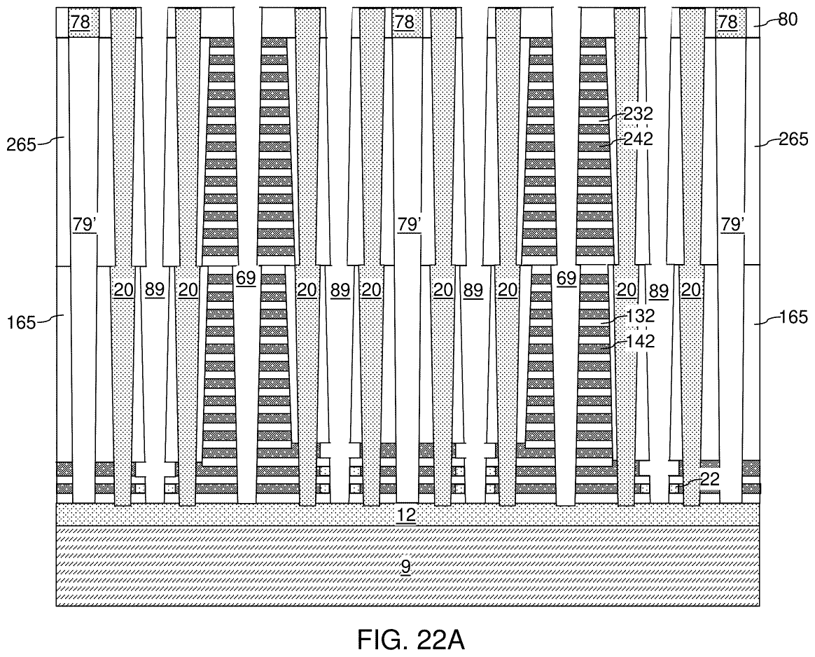

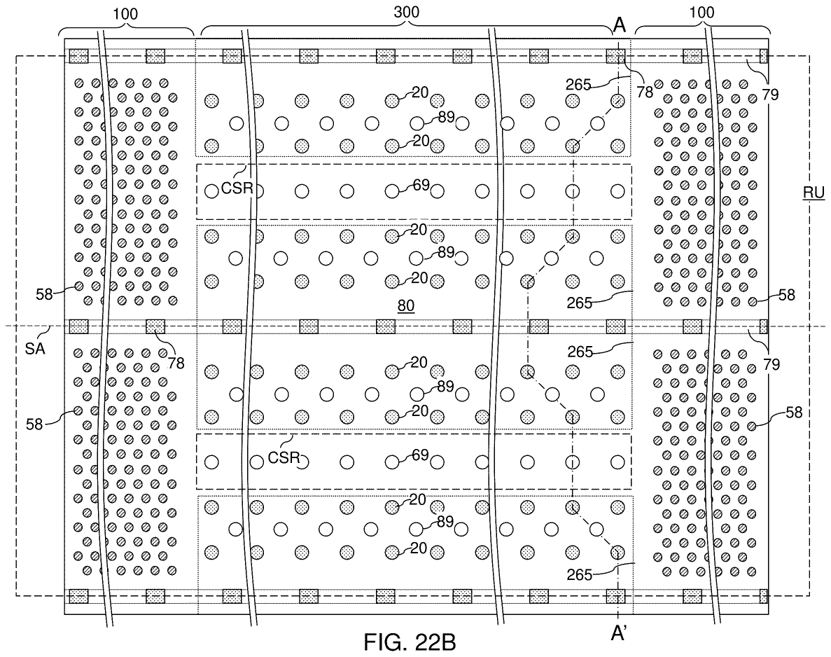

Referring to FIGS. 22A and 22B, a first selective isotropic etch process can be performed to remove the sacrificial access opening fill structures 68, the finned sacrificial contact via opening fill structure 36, and the sacrificial lateral isolation trench fill structures 74 without etching the materials of the contact-level dielectric layer 80, the bridge structures 78, the alternating stacks {(132, 142), (232, 242)}, and the retro-stepped dielectric material portions (165, 265). For example, if the sacrificial access opening fill structures 68, the finned sacrificial contact via opening fill structure 36, and the sacrificial lateral isolation trench fill structures 74 comprise amorphous silicon, a wet etch process using hot trimethyl-2 hydroxyethyl ammonium hydroxide (“hot TMY”) or tetramethyl ammonium hydroxide (TMAH) can be performed to remove the sacrificial access opening fill structures 68, the finned sacrificial contact via opening fill structure 36, and the sacrificial lateral isolation trench fill structures 74. Access openings 69 are formed in volumes from which the sacrificial access opening fill structures 68 are removed. Contact openings 89 are formed in the volumes from which the finned sacrificial contact via opening fill structure 36 are removed. Lateral isolation cavities 79′ are formed in the volumes from which the sacrificial lateral isolation trench fill structures 74 are removed. According to an aspect of the present disclosure, at least one row of access openings 69 can be formed through each of the connection strip portions in a respective connection strip region CSR. At least one row of contact openings 89 can be formed through each of the retro-stepped dielectric material portions (165, 265).

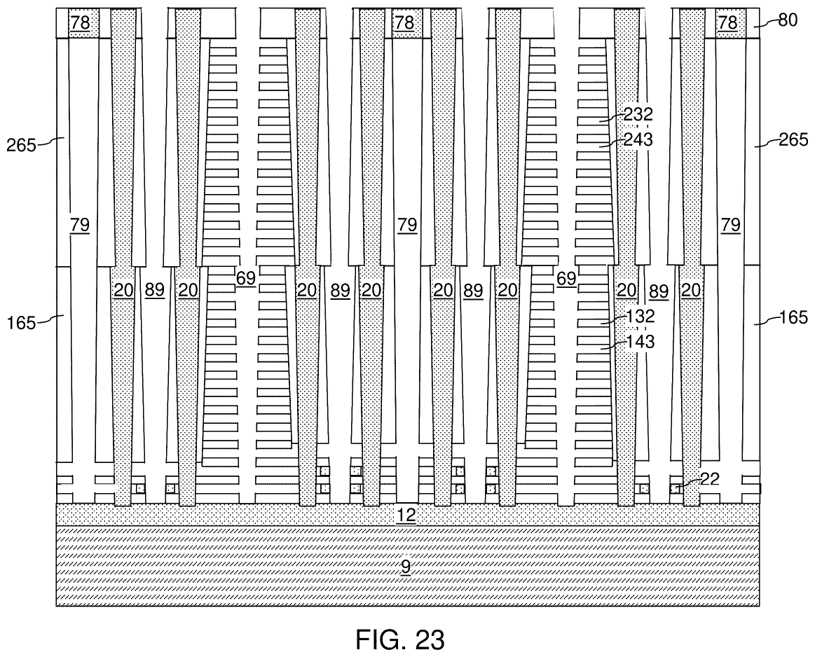

Referring to FIG. 23, a second selective isotropic etch process can be performed to remove the sacrificial material layers (142, 242) selectively to the insulating layers (132, 232) by using the access openings 69, the contact openings 89, and the lateral isolation trenches 79 as conduits for transporting an isotropic etchant. Specifically, the sacrificial material layers (142, 242) may be isotropically etched selectively to the insulating layers (132, 232), the bridge structures 78, the annular dielectric spacers 22, and the retro-stepped dielectric material portions (165, 265) by supplying an isotropic etchant into the access openings 69, the contact openings 89, and the lateral isolation trenches 79. In one embodiment, an etchant that selectively etches the material of the sacrificial material layers (142, 242) without etching the materials of the insulating layers (132, 232), the bridge structures 78, the annular dielectric spacers 22, the retro-stepped dielectric material portions (165, 265), and the outermost layer of the memory films 50 may be introduced into the access openings 69, the contact openings 89, and the lateral isolation trenches 79 during the second selective isotropic etch process.

The second selective isotropic etch process may be a wet etch process using a wet etch solution, or may be a gas phase (dry) etch process in which the etchant is introduced in a vapor phase. For example, if the sacrificial material layers (142, 242) comprise silicon nitride, and if the insulating layers (132, 232), the bridge structures 78, the annular dielectric spacers 22, the retro-stepped dielectric material portions (165, 265), and the outermost layer of the memory films 50 comprise silicon oxide materials, the etch process may comprise a hot phosphoric acid etch process, which etches silicon nitride selectively to silicon oxide, silicon, and various other materials used in the art.

Laterally-extending cavities (143, 243) are formed in volumes from which the sacrificial material layers (142, 242) are removed. The laterally-extending cavities 43 include first laterally-extending cavities 143 that are formed in volumes from which the first-tier sacrificial material layers 142 are removed and second laterally-extending cavities 243 that are formed in volumes from which the second-tier sacrificial material layers 242 are removed. Each of the laterally-extending cavities (143, 243) may have a lateral dimension that is greater than a vertical dimension. In other words, the lateral dimension of each of the laterally-extending cavities (143, 243) may be greater than the height of the respective laterally-extending cavities (143, 243).

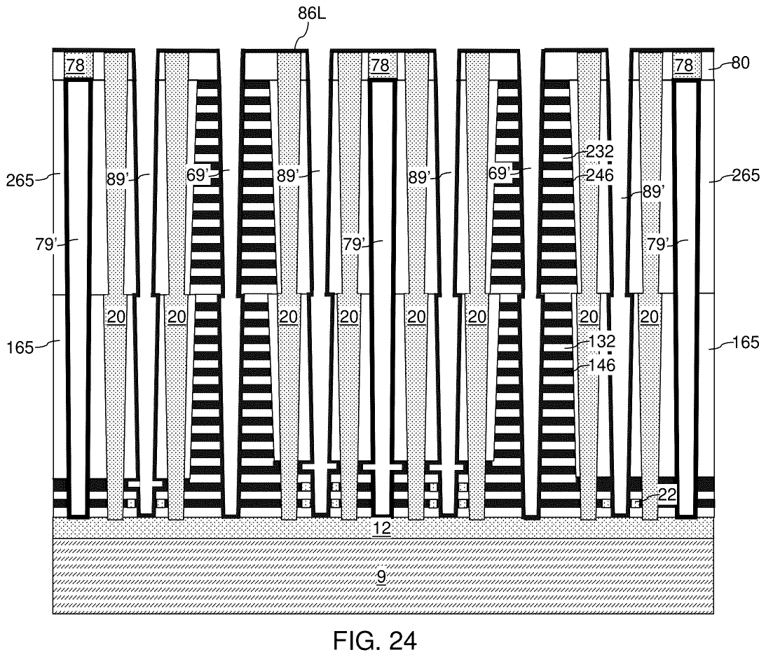

Referring to FIG. 24, an electrically conductive material layer 86L may be conformally deposited in the laterally-extending cavities (143, 243), in peripheral regions of each of the access openings 69, the contact openings 89, and the lateral isolation trenches 79, and over the top surface of the contact-level dielectric layer 80. The electrically conductive material layer 86L can be conformally deposited on all physically exposed surfaces around the access openings 69, the contact openings 89, and the lateral isolation trenches 79, and on the physically exposed top surface of the contact-level dielectric layer 80. The electrically conductive material layer 86L comprises at least one electrically conductive material, which may be a combination of a metallic barrier material (such as TiN, TaN, WN, and/or MoN) and a metal fill material (such as W, Ti, Ta, Mo, Co, Ru, Cu, etc.). The total thickness of the at least one electrically conductive material may be selected such that all portions of the laterally-extending cavities (143, 243) that are formed by removal of unthickened portions of the sacrificial material layers (142, 242) are completely filled within the electrically conductive material layer 86L, while portions of the laterally-extending cavities (143, 243) that are formed by removal of thickened portions (142T, 242T) of the sacrificial material layers (142, 242) are only partially filled by the electrically conductive material layer 86L.

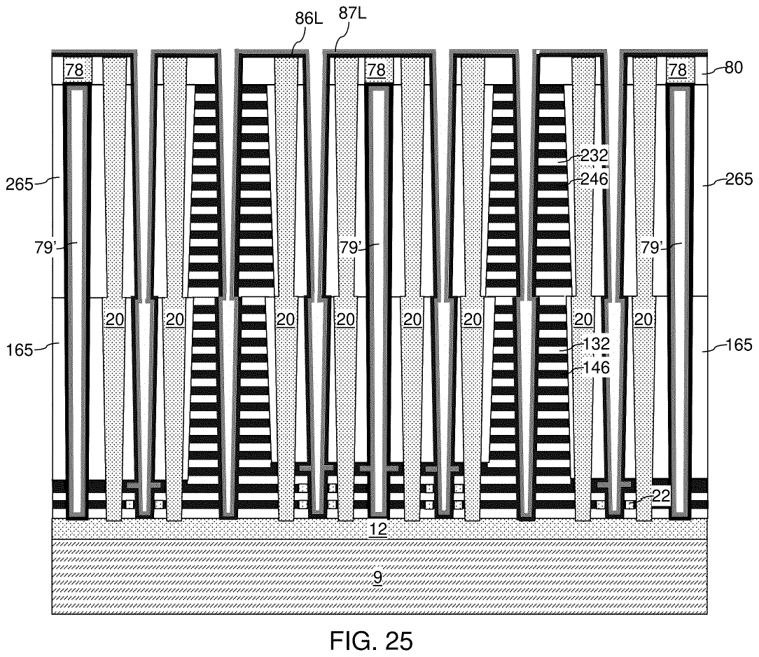

Referring to FIG. 25, a dielectric liner layer 87L can be conformally deposited over the electrically conductive material layer 86L. The dielectric liner layer 87L comprises a dielectric material, such as silicon oxide or silicon nitride. The thickness of the dielectric liner layer 87L can be selected such that unfilled voids within the portions of the laterally-extending cavities (143, 243) that are formed by removal of thickened portions (142T, 242T) of the sacrificial material layers (142, 242) are filled with the dielectric liner layer 87L, while center regions of each of the access openings 69, the contact openings 89, and the lateral isolation trenches 79 are not completely filled with the dielectric liner layer 87L. The thickness of the dielectric liner layer 87L can be in a range from 20 nm to 100 nm, although lesser and greater thicknesses may also be employed.

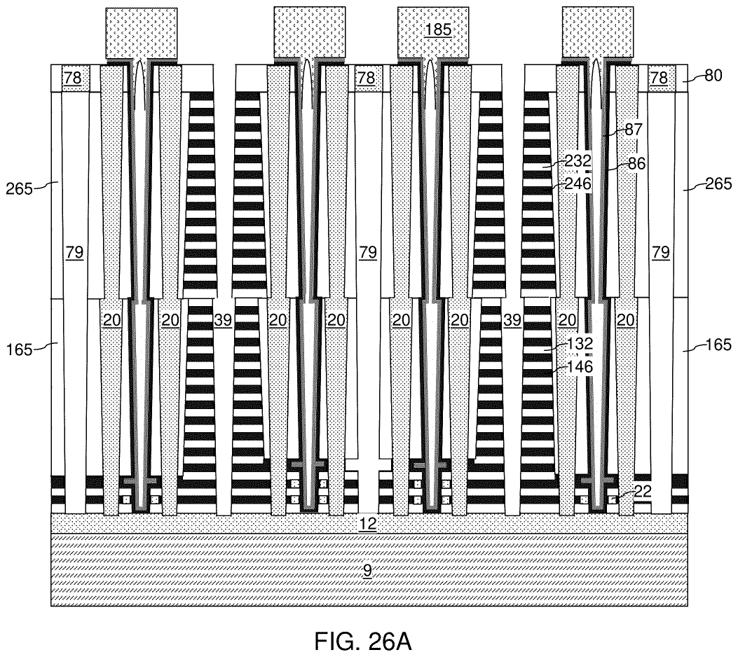

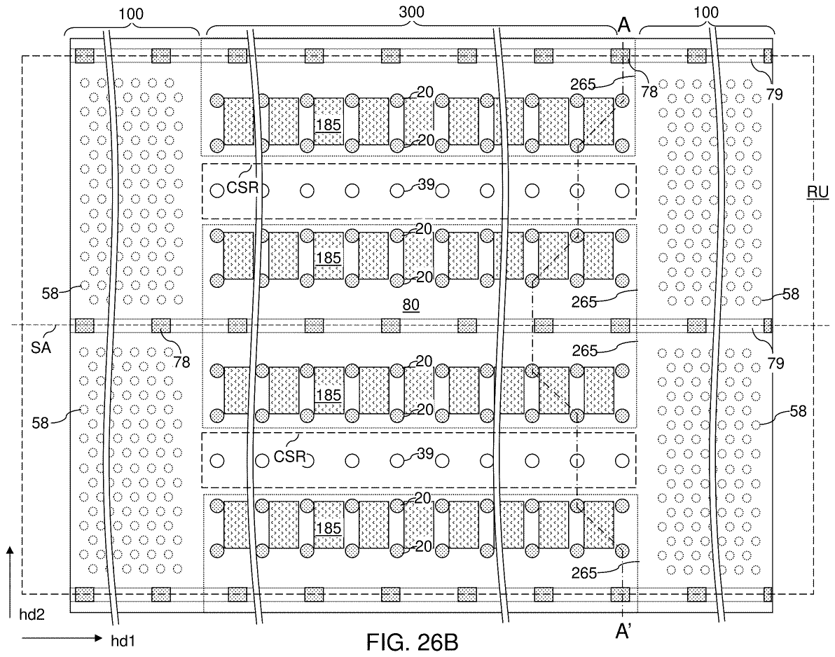

Referring to FIGS. 26A and 26B, a photoresist layer can be applied over the first exemplary structure, and can be lithographically patterned into a set of discrete photoresist material portions 185 covering a respective one of the contact openings 89. A first selective recess etch process can be performed to etch unmasked portions of the dielectric liner layer 87L selectively to the electrically conductive material layer 86L. If the dielectric liner layer 87L comprises silicon oxide or silicon nitride, a wet etch process employing dilute hydrofluoric acid or hot phosphoric acid may be performed to etch unmasked portions of the dielectric liner layer 87L. Each remaining portion of the dielectric liner layer 87L underlying a respective discrete photoresist material portion 185 constitutes a dielectric liner 87.

A second selective recess etch process can be performed to etch portions of the electrically conductive material layer 86L that are not masked by the dielectric liners 87. The second selective recess etch process etches the material of the electrically conductive material layer 86L selectively to the materials of the dielectric liners 87, the insulating layers (132, 232), the contact-level dielectric layer 80, the bridge structures 78, the retro-stepped dielectric material portions (165, 265), and the etch-stop dielectric layer 12. For example, the second isotropic selective recess etch process may comprise a timed wet etch process having an etch chemistry that etches the electrically conductive material layer 86L selectively to the dielectric materials of the dielectric liners 87, the insulating layers (132, 232), the contact-level dielectric layer 80, the bridge structures 78, the retro-stepped dielectric material portions (165, 265), and the etch-stop dielectric layer 12. Unmasked portions of the electrically conductive material layer 86L located inside the lateral isolation trenches 79 or inside the access openings 39 can be removed by the second isotropic selective recess etch process.

Each remaining portion of the electrically conductive material layer 86L that remains in a respective laterally-extending cavity (143, 243) constitutes an electrically conductive layer (146, 246). The electrically conductive layers (146, 246) comprise first-tier electrically conductive layers 146 that are formed within a respective first-tier laterally-extending cavity 143 and second-tier electrically conductive layers 246 that are formed within a respective second-tier laterally-extending cavity 243. Each remaining vertically-extending portion of the electrically conductive material layer 86L that remains within or above a respective contact opening 39 constitutes a layer contact via structure 86. Each layer contact via structure 86 comprises a vertically-extending portion of the electrically conductive material layer 86L that is deposited in the peripheral region of a respective contact opening 89.

Thus, the sacrificial material layers (142, 242) within each of the multiple alternating stacks {(132, 142), (232, 242)} are replaced with the electrically conductive layers (146, 246). A layer contact via structure 86 is formed in each contact opening 89. Each layer contact via structure 86 is electrically connected to a respective one of the electrically conductive layers (146, 246). An alternating stack {(132, 146), (232, 246)} of insulating layers (132, 232) and electrically conductive layers (146, 246) that alternate along a vertical direction is formed between each neighboring pair of lateral isolation trenches 79. Each alternating stack {(132, 146), (232, 246)} of insulating layers (132, 232) and electrically conductive layers (146, 246) comprises a first alternating stack portion located in a first memory array region 100, a second alternating stack portion located in a second memory array region 100 that is laterally spaced from the first memory array region 100 along a first horizontal direction hd1, and a connection strip portion located in a connection strip region CSR and connecting the first alternating stack portion and the second alternating stack portion. A first retro-stepped dielectric material portion (165 and/or 265) comprises a first proximal dielectric sidewall that contacts a first lengthwise sidewall of the connection strip portion. A second retro-stepped dielectric material portion (165 and/or 265) comprises a second proximal dielectric sidewall that contacts a second lengthwise sidewall of the connection strip portion.

In one embodiment, layer contact via structures 86 vertically extend through the first retro-stepped dielectric material portion (165 and/or 265), and are electrically connected to a respective one of the electrically conductive layers (146, 246). In one embodiment, each of the electrically conductive layers (146, 246) comprises a horizontally-extending portion of an electrically conductive material layer 86L as patterned at the processing steps of FIGS. 26A and 26B, and the layer contact via structures 86 comprise vertically-extending portions of the electrically conductive material layer 86L. In one embodiment, each layer contact via structure 86 vertically extends from a first horizontal plane including a bottommost surface of the alternating stack {(132, 146), (232, 246)} to a second horizontal plane including a topmost surface of the alternating stack {(132, 146), (232, 246)}.

In one embodiment, for an electrically conductive layer (146, 246) that is not a bottommost electrically conductive layer (146, 246), a subset of the electrically conductive layers (146, 246) underlies the electrically conductive layers (146, 246). A layer contact via structure 86 contacts a cylindrical sidewall of the electrically conductive layer (146, 246), and vertically extends through the subset of the electrically conductive layers (146, 246). Annular dielectric spacers 22 can laterally surround the layer contact via structure. The annular dielectric spacers 22 comprise inner cylindrical sidewalls in contact with sidewall surface segments of the layer contact via structure 86, and are laterally surrounded by the subset of the electrically conductive layers (146, 246). The discrete patterned photoresist material portions 185 can be subsequently removed, for example, by ashing.

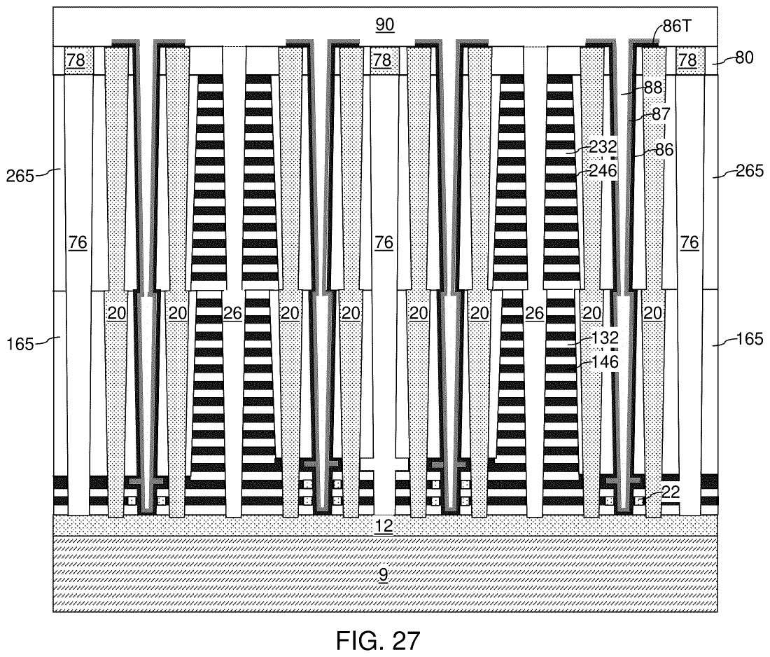

Referring to FIG. 27, a dielectric fill material can be conformally deposited in the access openings 39, remaining unfilled volumes of the contact openings 89, and in the lateral isolation trenches 79. In one embodiment, the dielectric fill material may comprise silicon oxide. The horizontally-extending portion of the dielectric fill material that is deposited over the contact-level dielectric layer 80 constitutes a connection-level dielectric layer 90. Each vertically-extending portion of the dielectric fill material that fills a respective one of the access openings 39 constitutes an access via opening fill structure 26, which is a dielectric pillar structure. Each vertically-extending portion of the dielectric fill material that fills a respective void within a respective contact opening 89 constitutes an in-via dielectric pillar portion 88. Each portion of the dielectric fill material that fills a respective lateral isolation trench 79 constitutes an in-trench dielectric wall structure 76.

For each alternating stack {(132, 146), (232, 246)} of insulating layers (132, 232) and electrically conductive layers (146, 246) located in a memory block area between a neighboring pair of lateral isolation trenches 79, each of the pair of lateral isolation trenches 79 can be filled with a first lateral isolation trench fill structure (76, 78) or a second lateral isolation trench fill structure (76, 78), respectively. The first lateral isolation trench fill structure (76, 78) laterally extends along the first horizontal direction hd1 and contacts a first lengthwise sidewall of the alternating stack {(132, 146), (232, 246)} and a first distal dielectric sidewall of the first retro-stepped dielectric material portion (165 and/or 265). The second lateral isolation trench fill structure (76, 78) laterally extends along the first horizontal direction hd1 and contacts a second lengthwise sidewall of the alternating stack {(132, 146), (232, 246)} and a second distal dielectric sidewall of the second retro-stepped dielectric material portion (165 and/or 265).

A combination of an electrically conductive layer (146, 246) and a layer contact via structure 86 may comprise a continuous electrically conductive material layer. In one embodiment, the vertically-extending portion of the electrically conductive material layer constitutes a layer contact via structure 86, and comprises a vertically-extending cavity therein. In one embodiment, an in-via dielectric liner 87 comprising a first portion of a first insulating material and an in-via dielectric pillar portion 88 are located within the vertically-extending cavity.

In one embodiment, an in-via dielectric pillar portion 88 comprising a first portion of a dielectric fill material may be surrounded by an in-via dielectric liner 87 within each contact opening 89. In one embodiment, each of the first lateral isolation trench fill structure (76, 78) and the second lateral isolation trench fill structure (76, 78) comprises an in-trench dielectric wall structure 76 comprising a respective second portion of the dielectric fill material.

In one embodiment, each layer contact via structure 86 comprises a tab portion 86T that is adjoined to a top end of a vertically-extending portion and overlying a top surface of the contact-level dielectric layer 80. The connection-level dielectric layer 90 overlies the tab portion 86T, the alternating stack {(132, 146), (232, 246)}, the first lateral isolation trench fill structure (76, 78), and the second lateral isolation trench fill structure (76, 78).

For each alternating stack {(132, 146), (232, 246)}, first memory stack structures 55 vertically extend through the first alternating stack portion, and second memory stack structures 55 vertically extend through the second alternating stack portion. Each of the first memory stack structures 55 and the second memory stack structures 55 comprises a respective vertical stack of memory elements (e.g., portions of the memory film 50) located at levels of the electrically conductive layers (146, 246) and a vertical semiconductor channel 60.

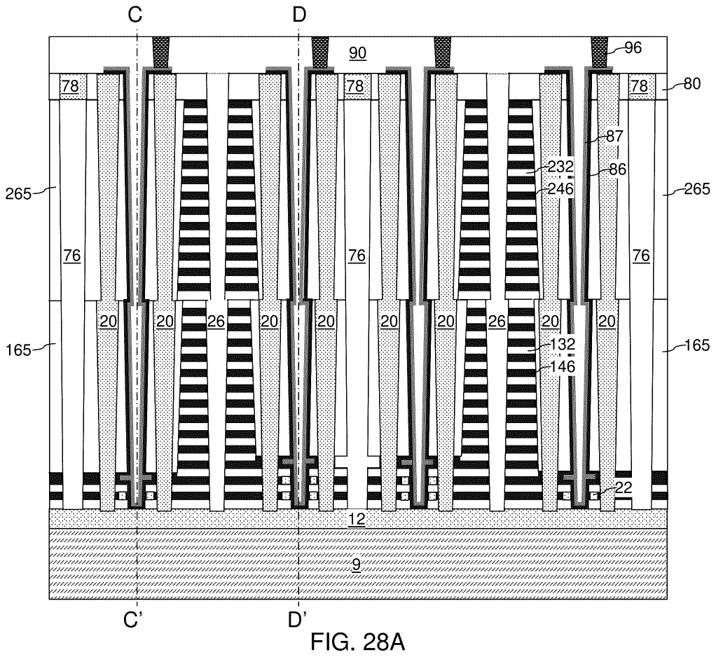

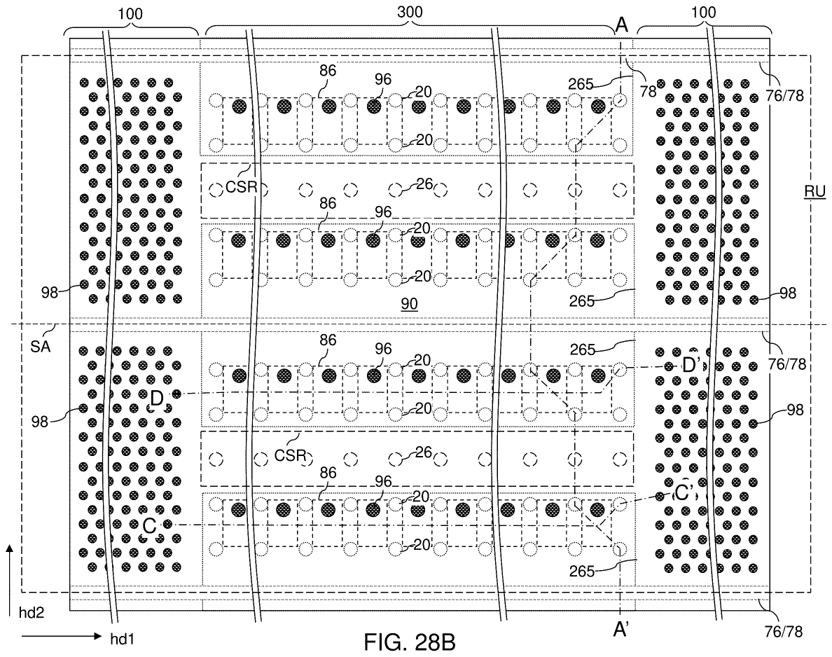

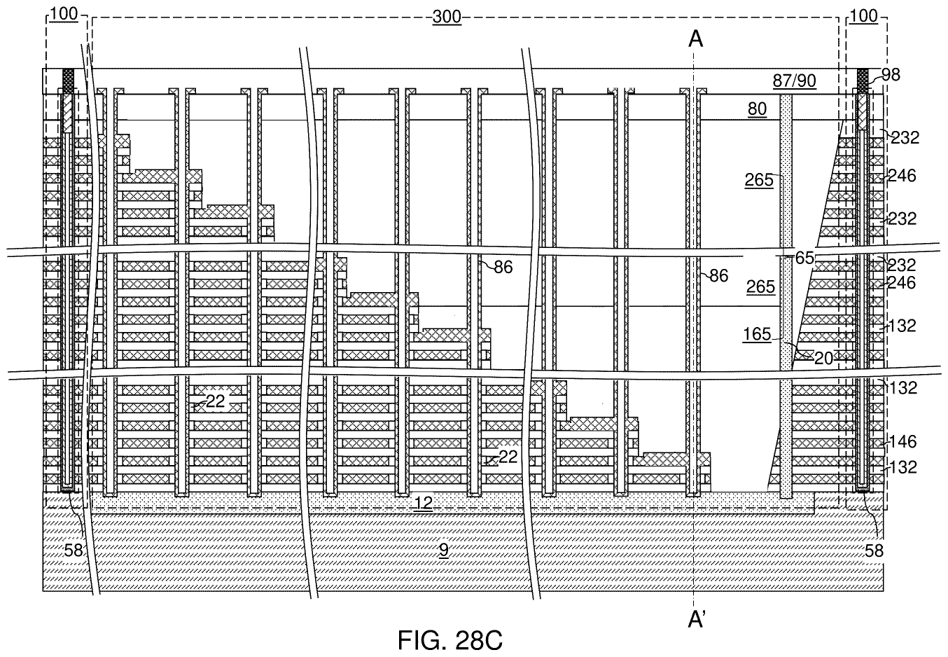

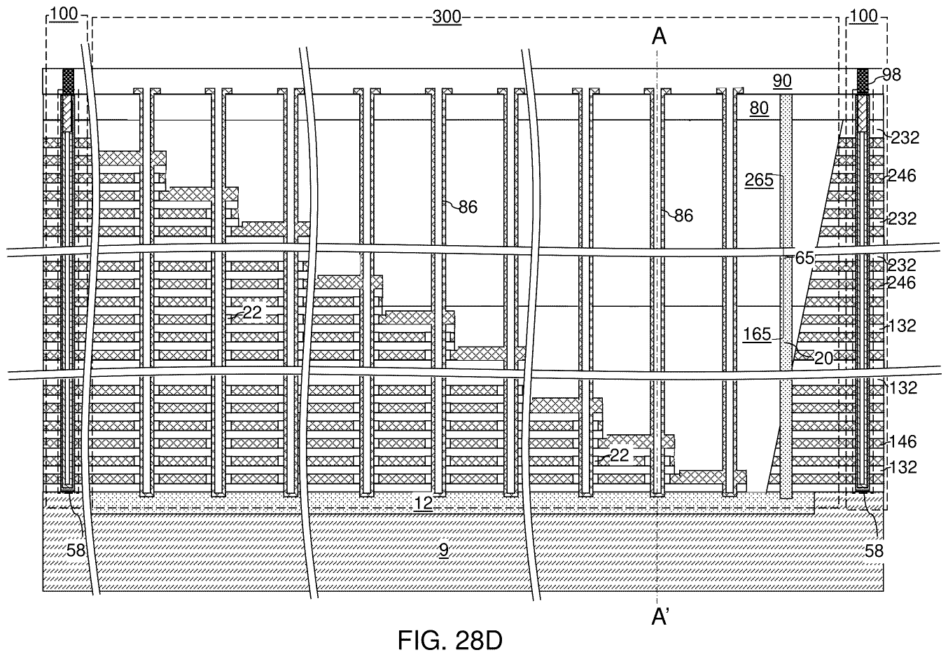

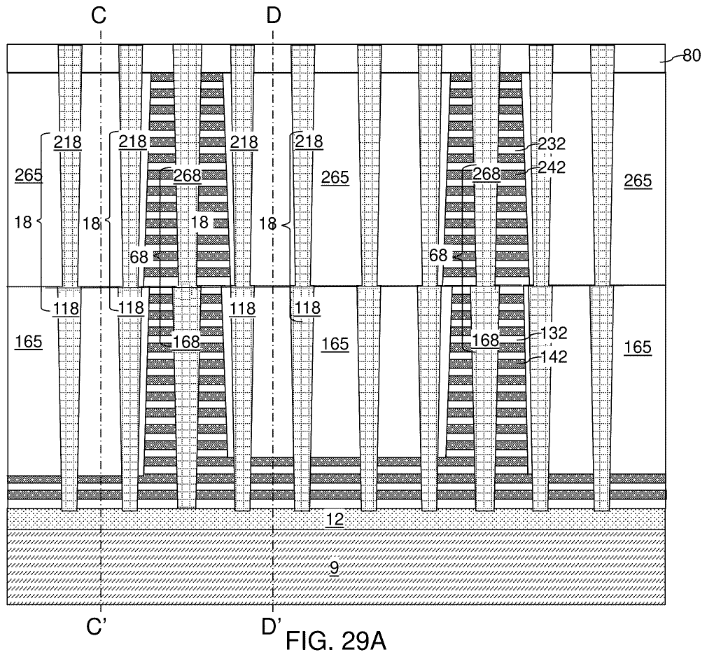

Referring to FIGS. 28A-28D, connection via structures 96 can be formed through the connection-level dielectric layer 90 on a respective one of the layer contact via structures 86. In one embodiment, each connection via structure 96 vertically extends through the connection-level dielectric layer 90 and contacts a top surface of the tab portion of a respective layer contact via structure 86. Electrically conductive bit line via structures 98 are formed over the memory array regions 100 and electrically contact the drain regions 63 of the memory opening fill structures 58. Bit lines (not shown for clarity) are formed over and in electrical contact with the bit lines via structures 98.

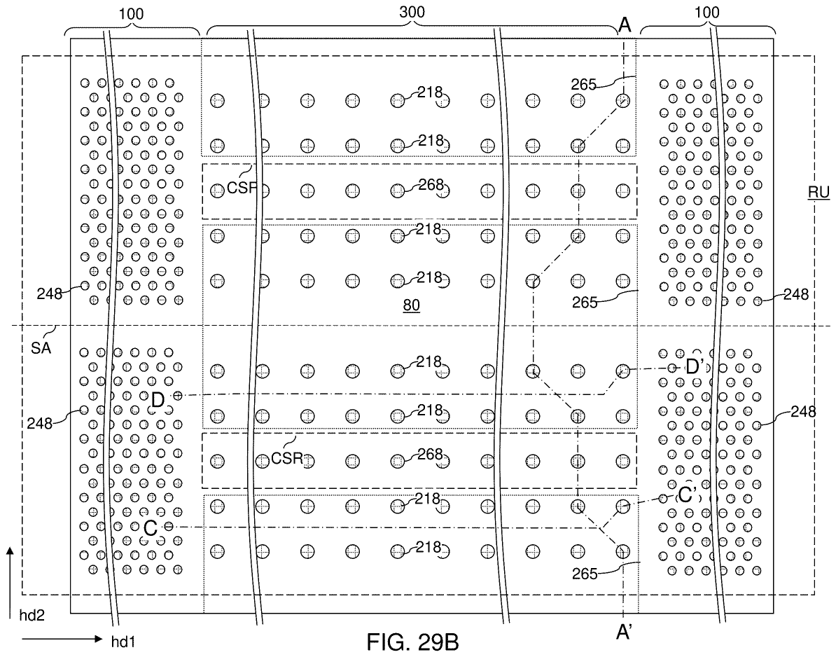

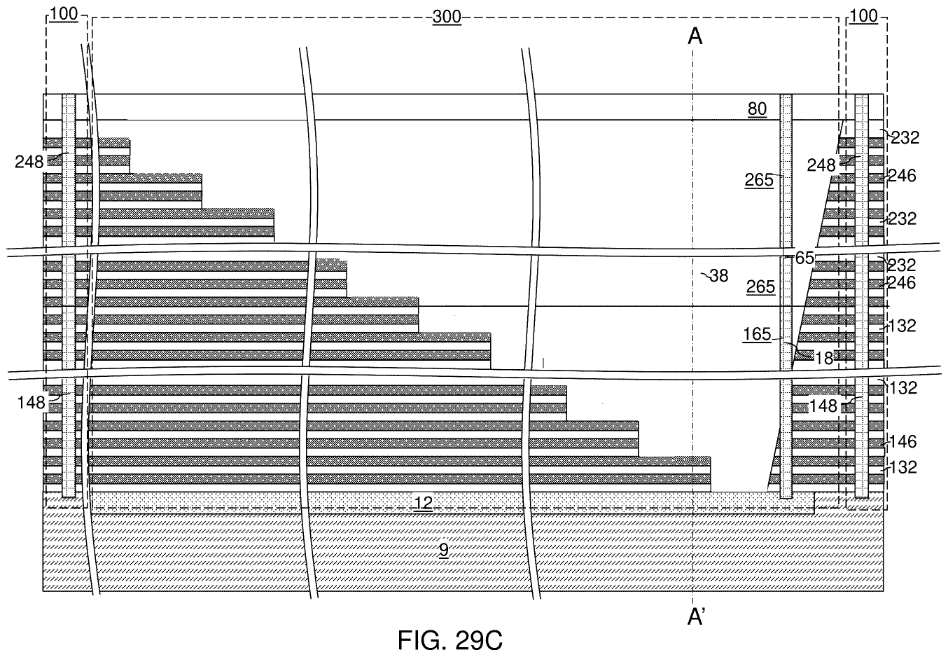

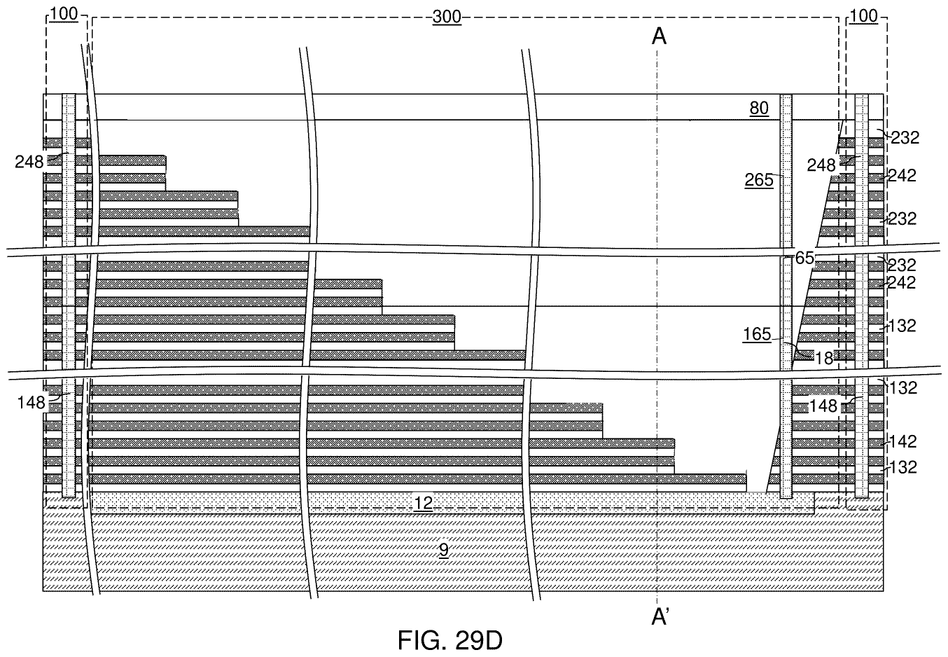

Referring to FIGS. 29A-29D, a second exemplary structure is illustrated after formation of second-tier sacrificial opening fill structures (248, 218, 268). The second exemplary structure can be derived from the first exemplary structure by omitting formation of the first-tier contact openings and second-tier contact openings. Accordingly, sacrificial first-tier contact opening fill structure 138 and sacrificial second-tier contact opening fill structure 238 are not formed in the second exemplary structure. Further, the processing steps described with reference to FIGS. 3A-3E are optional and may be omitted. Thus, the sacrificial material layers (142, 242) are not necessarily locally thickened in the second exemplary structure. Generally, the second exemplary structure illustrated in FIGS. 29A-29D can be derived from the first exemplary structure illustrated in FIGS. 8A-8D by omitting the sacrificial first-tier contact opening fill structure 138 and the sacrificial second-tier contact opening fill structure 238.

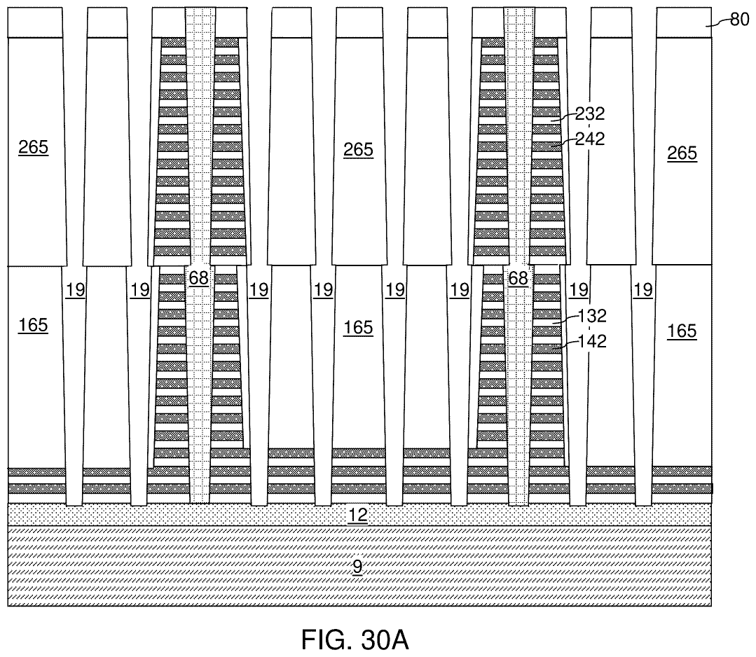

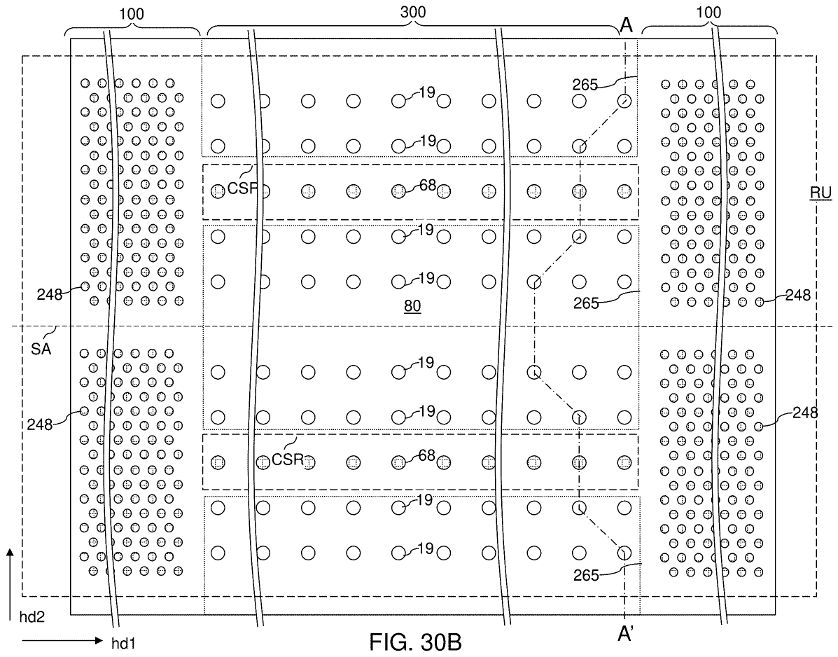

Referring to FIGS. 30A and 30B, the processing steps described with reference to FIGS. 9A and 9B can be performed to form support openings 19.

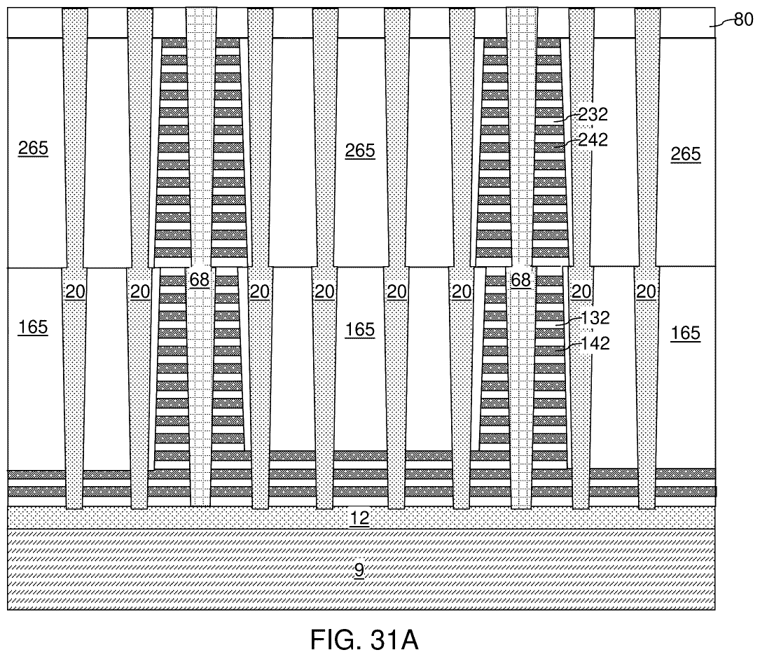

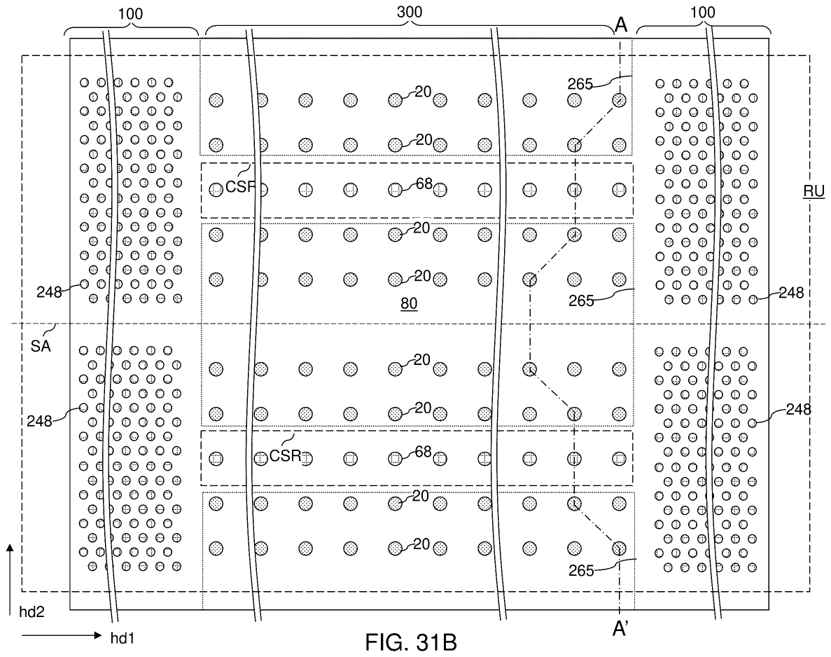

Referring to FIGS. 31A and 31B, the processing steps described with reference to FIGS. 10A and 10B can be performed to form support pillar structures 20 in the support openings 19.

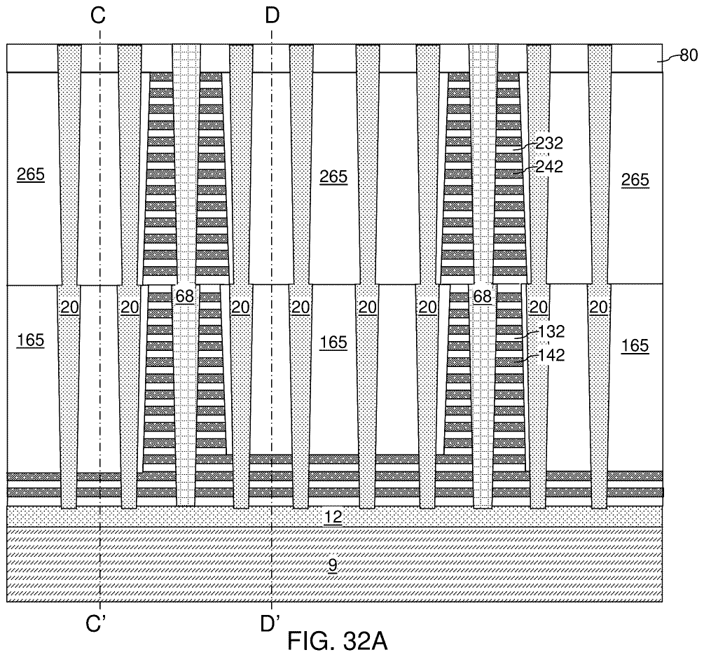

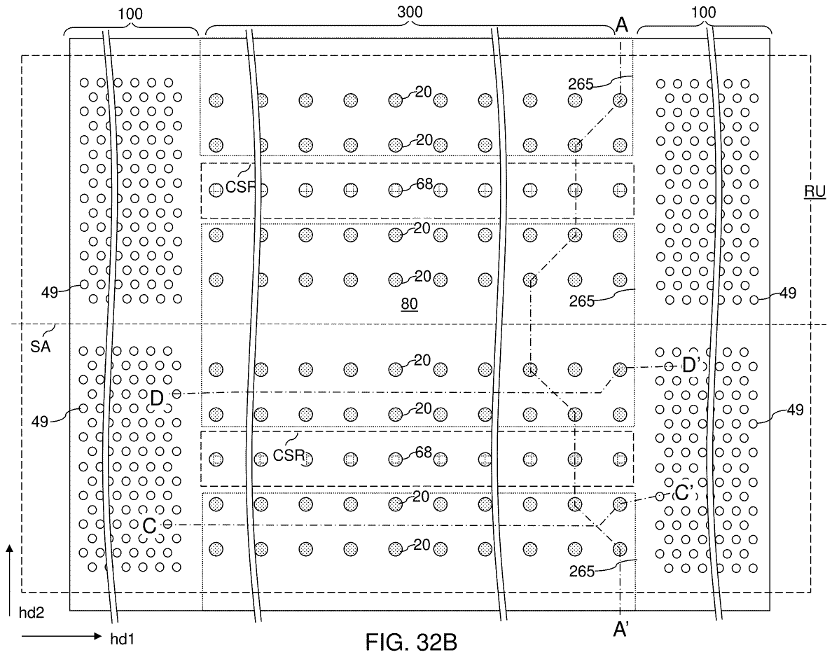

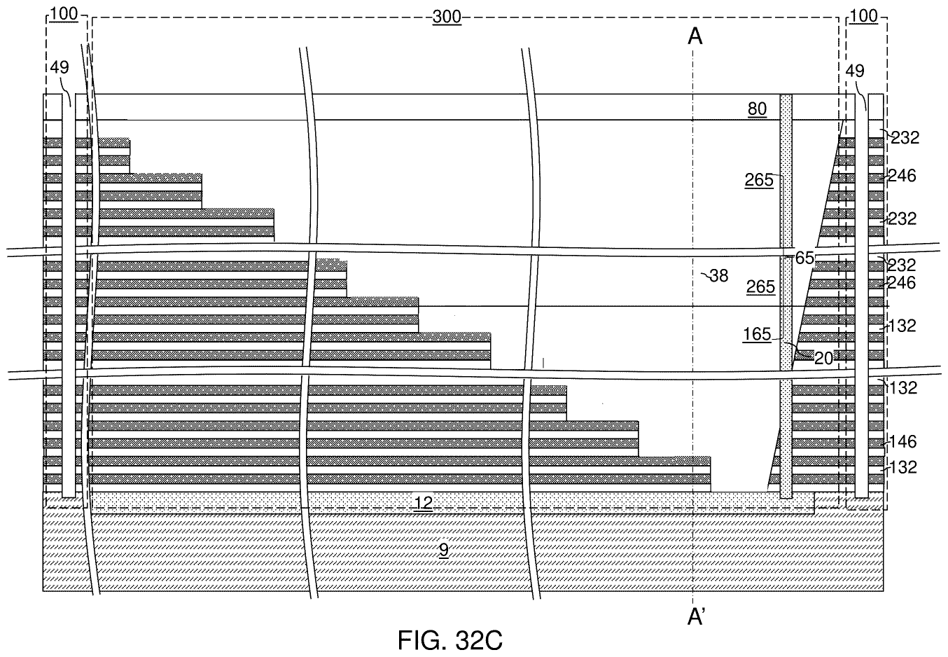

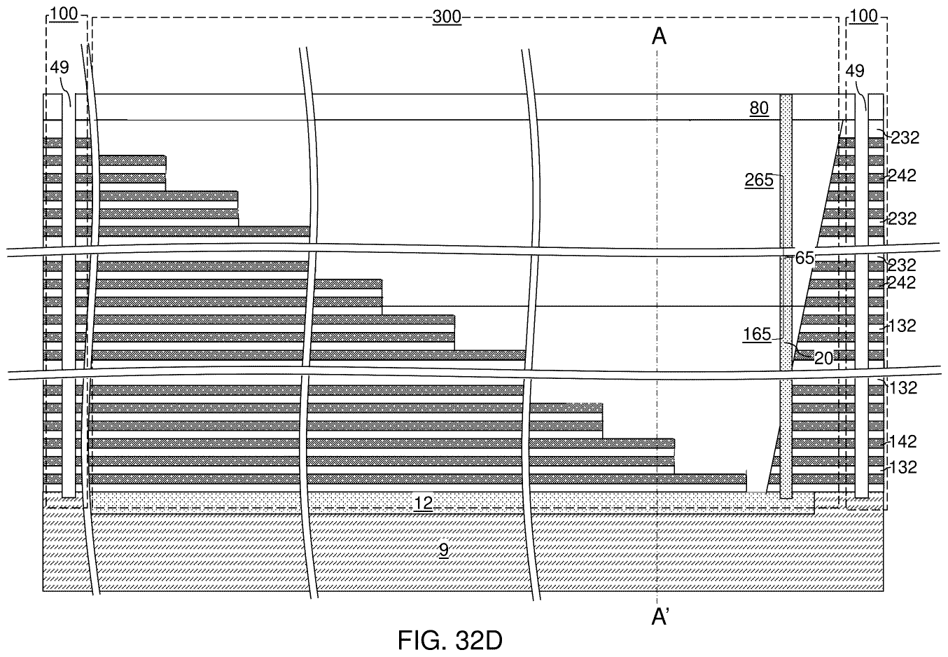

Referring to FIGS. 32A-32D, the processing steps described with reference to FIGS. 15A-15D can be performed to form memory openings 49.

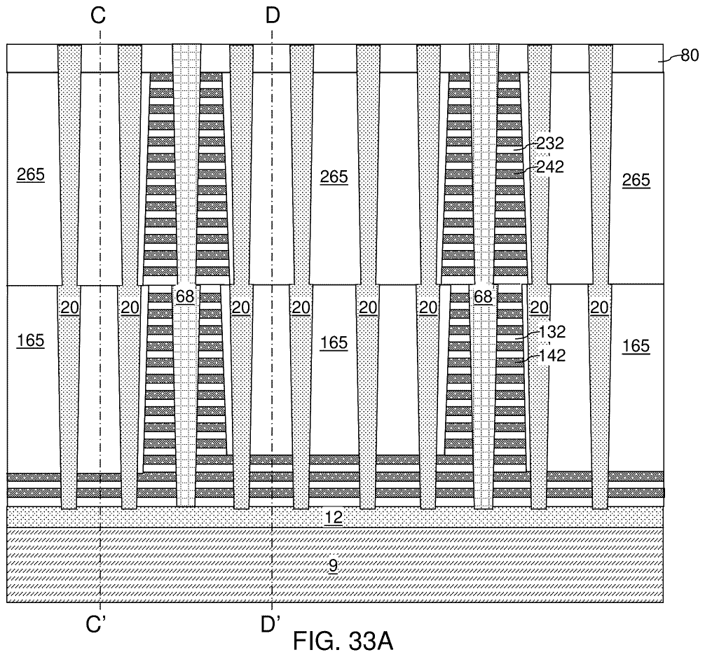

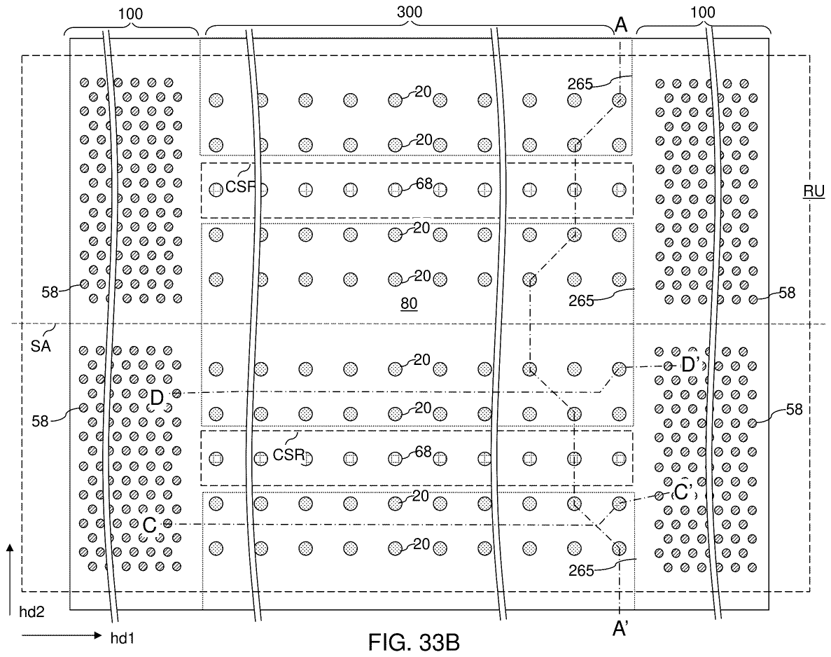

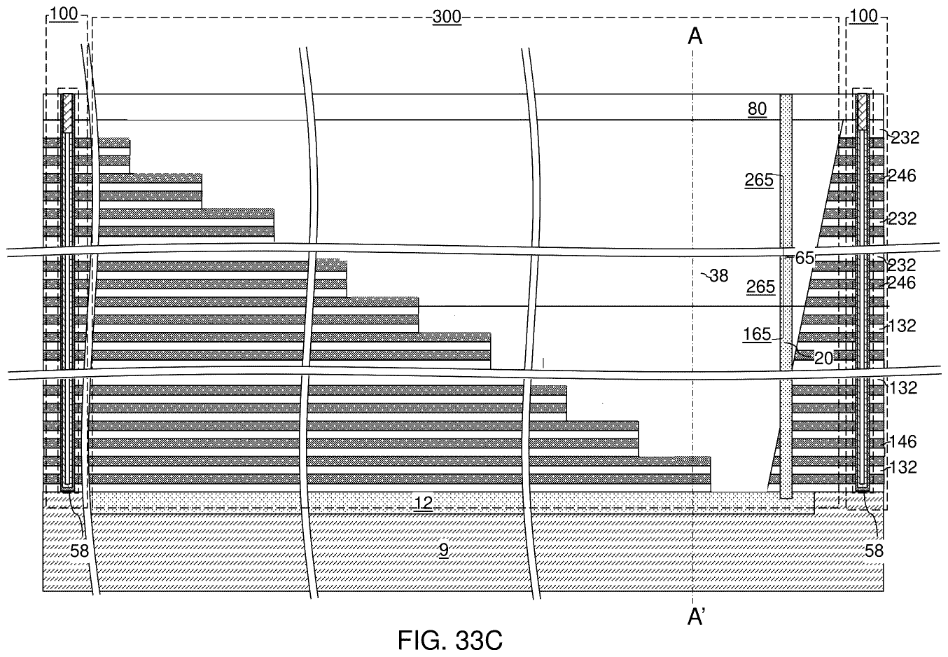

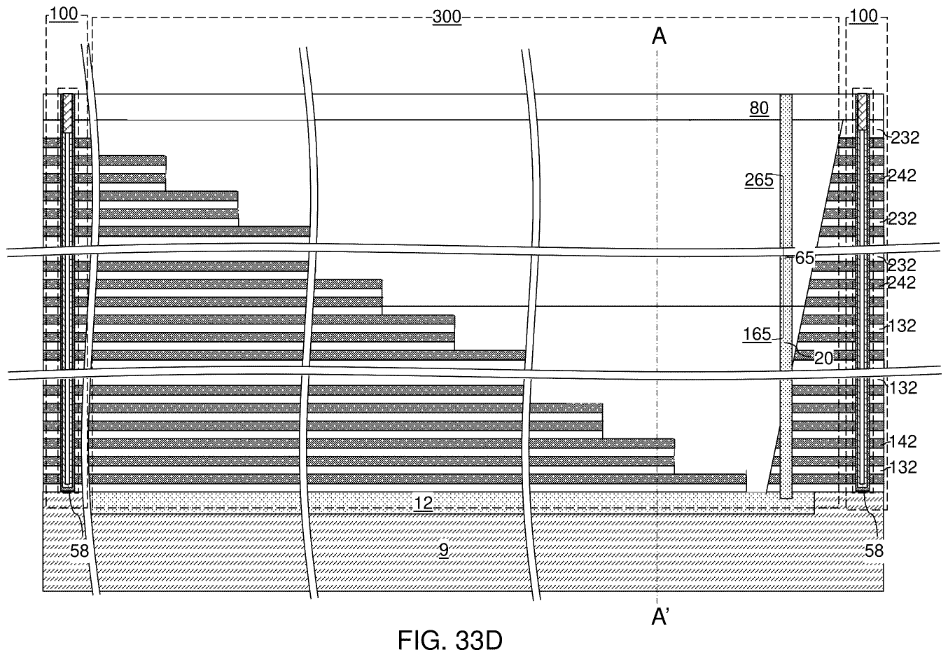

Referring to FIGS. 33A-33D, the processing steps described with reference to FIGS. 16A-16F can be performed to form memory opening fill structures 58 in the memory openings 49.

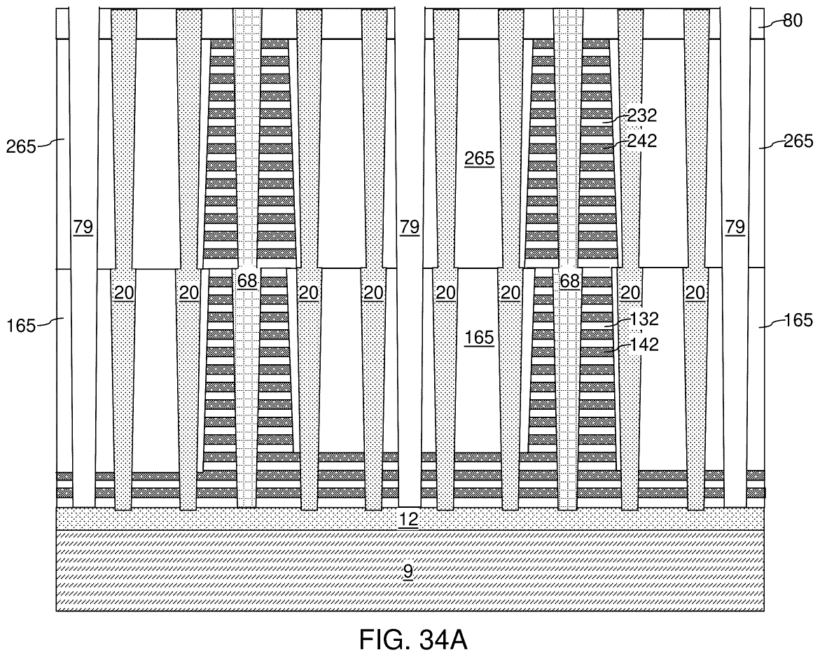

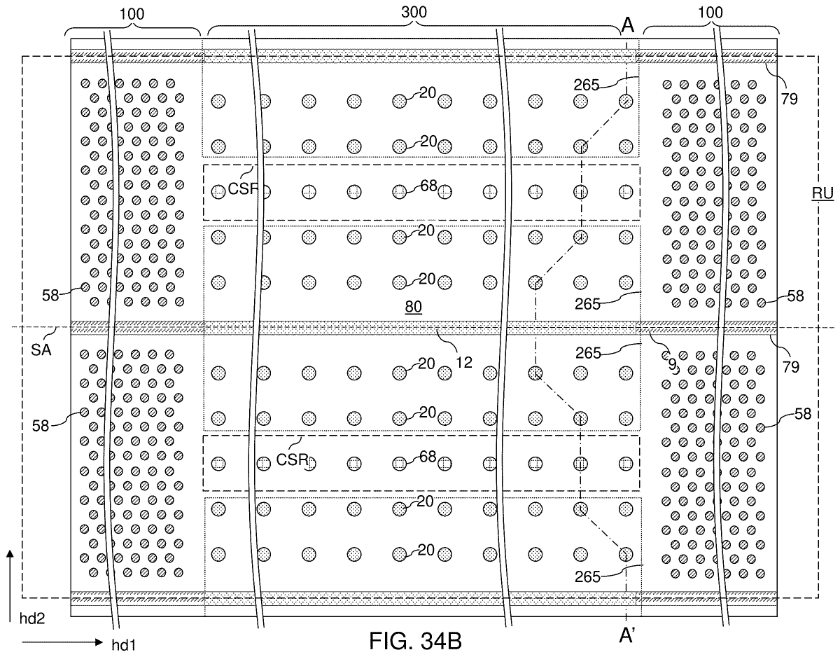

Referring to FIGS. 34A and 34B, the processing steps described with reference to FIGS. 18A and 18B can be performed to form lateral isolation trenches 79.

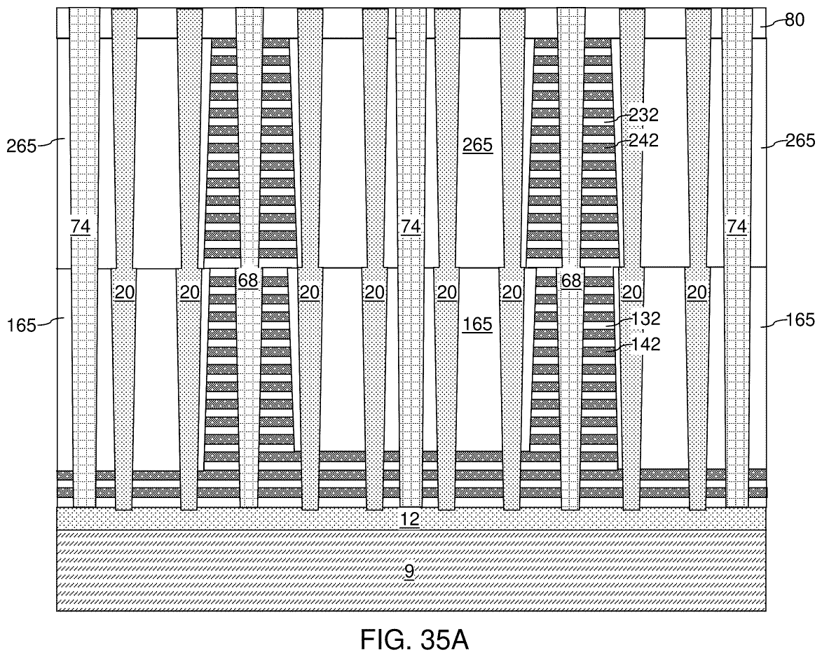

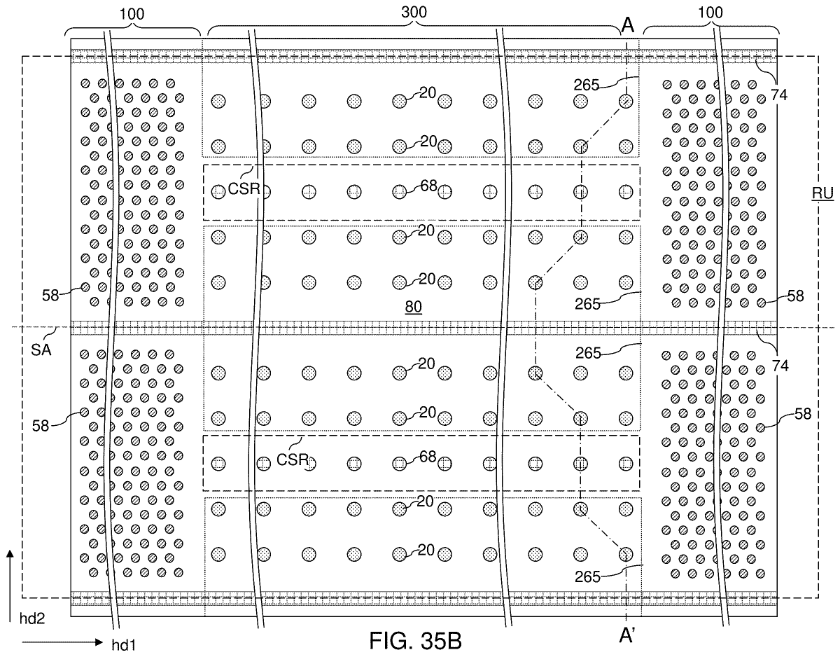

Referring to FIGS. 35A and 35B, the processing steps described with reference to FIGS. 19A and 19B can be performed to form sacrificial lateral isolation trench fill structures 74 in the lateral isolation trenches 79.

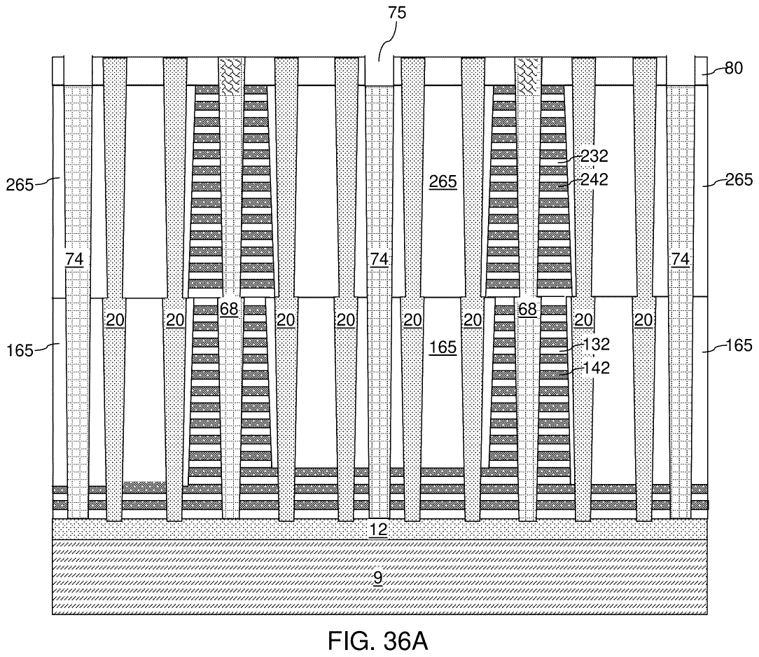

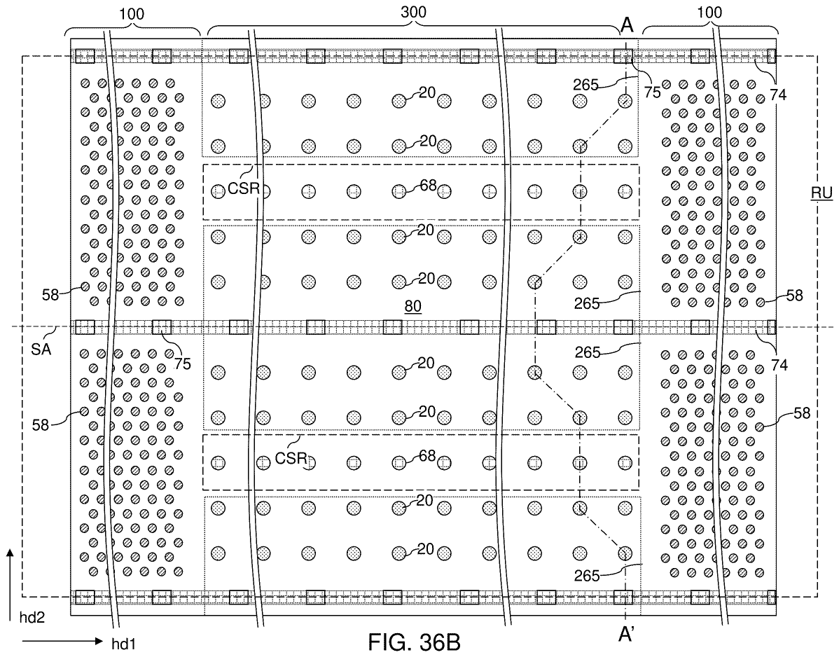

Referring to FIGS. 36A and 36B, the processing steps described with reference to FIGS. 20A and 20B can be performed to form the bridge recesses 75 in upper portions of the sacrificial lateral isolation trench fill structures 74.

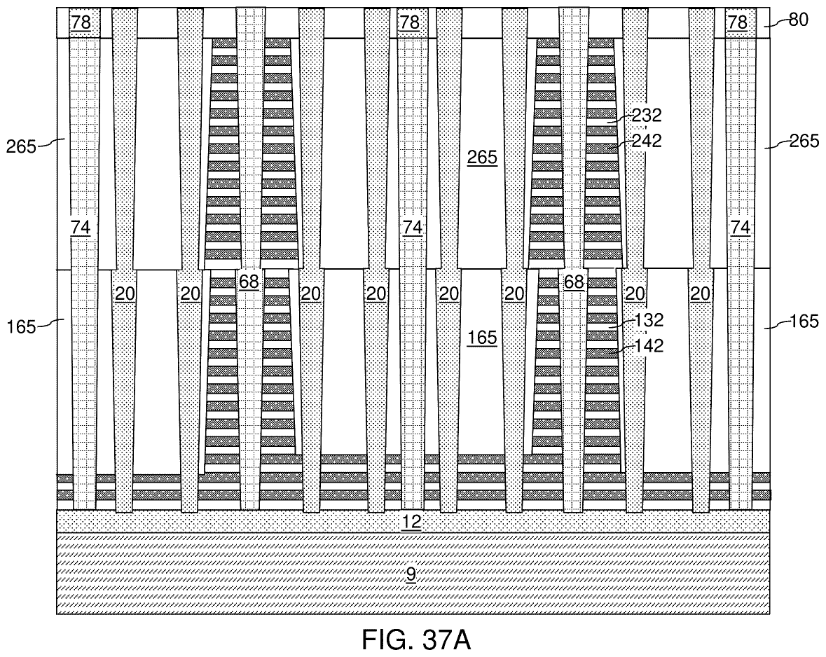

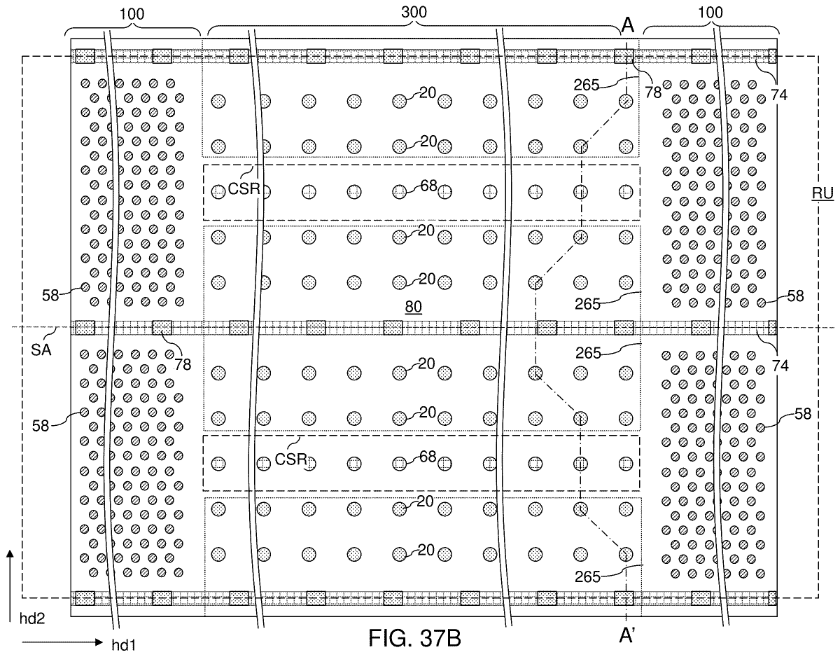

Referring to FIGS. 37A and 37B, the processing steps described with reference to FIGS. 21A and 21B can be performed to form the bridge structures 78 in the bridge recesses 75

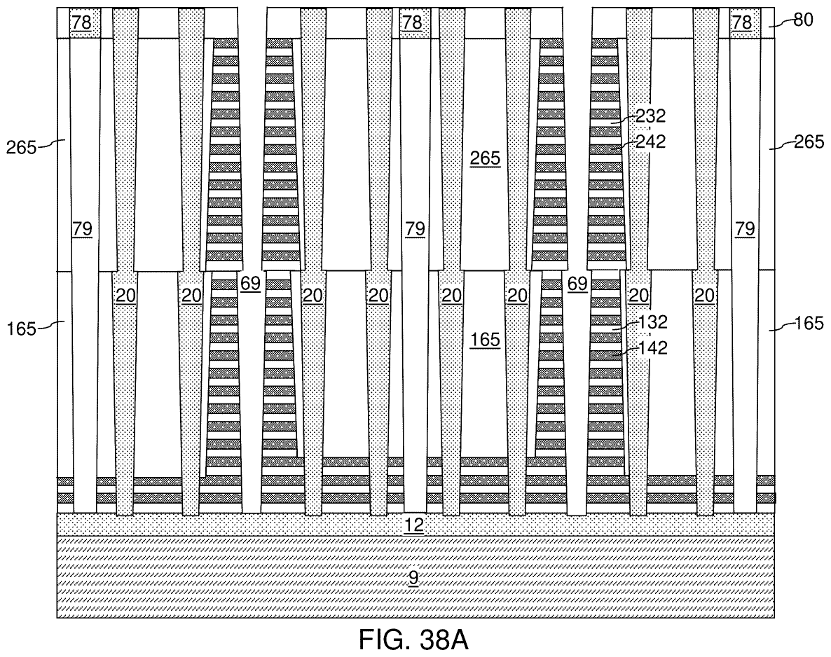

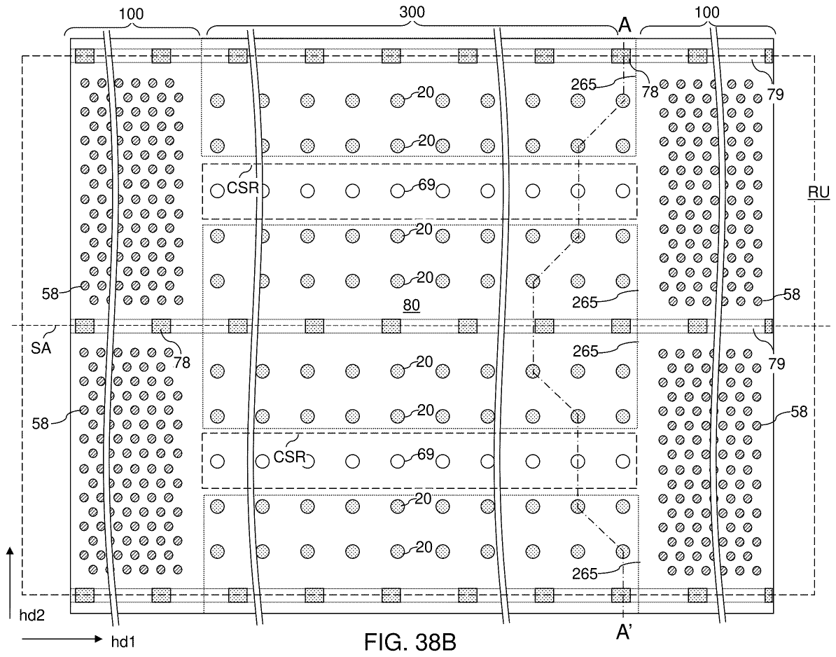

Referring to FIGS. 38A and 38B, the first selective etch process described with reference to FIGS. 22A and 22B can be performed to remove the sacrificial access opening fill structures 68 and the sacrificial lateral isolation trench fill structures 74 without etching the materials of the contact-level dielectric layer 80, the bridge structures 78, the alternating stacks {(132, 142), (232, 242)}, and the retro-stepped dielectric material portions (165, 265). For example, if the sacrificial access opening fill structures 68 and the sacrificial lateral isolation trench fill structures 74 comprise amorphous silicon, a wet etch process using hot trimethyl-2 hydroxyethyl ammonium hydroxide (“hot TMY”) or tetramethyl ammonium hydroxide (TMAH) can be performed to remove the sacrificial access opening fill structures 68 and the sacrificial lateral isolation trench fill structures 74. Access openings 69 are formed in volumes from which the sacrificial access opening fill structures 68 are removed. Lateral isolation cavities 79′ are formed in the volumes from which the sacrificial lateral isolation trench fill structures 74 are removed. According to an aspect of the present disclosure, at least one row of access openings 69 can be formed through each of the connection strip portions in a respective connection strip region CSR.

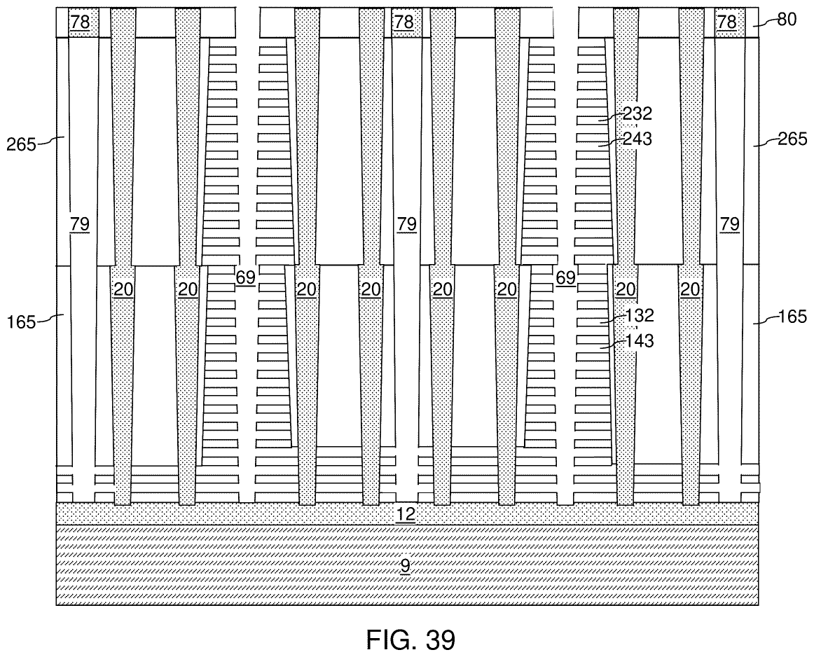

Referring to FIG. 39, a second selective etch process described with reference to FIG. 23 can be performed to remove the sacrificial material layers (142, 242) selectively to the insulating layers (132, 232) employing the access openings 69 and the lateral isolation trenches 79 as conduits for transporting an isotropic etchant. Specifically, the sacrificial material layers (142, 242) may be isotropically etched selectively to the insulating layers (132, 232), the annular dielectric spacers 22, the bridge structures 78, and the retro-stepped dielectric material portions (165, 265) by supplying an isotropic etchant into the access openings 69 and the lateral isolation trenches 79. In one embodiment, an etchant that selectively etches the materials of the insulating layers (132, 232), the annular dielectric spacers 22, the bridge structures 78, the retro-stepped dielectric material portions (165, 265), and the outermost layer of the memory films 50 may be introduced into the access openings 69 and the lateral isolation trenches 79 during the second selective isotropic etch process.

The second selective isotropic etch process may be a wet etch process using a wet etch solution, or may be a gas phase (dry) etch process in which the etchant is introduced in a vapor phase into the lateral isolation trench. For example, if the sacrificial material layers (142, 242) comprise silicon nitride, and if the insulating layers (132, 232), the annular dielectric spacers 22, the bridge structures 78, the retro-stepped dielectric material portions (165, 265), and the outermost layer of the memory films 50 comprise silicon oxide materials, the etch process may comprise a hot phosphoric acid etch process, which etches silicon nitride selectively to silicon oxide, silicon, and various other materials used in the art.

Laterally-extending cavities (143, 243) are formed in volumes from which the sacrificial material layers (142, 242) are removed. The laterally-extending cavities 43 include first laterally-extending cavities 143 that are formed in volumes from which the first-tier sacrificial material layers 142 are removed and second laterally-extending cavities 243 that are formed in volumes from which the second-tier sacrificial material layers 242 are removed. Each of the laterally-extending cavities (143, 243) may have a lateral dimension that is greater than a vertical dimension.

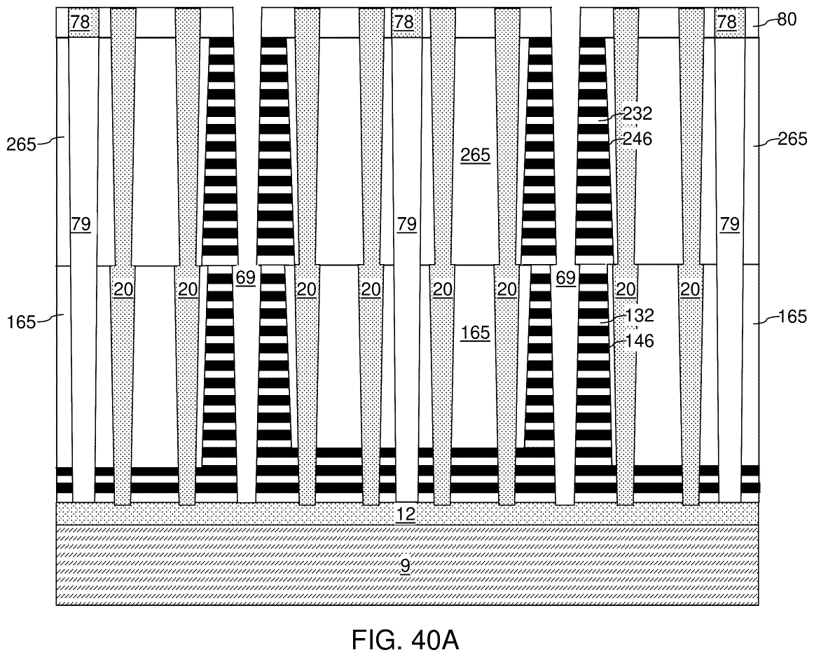

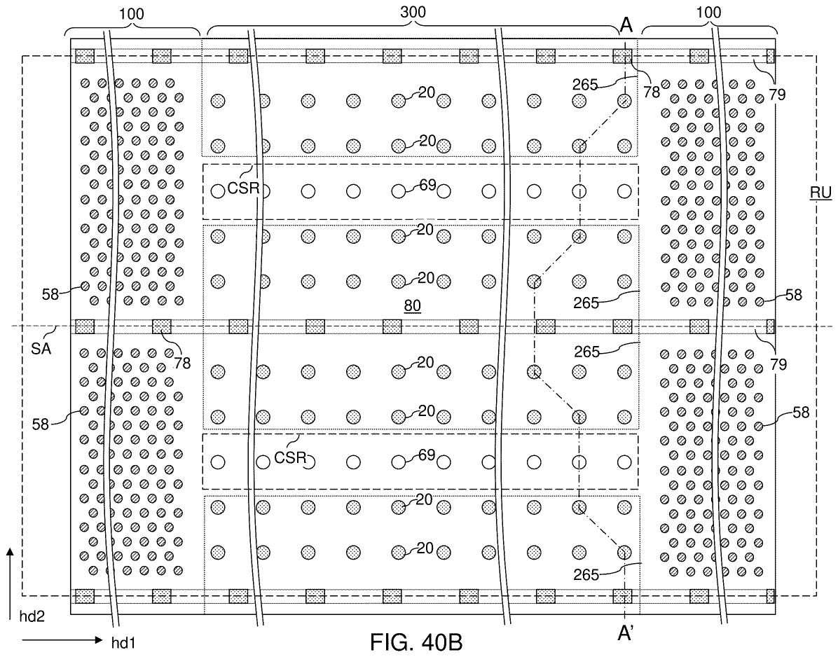

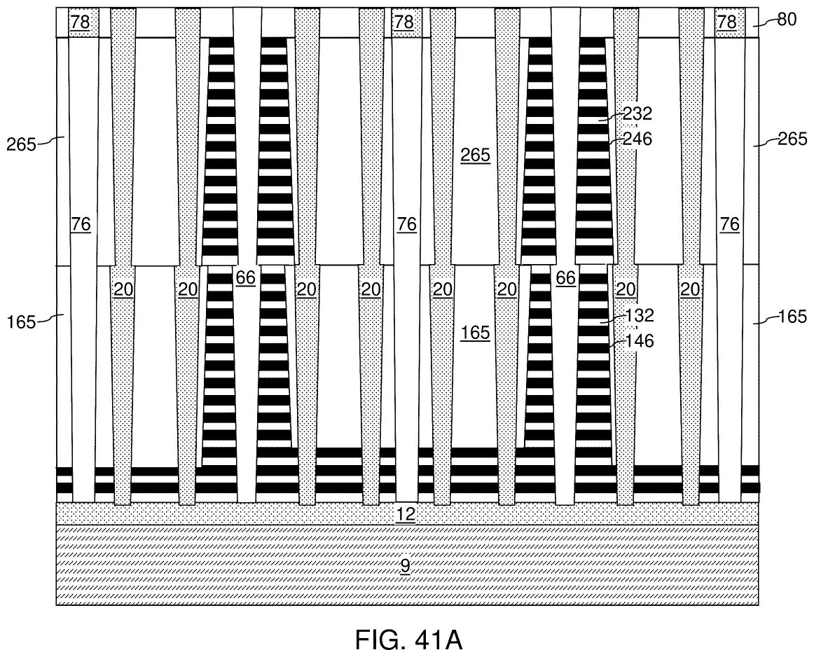

Referring to FIGS. 40A and 40B, an electrically conductive material layer may be conformally deposited in the laterally-extending cavities (143, 243), in peripheral regions of each of the access openings 69 and the lateral isolation trenches 79, and over the top surface of the contact-level dielectric layer 80. The electrically conductive material layer can be conformally deposited on all physically exposed surfaces around the access openings 69 and the lateral isolation trenches 79, and on the physically exposed top surface of the contact-level dielectric layer 80. The electrically conductive material layer comprises at least one electrically conductive material, which may be a combination of a metallic barrier material (such as TiN, TaN, WN, and/or MoN) and a metal fill material (such as W, Ti, Ta, Mo, Co, Ru, Cu, etc.). The total thickness of the at least one metallic material may be selected such that the entirety of the laterally-extending cavities (143, 243) is filled within the electrically conductive material layer.

A selective recess etch process can be performed to etch portions of the electrically conductive material layer that are located outside the laterally-extending cavities (143, 243). The selective recess etch process etches the electrically conductive material layer selectively to the materials of the insulating layers (132, 232), the contact-level dielectric layer 80, the bridge structures 78, the retro-stepped dielectric material portions (165, 265), and the etch-stop dielectric layer 12. Portions of the electrically conductive material layer located inside the lateral isolation trenches 79 or inside the access openings 39 can be removed by the selective recess etch process.

Each remaining portion of the electrically conductive material layer that remains in a respective laterally-extending cavity (143, 243) constitutes an electrically conductive layer (146, 246). The electrically conductive layers (146, 246) comprise first-tier electrically conductive layers (e.g., word lines and underlying source side select gate electrodes) 146 that are formed within a respective first-tier laterally-extending cavity 143 and second-tier electrically conductive layers (e.g., additional word lines and overlying drain side select gate electrodes) 246 that are formed within a respective second-tier laterally-extending cavity 243.

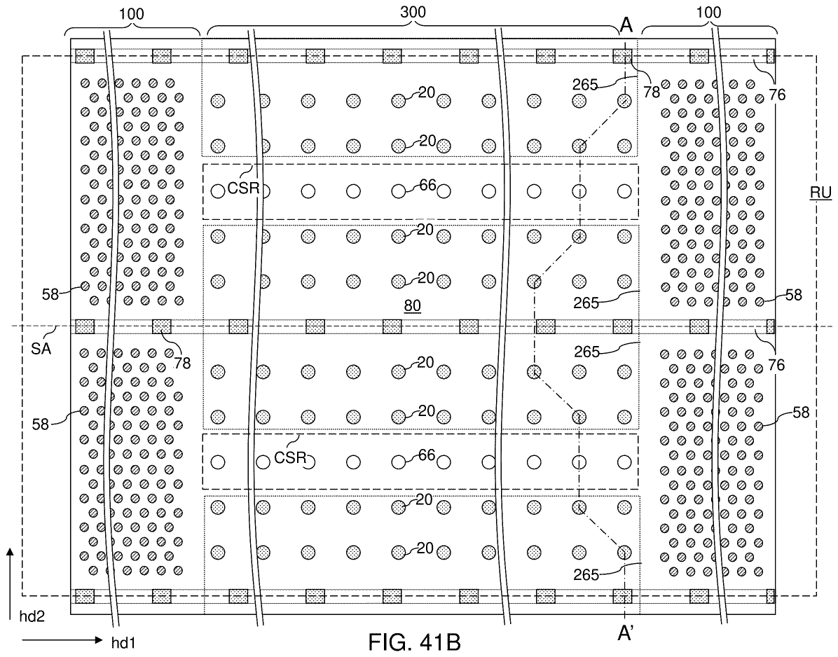

Referring to FIGS. 41A and 41B, a dielectric fill material can be conformally deposited in the access openings 39 and in the lateral isolation trenches 79. In one embodiment, the dielectric fill material may comprise silicon oxide. The horizontally-extending portion of the dielectric fill material that is deposited over the contact-level dielectric layer 80 constitutes a connection-level dielectric layer 90. Each vertically-extending portion of the dielectric fill material that fills a respective one of the access openings 39 comprises an access via opening fill structure 26, which is a dielectric pillar structure. Each portion of the dielectric fill material that fills a respective lateral isolation trench 79 constitutes an in-trench dielectric wall structure 76.

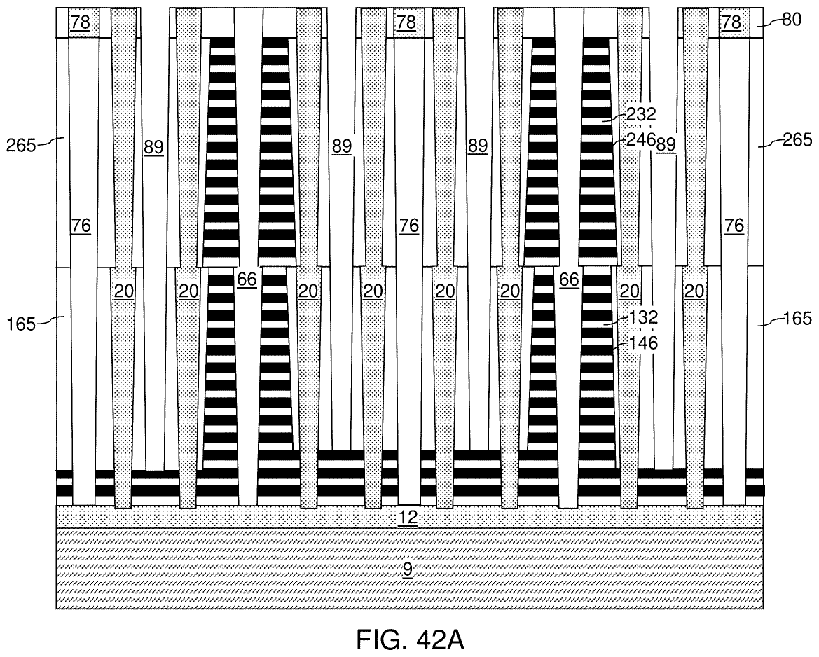

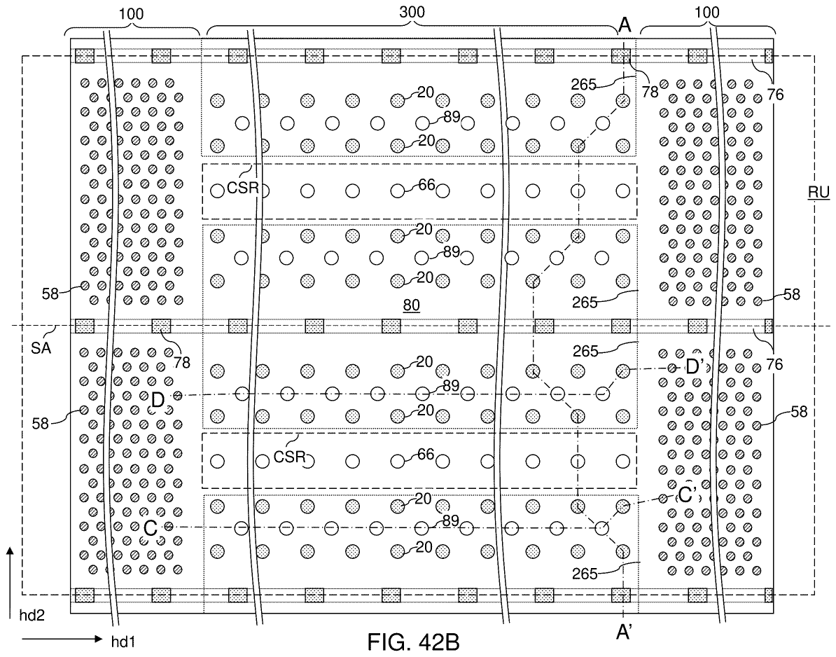

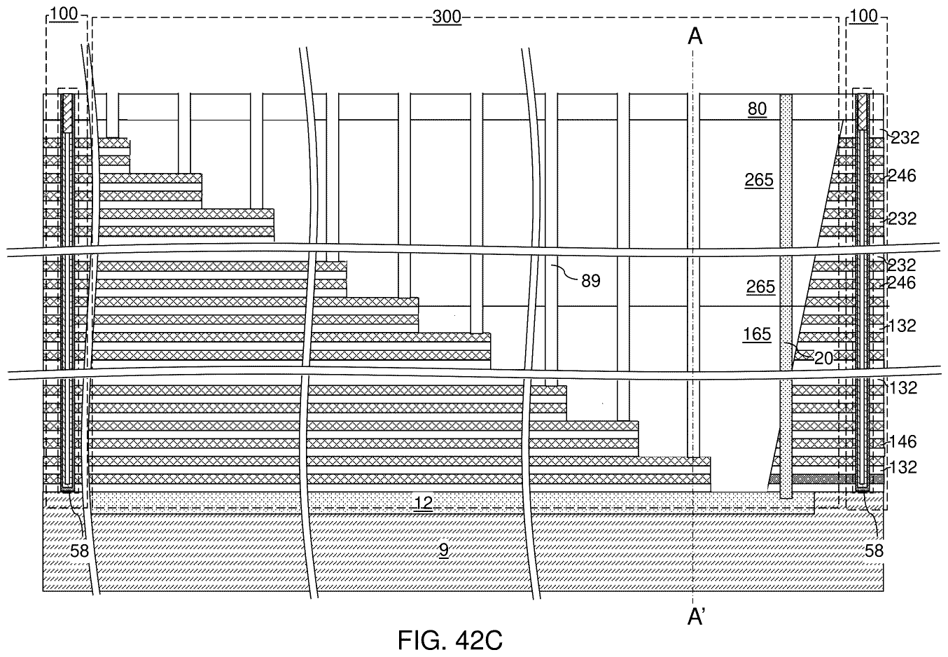

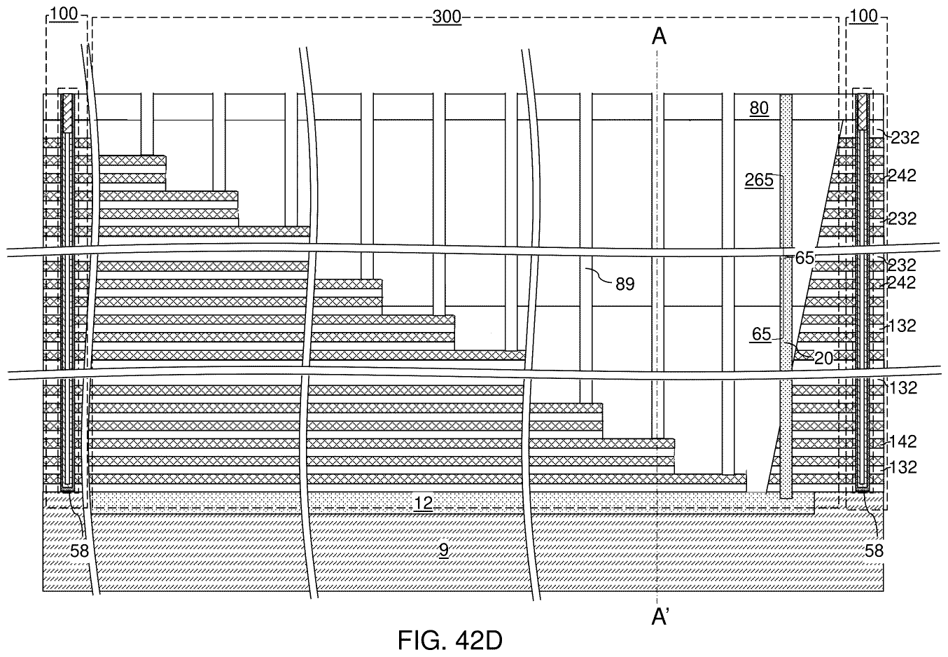

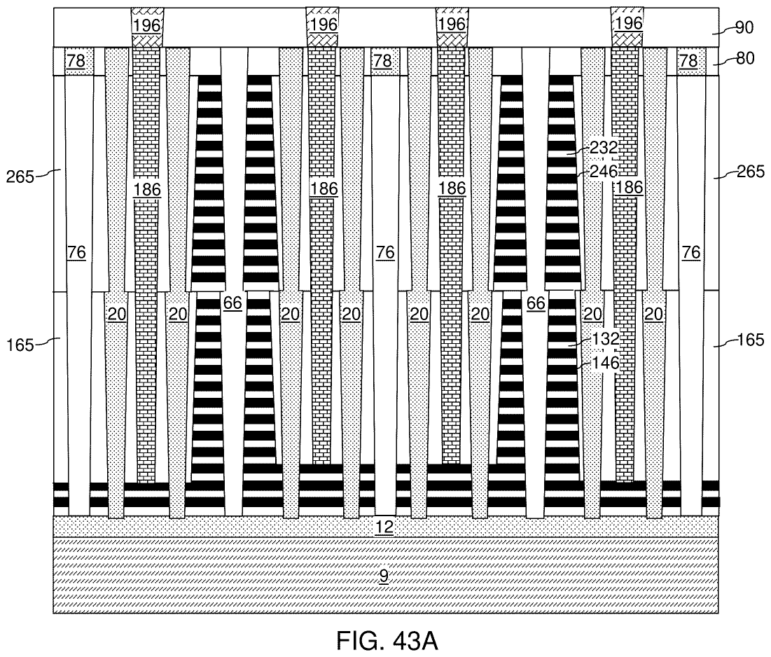

Referring to FIGS. 42A-42D, a photoresist layer (not shown) can be applied over the contact-level dielectric layer 80, and can be lithographically patterned to form openings over the horizontal surface segments of the electrically conductive layers (146, 246) that contact bottom surface segments of the retro-stepped dielectric material portions (165, 265). An anisotropic etch process is performed to transfer the pattern of the openings in the photoresist layer through the contact-level dielectric layer 80 and the retro-stepped dielectric material portions (165, 265). The anisotropic etch process can have an etch chemistry that etches the materials of the contact-level dielectric layer 80 and the retro-stepped dielectric material portions (165, 265) selectively to the material(s) of the electrically conductive layers (146, 246). Contact openings 89 can be formed through the contact-level dielectric layer 80 and the retro-stepped dielectric material portions (165, 265). A top surface segments of an electrically conductive layer (146, 246) is physically exposed at the bottom of each contact opening 89.

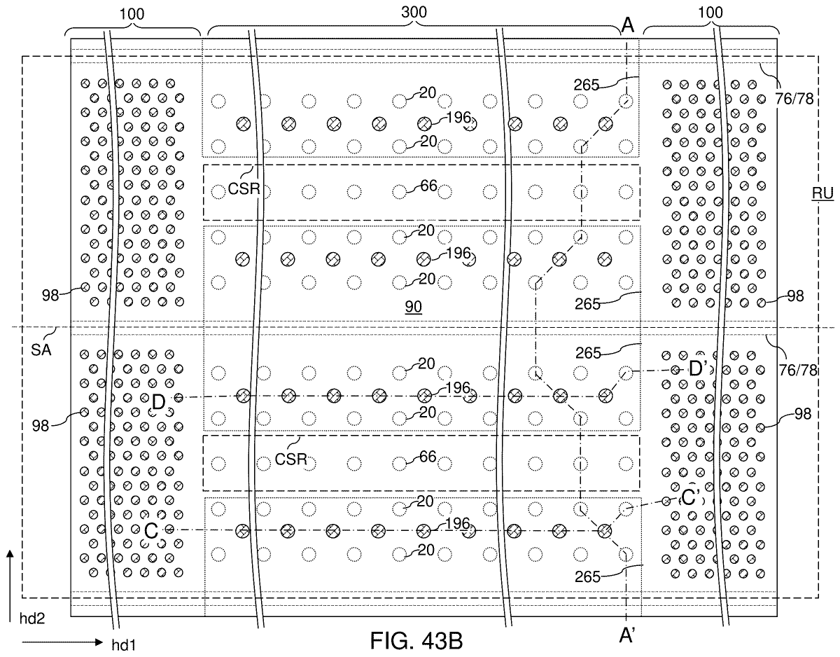

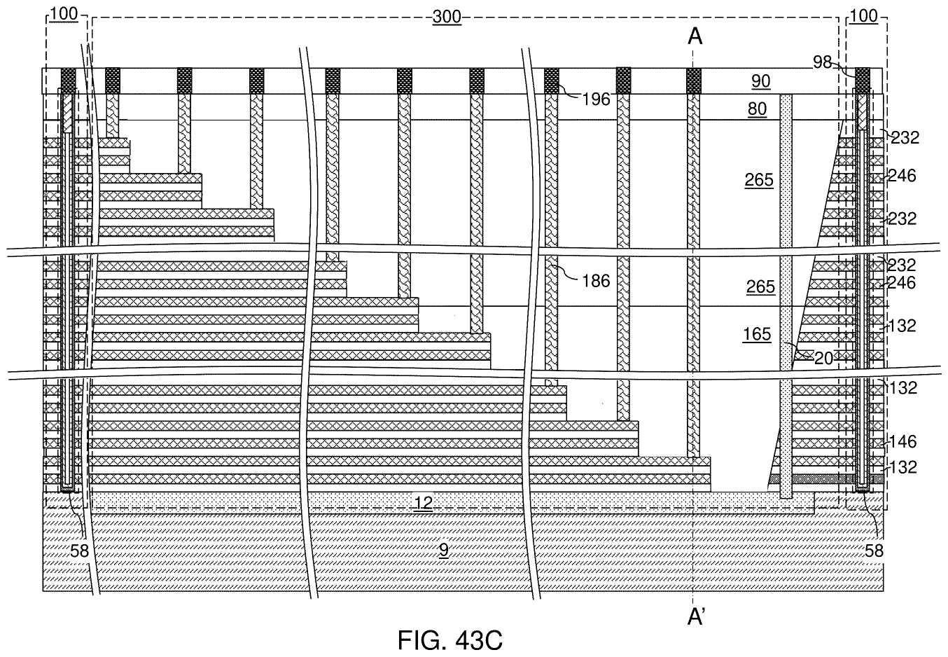

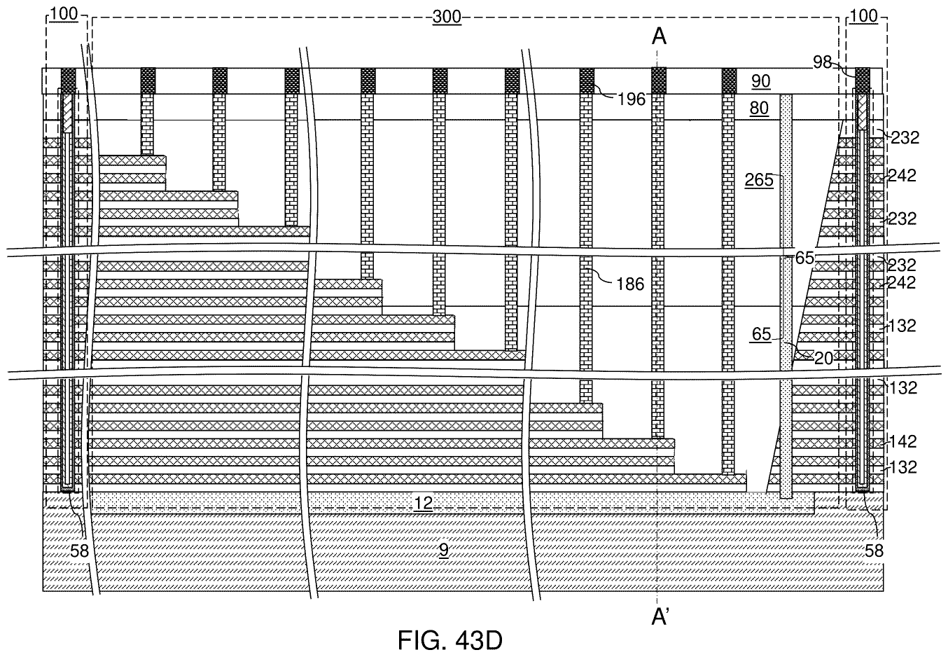

Referring to FIGS. 43A-43D, at least one conductive material can be deposited in the contact openings 89. The at least one conductive material may comprise a combination of a metallic barrier material (such as TiN, TaN, WN, and/or MoN) and a metal fill material (such as W, Ti, Ta, Mo, Co, Ru, Cu, etc.). Excess portions of the at least one conductive material can be removed from above the horizontal plane including the top surface of the contact-level dielectric layer 80. Each remaining portion of the at least one conductive material that fills a respective contact opening 89 constitutes a contact via structure 186.

Each of the layer contact via structures 186 is electrically connected to a respective one of the electrically conductive layers (146, 246). Each layer contact via structure 186 vertically extends through at least one retro-stepped dielectric material portion (165 and/or 265), and is electrically connected to a respective one of the electrically conductive layers (146, 246). In one embodiment, each layer contact via structure 186 comprises a bottom surface contacting a top surface of a respective one of the electrically conductive layers (146, 246).

A connection-level via structure 196 can be formed over the contact-level dielectric layer 80. Connection via structures 196 can be formed through the connection-level dielectric layer 90 on a respective one of the layer contact via structures 86. In one embodiment, each connection via structure 196 vertically extends through the connection-level dielectric layer 90 and contacts a top surface of the tab portion of a respective layer contact via structure 86.

In the first and second embodiments, the connection strip regions CSR (e.g., word line bridge regions) which contain the connection strip portions of the electrically conductive layers (146, 246) are located mid-way between the pair of nearest lateral isolation trenches 79 along the bit line direction hd2. Thus, the structure is symmetrical on each side of the lateral isolation trench 79. This reduces the chance of the insulating layers (132, 232) tilting or collapsing into the lateral isolation trenches 79 during replacement of the sacrificial material layers (142, 242) with the electrically conductive layers (146, 246).

Furthermore, the stepped surfaces in each cavity (169, 269) are laterally separated from each other along the bit line direction hd2 by the CSR. This avoids having adjacent steps having a height of only one insulating layer and one sacrificial material layer being located directly adjacent to each other along the bit line direction hd2. This also permits all steps in the respective cavities (169, 269) to have a greater height of at least two pairs of insulating layers and sacrificial material layers along the word line direction hd1, since directly adjacent steps along the bit line direction hd2 may be omitted. This increases the process and lithography window for forming the thickened portions (142T, 242T) of the sacrificial material layers (142, 242) of the first embodiment, and reduces the chance of occurrence of cavities in the electrically conductive layers (146, 246).

Finally, the electrically conductive layers (146, 246) are deposited through at least the access openings 69 located in the CSR in addition to being deposited through the lateral isolation trenches 79. This reduces potential width shifts and variations of the stepped surfaces of the electrically conductive layers.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A method of forming a device structure, comprising:
forming a vertically alternating sequence of continuous insulating layers and continuous sacrificial material layers;
forming first and second stepped cavities having a respective stepped bottom surface in the vertically alternating sequence such that a connection strip region is located between the first and the second stepped cavities;
forming respective first and second in-process retro-stepped dielectric material portions in the respective first and second stepped cavities;
forming access openings through the connection strip region;
forming memory stack structures through the vertically alternating sequence, wherein each of the memory stack structures comprises a respective vertical stack of memory elements and a vertical semiconductor channel;
forming lateral isolation trenches through the vertically alternating sequence; and
replacing the sacrificial material layers with electrically conductive layers through the lateral isolation trenches and through the access openings.

2. The method of claim 1, wherein:
the lateral isolation trenches cut the vertically alternating sequence into multiple alternating stacks of respective insulating layers and respective sacrificial material layers; and
each of the multiple alternating stacks comprises a first alternating stack portion located in a first memory array region, a second alternating stack portion located in a second memory array region that is laterally spaced from the first memory array region along a first horizontal direction.

3. The method of claim 2, wherein:
the step of forming the lateral isolation trenches comprises forming a first lateral isolation trench and a second lateral isolation trench;
an area between the first lateral isolation trench structure and the second lateral isolation trench structure comprises an area of one memory block comprising one of the alternating stacks comprising one of the first alternating stack portions and one of the second alternating stack portions; and
the connection strip portion is located in a connection strip region of the area of one memory block and connects the one of the first alternating stack portions and the one of the second alternating stack portions along the first horizontal direction.

4. The method of claim 3, wherein:
each of the lateral isolation trenches laterally extends along a first horizontal direction;
the first lateral isolation trench divides the first in-process retro-stepped dielectric material portion into a respective pair of retro-stepped dielectric material portions;
the second lateral isolation trench divides the second in-process retro-stepped dielectric material portion into a respective additional pair of retro-stepped dielectric material portions; and
a contiguous combination of the one of the multiple alternating stacks, a respective first retro-stepped dielectric material portion, and a respective second retro-stepped dielectric material portion is formed between the neighboring pair of the first lateral isolation trench and the second lateral isolation trench.

5. The method of claim 4, wherein:
the respective first retro-stepped dielectric material portion is a patterned portion of the first in-process retro-stepped dielectric material portion; and
the respective second retro-stepped dielectric material portion is a patterned portion of the second in-process retro-stepped dielectric material portion.

6. The method of claim 4, further comprising:
forming contact openings through the first retro-stepped dielectric material portion and the second retro-stepped dielectric material portion; and
forming layer contact via structures in the contact openings, wherein each of the layer contact via structures is electrically connected to a respective one of the electrically conductive layers.

7. The method of claim 1, further comprising:
performing an isotropic etch process that introduces an isotropic etchant that etches the sacrificial material layers selectively to the insulating layers into the access openings and the lateral isolation trenches to form laterally-extending cavities in volumes from which the sacrificial material layers are removed; and
depositing the electrically conductive layers into the laterally-extending cavities through the access openings and the lateral isolation trenches to replace the sacrificial material layers with electrically conductive layers.

8. The method of claim 7, further comprising forming contact openings through the first and second in-process retro-stepped dielectric material portions.

9. The method of claim 8, wherein:
the isotropic etchant that etches the sacrificial material layers selectively to the insulating layers is also introduced into the contact openings;
the electrically conductive layers are also deposited into the laterally-extending cavities through the contact openings;
portions of the electrically conductive layers located in the contact openings comprise layer contact via structures; and
portions of the electrically conductive layers located in the laterally-extending cavities comprise word lines.

10. The method of claim 9, further comprising:
forming a connection-level dielectric layer overlies the layer contact via structures; and
forming connection via structures through the connection-level dielectric layer and contacting top surfaces of horizontal tab portions of the layer contact via structures.

11. The method of claim 8, wherein:
each of the layer contact via structures electrically contacts a respective one of the word lines;
a subset of the word lines underlies said one of the word lines; and
the layer contact via structure vertically extends through the subset of the word lines.

12. The method of claim 11, further comprising:
forming annular recesses in the sacrificial material layers through the contact openings;
forming annular dielectric spacers in the annular recesses, wherein inner cylindrical sidewalls of the annular dielectric spacers contact sidewall surface segments of the layer contact via structures, and the annular dielectric spacers are laterally surrounded by the subset of the word lines.

13. The method of claim 11, further comprising:
conformally depositing an additional continuous sacrificial material layer over the stepped bottom surfaces of the first and the second stepped cavities, and anisotropically depositing a non-conformal cover material layer in which vertical thickness of its horizontally-extending portions is greater than lateral thickness of its vertically-extending portions of the non-conformal cover material layer over the additional continuous sacrificial material layer prior to the step of forming the respective first and second in-process retro-stepped dielectric material portions;
isotropically etching the non-conformal cover material layer to leave cover material plates that overlie only horizontally-extending portions of the additional continuous sacrificial material layer; and
selectively etching unmasked portions of the additional continuous sacrificial material layer using the cover material plates as a mask to remove exposed vertically-extending portions of the additional continuous sacrificial material layer,
wherein:
the horizontally-extending portions of the additional continuous sacrificial material layer that remain after the step of selectively etching are incorporated into respective continuous sacrificial material layers to form thickened portions of the sacrificial material layers on the stepped bottom surfaces of the first and the second stepped cavities; and
the word lines comprise thickened portions on the stepped bottom surfaces of the first and the second stepped cavities after the replacing the sacrificial material layers with the electrically conductive layers.

14. The method of claim 11, further comprising:
forming an in-via dielectric liner in vertically-extending cavities in the contact via structures; and
depositing a dielectric fill material into the vertically-extending cavities and the lateral isolation trenches to form in-via dielectric pillar portions in the vertically-extending cavities and in-trench dielectric wall structures in the lateral isolation trenches.

15. The method of claim 1, further comprising forming access opening fill dielectric material portions in the access openings.

16. The method of claim 1, wherein the step of replacing the sacrificial material layers with the electrically conductive layers forms an alternating stack of insulating layers and electrically conductive layers.

17. The method of claim 16, wherein the alternating stack of insulating layers and electrically conductive layers comprises:
a first alternating stack portion located in a first memory array region;
a second alternating stack portion located in a second memory array region that is laterally spaced from the first memory array region along a first horizontal direction;
a connection strip portion located in the connection strip region and connecting the first alternating stack portion and the second alternating stack portion;
a first staircase portion adjoined to a first side of the connection strip portion along a second horizontal direction that is perpendicular to the first horizontal direction; and
a second staircase portion adjoined to a second side of the connection strip portion along the second horizontal direction.

18. The method of claim 17, further comprising:
forming a first lateral isolation trench fill structure extending along the first horizontal direction in a first one of the lateral isolation trenches; and
forming a second lateral isolation trench fill structure extending along the first horizontal direction in a second one of the lateral isolation trenches, and spaced from the first lateral isolation trench fill structure along the second horizontal direction by the alternating stack.

19. The method claim 17, wherein at least 80 percent of all of the electrically conductive layers in the alternating stack continuously extend in the connection strip portion from the first memory array region to the second memory array region.

20. The method of claim 17, wherein:
each vertical step in the first staircase portion comprises at least two of the electrically conductive layers and at least two of the insulating layers; and
each vertical step in the second staircase portion comprises at least two of the electrically conductive layers and at least two of the insulating layers.
